(19) United States
(12) Patent Application Publication
(10) Pub. No.: US 2024/0090316 A1
(43) Pub. Date: Mar. 14, 2024

(54) MIXTURES AND APPLICATIONS THEREOF IN OPTOELECTRONIC FIELD

(71) Applicant: Zhejiang Brilliant Optoelectronic Technology Co.,Ltd., Taizhou (CN)

(72) Inventors: Junyou PAN, Taizhou (CN); Jiahui TAN, Taizhou (CN)

(73) Assignee: Zhejiang Brilliant Optoelectronic Technology Co.,Ltd., Taizhou (CN)

(21) Appl. No.: 18/483,385

(22) Filed: Oct. 9, 2023

Related U.S. Application Data
(63) Continuation of application No. PCT/CN2022/085637, filed on Apr. 7, 2022.

(30) Foreign Application Priority Data
Apr. 7, 2021 (CN) 202110370819.7

(51) Int. Cl. H10K 85/50; C09D 11/033; C09D 11/037; C09D 11/107; C09D 11/322; C09D 11/36; C09D 11/50; C09D 11/52; C09K 11/02; C09K 11/06; H10K 59/38; H10K 85/10; H10K 85/60

(52) U.S. Cl. CPC H10K 85/50; C09D 11/033; C09D 11/037; C09D 11/107; C09D 11/322; C09D 11/36; C09D 11/50; C09D 11/52; C09K 11/02; C09K 11/06; H10K 59/38; H10K 85/141; H10K 85/623; H10K 85/626; H10K 85/633

(57) ABSTRACT

Disclosed are mixtures including an organic compound H and a perovskite emitter E. Also provided are formulations containing the mixtures and at least one solvent. Further provided are organic light-emitting devices containing the mixtures.

### CROSS-REFERENCE TO RELATED APPLICATIONS

The present application is a continuation of International Application No. PCT/CN2022/085637, filed on Apr. 7, 2022, which claims priority to Chinese Patent Application No. 202110370819.7, filed on Apr. 7, 2021. All of the aforementioned applications are incorporated herein by reference in their entireties.

### TECHNICAL FIELD

The present disclosure relates to the field of organic electronic material and technology, and in particularly to a mixture, a formulation, an organic light-emitting device, and the applications thereof in the optoelectronic field.

### BACKGROUND

According to the principles of colorimetry, the narrower the full width at half maximum (FWHM) of the lights perceived by the human eyes is, the higher the color purity, and the more vivid the color display would be. Display devices with narrow-FWHM red, green and blue primary light are able to show vivid views with high color gamut and high visual quality.

The current mainstream full-color displays are achieved mainly in two ways. The first method is to actively emit red, green and blue lights, typically such as RGB-OLED display. The current mature technology is to fabricate light-emitting devices with three colors by vacuum evaporation with fine metal masks, which is complex, at high cost and difficult to achieve high-resolution display over 600 ppi. The second method is using color converters to convert the single-color light from the light-emitting devices into different colors, thereby achieving a full-color display. For example, Samsung combines blue OLEDs with red and green quantum dots (QD) films as the color converters. In this case, the fabrication of the light emitting devices is much simpler, and thus higher yield. Furthermore, the manufacture of the color converters can be achieved by different technologies, such as vacuum evaporation, ink-jet printing, transfer printing, photolithography, etc., appliable to a variety of display products with very different resolution requirements from low resolution large-size TV (around only 50 ppi) to high resolution silicon-based micro-display (over 3000 ppi).

Currently, the most promising color conversion materials for use in color converters are inorganic nanocrystals, commonly known as quantum dots, which are nanoparticles (especially quantum dots) of an inorganic semiconductor material (InP, CdSe, CdS, ZnSe, etc.) with a diameter of 2 nm to 8 nm. Limited by the current synthesis and separation technology of quantum dots, the FWHMs of CD-containing quantum dots typically range from 25 nm to 40 nm, which meet the display requirements of NTSC for color purity. Meanwhile, Cd-free quantum dots generally come with larger FWHMs of 35 nm to 75 nm. In addition, the extinction coefficient is generally low, requiring thicker films, the typical 10 μm or more is needed to achieve complete absorption of blue light, which is a great challenge for mass production processes, especially for Samsung's technology of combing blue OLED with red-green quantum dots.

Another promising color conversion material is a perovskite-based emitting material having a narrow FWHM of the emission peak, but still low extinction coefficient.

Therefore, from the industrial perspective, it is urgent to find a material for color converters that maintains the characteristics of the narrow emission spectrum while reducing the thickness of the film.

### SUMMARY

In one aspect, the present disclosure provides a mixture comprising an organic compound H and a perovskite emitter E, where, 1) the emission spectrum of the organic compound H is on the short wavelength side of the absorption spectrum of the perovskite emitter E, and at least partially overlaps with the absorption spectrum of the perovskite emitter E; 2) the perovskite emitter E includes constituent components A, B, and X, where the constituent component A indicates a component positioned at each vertex of a hexahedron having the constituent component B at the center in a perovskite type crystal structure and is a monovalent cation; the constituent component X indicates a component positioned at each vertex of an octahedron having the constituent component B at the center in the perovskite type crystal structure and is an anion; the constituent component B indicates a component positioned at the centers of the hexahedron where the constituent component A is disposed at each vertex and the octahedron where the constituent component X is disposed at each vertex in the perovskite type crystal structure and is a metal cation; preferably, the FWHM of the emission spectrum of the perovskite emitter E≤45 nm.

In addition or alternatively, the perovskite emitter E of the mixture is selected from a compound having any of a three-dimensional structure, a two-dimensional structure, a quasi-two-dimensional structure, or any combination thereof, and the compositional formula of the perovskite emitter E having a three-dimensional structure is represented by ABX_{(3+δ)}, the compositional formula of the perovskite emitter E having a two-dimensional or quasi-two-dimensional structure is represented by A₂BX_{(4+δ)}, where δ is a number which can be changed according to the charge balance of B and is in a range of −0.7 to 0.7.

In addition or alternatively, the mixture further comprises at least one organic resin.

In another aspect, the present disclosure also provides a formulation comprising a mixture as described herein, and at least one solvent.

In yet another aspect, the present disclosure further provides an organic functional film comprising a mixture as described herein.

In yet another aspect, the present disclosure further provides an optoelectronic device comprising a mixture or an organic functional film as described herein.

In yet another aspect, the present disclosure further provides an organic light-emitting device comprising a substrate, a first electrode, an organic light-emitting layer, a second electrode, a color conversion layer, and an encapsulation layer in sequence from bottom to top, the second electrode is at least partially transparent, where 1) the color conversion layer comprises the mixture as described herein; 2) the color conversion layer absorbs 50% or more of the light emitted by the organic light-emitting layer through the second electrode; 3) the emission spectrum of the organic compound H is on the short wavelength side of the absorption spectrum of the perovskite emitter E, and at least partially overlaps with the absorption spectrum of the perovskite emitter E.

Beneficial effect: in the mixture as described herein, the organic compound H has a relatively high extinction coefficient, the perovskite emitter E has a relatively high luminescence efficiency and narrow emission FWHM. Moreover, the energy transfer efficiency between the organic compound H and the perovskite emitter E is high, thereby optimizing separately the absorption and luminescence functions, and facilitating the preparation of a high-efficiency color converter with a thin thickness, meeting the requirements of high color gamut displays. Furthermore, the organic compound H can be selected from the compounds easy to synthesize. Due to the high proportion of the organic compound H in the formulation, the cost could be greatly reduced.

### BRIEF DESCRIPTION OF THE DRAWINGS

FIG. 1 is a schematic view of a red, green and blue (RGB) three-color display device.

### DETAILED DESCRIPTION OF THE EMBODIMENTS

The present disclosure provides a mixture, a formulation, an organic light-emitting device, and the applications thereof in the optoelectronic field.

In order to facilitate understanding of the present disclosure, the present disclosure will be described in detail below with reference to the accompanying drawings, in which the preferred embodiments of the present disclosure are shown. The present disclosure may be embodied in many different forms and is not limited to the embodiments described herein. Rather, these embodiments are provided so that the understanding of the invention of the present disclosure will be more thorough.

Unless otherwise defined, all technical and scientific terms used herein have the same meaning as commonly understood by one of ordinary skill in the art belonging to the present disclosure. The terms used herein in the description of the present disclosure are used only for the purpose of describing specific embodiments and are not intended to be limiting of the present disclosure. As used herein, the term “and/or” includes any and all combinations of one or more of the relevant listed items.

As used herein, the terms “host material”, “matrix material” have the same meaning, and they are interchangeable with each other.

As used herein, the terms “formulation”, “printing ink”, and “ink” have the same meaning, and they are interchangeable with each other.

In one aspect, the present disclosure provides a mixture comprising an organic compound H and a perovskite emitter E, where 1) the emission spectrum of the organic compound H is on the short wavelength side of the absorption spectrum of the perovskite emitter E, and at least partially overlaps with the absorption spectrum of the perovskite emitter E; 2) the perovskite emitter E includes constituent components A, B, and X, where the constituent component A indicates a component positioned at each vertex of a hexahedron having the constituent component B at the center in a perovskite type crystal structure and is a monovalent cation; the constituent component X indicates a component positioned at each vertex of an octahedron having the constituent component B at the center in the perovskite type crystal structure and is an anion; the constituent component B indicates a component positioned at the centers of the hexahedron where the constituent component A is disposed at each vertex and the octahedron where the constituent component X is disposed at each vertex in the perovskite type crystal structure and is a metal cation; 3) the FWHM of the emission spectrum of the perovskite emitter E≤45 nm.

In some embodiments, the FWHM of the emission spectrum of the perovskite emitter E≤45 nm, preferably ≤40 nm, more preferably ≤35 nm, further preferably ≤30 nm, and most preferably ≤25 nm.

In some embodiments, the photoluminescence quantum efficiency (PLQY) of the perovskite emitter E≥60%, preferably ≥65%, more preferably ≥70%, and most preferably ≥80%.

In some embodiments, the perovskite emitter E is selected from a compound having any of a three-dimensional structure, a two-dimensional structure, a quasi-two-dimensional structure, or any combination thereof, and the compositional formula of the perovskite emitter E having a three-dimensional structure is represented by ABX_{(3+δ)}, the compositional formula of the perovskite emitter E having a two-dimensional or quasi-two-dimensional structure is represented by A₂BX_{(4+δ)}, where δ is a number which can be changed according to the charge balance of B and is in a range of −0.7 to 0.7.

In some embodiments, the perovskite emitter is a nanoemitter.

In some embodiments, the average particle size of the perovskite nanoemitter is in the range of 1 nm to 1000 nm. In some embodiments, the average particle size of the perovskite nanoemitter is in the range of 1 nm to 100 nm. In some embodiments, the average particle size of the perovskite nanoemitter is in the range of 1 nm to 20 nm, preferably in the range of 1 nm to 10 nm.

In some embodiments, the constituent component A of the perovskite emitter E as a monovalent cation may be selected from a cesium ion, an organic ammonium ion, or an amidinium ion.

In some embodiments, in a case where the constituent component A of the perovskite emitter E is a cesium ion, an organic ammonium ion having 3 or less carbon atoms, or an amidinium ion having 3 or less carbon atoms, the perovskite emitter E has a three-dimensional structure represented by ABX_{(3+δ)}.

In some embodiments, the constituent component A is preferably selected from a cesium ion or an organic ammonium ion.

In some embodiments, the constituent component A in multiple occurrences, is independently selected from cesium ions, or cations of formula (I); In some embodiments, the organic ammonium ion comprises a cation of formula (I).

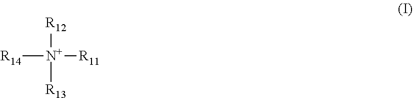

Where R₁₁ to R₁₄ are independently selected from the group consisting of —H, -D, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, and R₁₁ to R₁₄ are not all H or D.

In a case where R₁₁ to R₁₄ represent an alkyl group, the number of carbon atoms of each of R₁₁ to R₁₄ is typically independently in a range of 1 to 20, preferably in a range of 1 to 4, more preferably in a range of 1 to 3, further preferably 1.

In a case where R₁₁ to R₁₄ represent a cycloalkyl group, the number of carbon atoms of each of R₁₁ to R₁₄ is typically independently in a range of 3 to 30, preferably in a range of 3 to 11, more preferably in a range of 3 to 8. The number of carbon atoms include the number of carbon atoms in a substituent.

Preferably, each of R₁₁ to R₁₄ is independently selected from a hydrogen atom or an alkyl group.

A perovskite compound having a three-dimensional structure with high emission intensity can be obtained by decreasing the number of alkyl groups and cycloalkyl groups which can be included in formula (I) and decreasing the number of carbon atoms in the alkyl group and the cycloalkyl group.

In a case where the number of carbon atoms in the alkyl group or the cycloalkyl group is more than 4, a compound partially or entirely having a two-dimensional and/or quasi-two-dimensional (quasi-2D) perovskite type crystal structure can be obtained. In a case where a two-dimensional perovskite type crystal structure is laminated at infinity, the structure becomes the same as the three-dimensional perovskite type crystal structure (reference literature: P. P. Boix et al., J. Phys. Chem. Lett. 2015, 6, 898-907).

It is preferable that the total number of carbon atoms in the alkyl group represented by R₁₁ to R₁₄ is in a range of 1 to 4. It is more preferable that the total number of carbon atoms in the cycloalkyl group represented by R₁₁ to R₁₄ is in a range of 3 to 4. It is further preferable that one of R₁₁ to R₁₄ represents a C₁-C₃ alkyl and three of R₁₁ to R₁₄ represent a hydrogen atom.

Examples of the alkyl group as R₁₁ to R₁₄ include a methyl group, an ethyl group, an n-propyl group, an isopropyl group, an n-butyl group, an isobutyl group, a sec-butyl group, a tert-butyl group, an n-pentyl group, an isopentyl group, a neopentyl group, a tert-pentyl group, a 1-methylbutyl group, an n-hexyl group, a 2-methylpentyl group, a 3-methylpentyl group, a 2,2-dimethylbutyl group, a 2,3-dimethylbutyl group, an n-heptyl group, a 2-methylhexyl group, a 3-methylhexyl group, a 2,2-dimethylpentyl group, a 2,3-dimethylpentyl group, a 2,4-dimethylpentyl group, a 3,3-dimethylpentyl group, a 3-ethylpentyl group, a 2,2,3-trimethylbutyl group, an n-octyl group, an isooctyl group, a 2-ethylhexyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, or an icosyl group.

Examples of the cycloalkyl group as R₁₁ to R₁₄ include a cyclopropyl group, a cyclobutyl group, a cyclopentyl group, a cyclohexyl group, a cycloheptyl group, a cyclooctyl group, a cyclononyl group, a cyclodecyl group, a norbornyl group, an isobornyl group, a 1-adamantyl group, a 2-adamantyl group, or a tricyclodecyl group.

As the organic ammonium ion represented by the constituent component A, CH₃NH₃⁺ (also referred to as a methylammonium ion), C₂H₅NH₃⁺ (also referred to as an ethylammonium ion), or C₃H₇NH₃⁺ (also referred to as a propylammonium ion) is preferable, CH₃NH₃⁺ or C₂H₅NH₃⁺ is more preferable, CH₃NH₃⁺ is further preferable.

In some embodiments, the constituent component A in multiple occurrences, is an amidinium ion of formula (II), the cation is preferably an amidinium ion:

(R₁₅R₁₆N═CH—NR₁₇R₁₈)⁺ (II)

Where R₁₅ to R₁₈ are independently selected from the group consisting of —H, -D, C₁-C₂₀ linear alkyl groups, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group.

The alkyl group represented by each of R₁₅ to R₁₈ may be independently linear or branched and may have an amino group as a substituent.

The number of carbon atoms of the alkyl group represented by each of independent R₁₅ to R₁₈ is typically in a range of 1 to 20, preferably in a range of 1 to 4, more preferably in a range of 1 to 3.

The number of carbon atoms of the cycloalkyl group represented by each of independent R₁₅ to R₁₈ is typically in a range of 3 to 30, preferably in a range of 3 to 11, more preferably in a range of 3 to 8.

As the group represented by each of independent R₁₅ to R₁₈, a hydrogen atom or an alkyl group is preferable.

Specific examples of the alkyl group as R₁₅ to R₁₈ are the same as those provided as exemplary examples of the alkyl group represented by each of independent R₁₁ to R₁₄.

Specific examples of the cycloalkyl group as R₁₅ to R₁₈ are the same as those provided as exemplary examples of the cycloalkyl group represented by each of independent R₁₁ to R₁₄.

A perovskite compound having a three-dimensional structure with high emission intensity can be obtained by decreasing the number of alkyl groups and cycloalkyl groups which can be included in formula (II) and decreasing the number of carbon atoms in the alkyl group and the cycloalkyl group.

In a case where the number of carbon atoms in the alkyl group or the cycloalkyl group is more than 4, a compound partially or entirely having a two-dimensional and/or quasi-two-dimensional (quasi-2D) perovskite type crystal structure can be obtained. In a case where a two-dimensional perovskite type crystal structure is laminated at infinity, the structure becomes the same as the three-dimensional perovskite type crystal structure (reference literature: P. P. Boix et al., J. Phys. Chem. Lett. 2015, 6, 898-907).

In addition, the total number of carbon atoms in the alkyl group represented by R₁₅ to R₁₈ is preferably in a range of 1 to 4, and the total number of carbon atoms in the cycloalkyl group represented by R₁₅ to R₁₈ is preferably in a range of 3 to 4. More preferably, R₁₅ represents a C₁-C₃ alkyl group, and each of R₁₆ to R₁₈ represents a hydrogen atom.

In the perovskite emitter E, the constituent component B indicates a component positioned at the centers of the hexahedron where the constituent component A is disposed at each vertex and the octahedron where the constituent component X is disposed at each vertex in the perovskite type crystal structure and is a metal ion. The metal ion as the constituent component B may be an ion formed of one or more selected from the group consisting of a monovalent metal ion, a divalent metal ion, and a trivalent metal ion. The constituent component B preferably contains a divalent metal ion, more preferably contains lead and tin ion.

In the perovskite emitter E, the constituent component X indicates an anion component positioned at each vertex of an octahedron having the constituent component B at the center in the perovskite type crystal structure. In some embodiments, the constituent component X in multiple occurrences, is independently selected from a halide ion or a thiocyanate ion. In some embodiments, the constituent component X is selected from a chloride ion, a bromide ion, a fluoride ion, an iodide ion, or a thiocyanate ion.

The constituent component X can be appropriately selected according to a desired emission wavelength.

In a case where the constituent component X is more than two kinds of halide ions, the content ratio of the halide ions can be appropriately selected according to the emission wavelength. For example, a combination of a bromide ion and a chloride ion, or a combination of a bromide ion and an iodide ion can be employed.

In the case where the perovskite emitter E is a three-dimensional structure, the three-dimensional network of the co-vertex octahedron having the constituent component B as the center and the constituent component X as the vertex is represented by BX₆.

In the case where the perovskite emitter E is a two-dimensional structure, the octahedron is represented by BX₆ with the constituent component B as the center and the constituent component X as the vertex, having four vertices in the same plane with the constituent component X, thereby forming a layer consisting of BX₆ of the two-dimensional connection and an alternate laminate structure consisting of the constituent component A.

The constituent component B is a metal cation that can have octahedral coordination with the constituent component X.

In some embodiments, the perovskite emitter E is an organic-inorganic perovskite.

The organic-inorganic perovskite is an ionic compound comprising organic cations, divalent metal ions, and halogen ions, and may contain a monovalent cation and other ions. The other ions may be organic ions or inorganic ions. The organic-inorganic perovskite comprising an inorganic semiconductor layer and an organic component may be any of two-dimensional perovskite, quasi-two-dimensional perovskite, and three-dimensional perovskite; preferably be two-dimensional perovskite or quasi-two-dimensional perovskite; more preferably be quasi-two-dimensional perovskite. Where the two-dimensional perovskite has an inorganic semiconductor layer formed by a two-dimensionally arrangement of inorganic skeleton equivalent to the octahedral portion of the perovskite-type structure and an organic layer in which organic cations are arranged with the cationic groups facing the inorganic semiconductor layer side, the quasi-two-dimensional perovskite with a layer comprising two-dimensional perovskite inorganic semiconductor layers and organic layers, and the inorganic semiconductor layers have two-dimensionally arrangement of two or more layers which is disposed at each vertex in the cubic crystal of the perovskite-type structure and is a monovalent cation.

In some embodiments, the perovskite emitter E is a quasi-two-dimensional organic-inorganic perovskite as a compound of formula (III).

R₂A_{n-1Bn}X₃ₙ₊₁ (III)

Where R represents a monovalent organic cation; A, B, and X are identically defined as described above. n is an integer greater than 2. Two Rs, multiple Bs, and multiple Xs may be same or different from each other. In the presence of more than one A, A may be the same or different from each other.

In the compound of formula (III), the inorganic semiconductor layer comprises a lattice represented by Aₙ₋₁BₙX₃ₙ₊₁, and the organic layer comprises a monovalent organic cation represented by R. n corresponds to the number of layer stacks of the two-dimensional arranged structure in the inorganic semiconductor layer, and is preferably an integer from 2 to 100.

The monovalent organic cation is represented by R preferably comprising an aromatic ring, more preferably comprising an alkylene group and an aromatic ring, even more preferably comprising a structure which contains an alkylene group linked to an aromatic ring, further preferably comprising an ammonium group in which an alkylene group is linked to an aromatic ring, and particularly preferably comprising an ammonium group of formula (IV).

Ar(CH₂)ₙ₁NH₃⁺ (IV)

Where Ar represents an aromatic ring, n1 is an integer from 1 to 20.

The aromatic ring in the organic cation may be an aromatic hydrocarbon or an aromatic heterocyclic ring, but preferably an aromatic hydrocarbon. As the heteroatom of the aromatic heterocycle, it may be a nitrogen atom, an oxygen atom, a sulfur atom, etc. As the aromatic hydrocarbon, it is preferably a benzene ring or a condensed polycyclic hydrocarbon having a plurality of benzene ring condensation structures, more preferably a benzene ring, a naphthalene ring, a phenanthrene group, an anthracene ring, a chrysene ring, a tetraphenylene ring, or a perylene ring, preferably a benzene ring, or a naphthalene ring, further preferably a benzene ring. As an aromatic heterocycle, preferably a pyridine ring, a pyrazine ring, a pyrimidine ring, a pyridazine ring, a pyrrole ring, a thiophene ring, a furan ring, a carbazole ring, a triazine ring, more preferably a pyridine ring, a pyrazine ring, a pyrimidine ring, or a pyridazine ring, further preferably a pyridine ring. The aromatic ring in the organic cation may be substituted with any substituent, for example an alkyl group, an aryl group, a halogen atom (preferably a fluorine atom), etc., and the hydrogen atom present in the aromatic ring or in a substituent bonded to the aromatic ring may also be a deuterium atom.

The monovalent cation represented by A may be an organic cation or an inorganic cation. Examples of monovalent cations include a formamide, an ammonium, a cesium, etc.; and formamide is preferable.

The divalent metal ion represented by constituent component B in multiple occurrences, may be independently selected from Cu²⁺, Ni²⁺, Mn²⁺, Fe²⁺, Co²⁺, Pd²⁺, Ge²⁺, Sn²⁺, Pb²⁺, Eu²⁺, etc., preferably selected from Sn²⁺, or Pb²⁺, more preferably selected from Pb²⁺.

The halogen ion represented by X may be selected from the individual ions of fluorine, chlorine, bromine, or iodine. The halogen ions represented by the plurality of Xs may be all the same, or a combination of two or three types of the halogen ions.

Preferred examples of the compounds of formula (IV) are the compounds with the following formulas (V) and (VI).

PEA₂FAₙ₋₁PbₙBr₃ₙ₊₁ (V)

PEA₂MAₙ₋₁PbₙBr₃ₙ₊₁ (VI)

Where PEA represents phenethylammonium, FA represents formamide, MA represents methylammonium, n is an integer greater than 2.

In the present disclosure, the crystal structure of the perovskite emitter E can be confirmed by an X-ray diffraction pattern.

In a case of the perovskite emitter E having the three-dimensional structure, typically, it is preferable that a peak derived from (hk1)=(001) is confirmed at a position where 2 θ is in a range of 12° to 18°, or a peak derived from (hk1)=(110) is confirmed at a position where 2 θ is in a range of 18° to 25° in the X ray diffraction pattern. It is more preferable that a peak derived from (hk1)=(001) is confirmed at a position where 2 θ is in a range of 13° to 16°, or a peak derived from (hk1)=(110) is confirmed at a position where 2 θ is in a range of 20° to 23° in the X ray diffraction pattern.

In a case of the perovskite emitter E having the perovskite type crystal structure of the two-dimensional structure, typically, it is preferable that a peak derived from (hk1)=(002) is confirmed at a position where 2 θ is in a range of 1° to 10° in the X ray diffraction pattern. It is more preferable that a peak derived from (hk1)=(002) is confirmed at a position where 2 θ is in a range of 2° to 8°.

Specific examples of the perovskite emitters E having the perovskite type crystal structure of the three-dimensional structure represented by ABX_{(3+δ)} are as follows, but not limited thereto.

CH₃NH₃PbBr₃, CH₃NH₃PbCl₃, CH₃NH₃PbI₃, CH₃NH₃PbBr_{(3-y)}I_{y} (0<y<3), CH₃NH₃PbBr_{(3-y)} Cl_{y}(0<y<3), (H₂N═CH—NH₂)PbBr₃, (H₂N═CH—NH₂)PbCl₃, (H₂N═CH—NH₂)PbI₃, CH₃NH₃Pb₍₁₋ₐ₎ CaₐBr₃ (0<a≤0.7), CH₃NH₃Pb₍₁₋ₐ₎SrₐBr₃ (0<a≤0.7), CH₃NH₃Pb₍₁₋ₐ₎LaₐBr_{(3+δ)}(0<α≤0.7, 0<δ≤0.7), CH₃NH₃Pb₍₁₋ₐ₎BaₐBr₃ (0<a≤0.7), CH₃NH₃Pb₍₁₋ₐ₎DyₐBr_{(3+δ)} (0<a≤0.7, 0<δ≤0.7), CH₃NH₃Pb₍₁₋ₐ₎ NaₐBr_{(3+δ)} (0<a≤0.7, −0.7≤δ<0), CH₃NH₃Pb₍₁₋ₐ₎LiₐBr_{(3+δ)} (0<a≤0.7, −0.7≤δ<0), CsPb₍₁₋ₐ₎NaₐBr_{(3+δ)} (0<a≤0.7, −0.7≤δ<0), CsPb₍₁₋ₐ₎LiₐBr_{(3+δ)} (0<a≤0.7, −0.7<δ≤0), CH₃NH₃Pb₍₁₋ₐ₎NaₐBr_{(3+δ-y)}I_{y} (0<a≤0.7, −0.7≤δ<0, 0<y<3), CH₃NH₃Pb₍₁₋ₐ₎LiₐBr_{(3+δ-y)}I_{y} (0<a≤0.7, −0.7<δ≤0, 0<y<3), CH₃NH₃Pb₍₁₋ₐ₎NaₐBr_{(3+δ-y)}Cl_{y} (0<a≤0.7, −0.7≤δ<0, 0<y<3), CH₃NH₃Pb₍₁₋ₐ₎LiₐBr_{(3+δ-y)}Cl_{y} (0<a≤0.7, −0.7≤δ<0, 0<y<3), (H₂N═CH—NH₂)Pb₍₁₋ₐ₎NaₐBr_{(3+δ)} (0<a≤0.7, −0.7≤δ<0), (H₂N═CH—NH₂)Pb₍₁₋ₐ₎ LiₐBr_{(3+δ)}(0<a≤0.7, −0.7≤δ<0), (H₂N═CH—NH₂)Pb₍₁₋ₐ₎NaₐBr_{(3+δ-y)}I_{y} (0<a≤0.7, −0.7≤δ<0, 0<y<3), (H₂N═CH—NH₂)Pb₍₁₋ₐ₎NaₐBr_{(3+δ-y)}Cl_{y} (0<a≤0.7, −0.7≤δ<0, 0<y<3), CsPbBr₃, CsPbCl₃, CsPbI₃, CsPbBr_{(3-y)}I_{y} (0<y<3), CsPbBr_{(3-y)}Cl_{y} (0<y<3), CH₃NH₃PbBr_{(3-y)}Cl_{y} (0<y<3), CH₃NH₃Pb₍₁₋ₐ₎ZnₐBr₃ (0<a≤0.7), CH₃NH₃Pb₍₁₋ₐ₎AlₐBr_{(3+δ)} (0<a≤0.7, 0≤δ<0.7), CH₃NH₃Pb₍₁₋ₐ₎CoₐBr₃ (0<a≤0.7), CH₃NH₃Pb₍₁₋ₐ₎MnₐBr₃ (0<a≤0.7), CH₃NH₃Pb₍₁₋ₐ₎MgₐBr₃ (0<a≤0.7), CsPb₍₁₋ₐ₎ZnₐBr₃ (0<a≤0.7), CsPb₍₁₋ₐ₎AlₐBr_{(3+δ)} (0<a≤0.7, 0≤δ≤0.7), CsPb₍₁₋ₐ₎CoₐBr₃ (0<a≤0.7), CsPb₍₁₋ₐ₎MnₐBr₃ (0<a≤0.7), CsPb₍₁₋ₐ₎MgₐBr₃ (0<a≤0.7), CH₃NH₃Pb₍₁₋ₐ₎ZnₐBr_{(3-y)}I_{y} (0<a≤0.7, 0<y<3), CH₃NH₃Pb₍₁₋ₐ₎AlₐBr_{(3+δ-y)} I_{y} (0<a≤0.7, 0<δ≤0.7, 0<y<3), CH₃NH₃Pb₍₁₋ₐ₎CoₐBr_{(3-y)}I_{y} (0<a≤0.7, 0<y<3), CH₃NH₃Pb₍₁₋ₐ₎MnₐBr_{(3-y)}I_{y} (0<a≤0.7, 0<y<3), CH₃NH₃Pb₍₁₋ₐ₎MgₐBr_{(3-y)}I_{y} (0<a≤0.7, 0<y<3), CH₃NH₃Pb₍₁₋ₐ₎ZnₐBr_{(3-y)}Cl_{y} (0<a≤0.7, 0<y<3), CH₃NH₃Pb₍₁₋ₐ₎AlₐBr_{(3+δ-y)}Cl_{y} (0<a≤0.7, 0<δ≤0.7, 0<y<3), CH₃NH₃Pb₍₁₋ₐ₎CoₐBr_{(3+δ-y)} Cl_{y} (0<a≤0.7, 0<y<3), CH₃NH₃Pb₍₁₋ₐ₎MnₐBr_{(3-y)}Cl_{y} (0<a≤0.7, 0<y<3), CH₃NH₃Pb₍₁₋ₐ₎MgₐBr_{(3-y)}Cl_{y} (0<a≤0.7, 0<y<3), (H₂N═CH—NH₂)ZnₐBr₃ (0<a≤0.7), (H₂N═CH—NH2)MgₐBr₃ (0<a≤0.7), (H₂N═CH—NH₂)Pb₍₁₋ₐ₎ZnₐBr_{(3-y)}I_{y} (0<a≤0.7, 0<y<3), (H₂N═CH—NH₂)Pb₍₁₋ₐ₎ZnₐBr_{(3-y)}Cl_{y} (0<a≤0.7, 0<y<3), etc.

The preferred perovskite emitter E having the three-dimensional structure is CsPbBr₃, CsPbBr_{(3-y)}I_{y} (0<y<3).

(C₄H₉NH₃)₂PbBr₄, (C₄H₉NH₃)₂PbCl₄, (C₄H₉NH₃)₂PbI₄, (C₇H₁₅NH₃)₂PbBr₄, (C₇H₁₅NH₃)₂PbCl₄, (C₇H₁₅NH₃)₂PbI₄, (C₄H₉NH₃)₂Pb₍₁₋ₐ₎LiₐBr_{(4+δ)} (0<a≤0.7, −0.7≤δ≤0), (C₄H₉NH₃)₂Pb₍₁₋ₐ₎NaₐBr_{(4+δ)} (0<a≤0.7, −0.7≤δ≤0), (C₄H₉NH₃)₂Pb₍₁₋ₐ₎RbₐBr_{(4+δ)} (0<a≤0.7, −0.7≤δ≤0), (C₇H₁₅NH₃)₂Pb₍₁₋ₐ₎NaₐBr_{(4+δ)} (0<a≤0.7, −0.7≤δ≤0), (C₇H₁₅NH₃)₂Pb₍₁₋ₐ₎LiₐBr_{(4+δ)} (0<a≤0.7, −0.7≤δ≤0), (C₇H₁₅NH₃)₂Pb₍₁₋ₐ₎RbₐBr_{(4+δ)} (0<a≤0.7, −0.7≤δ≤0), (C₄H₉NH₃)₂Pb₍₁₋ₐ₎NaₐBr_{(4+δ-y)}I_{y} (0<a≤0.7, −0.7≤δ≤0, 0<y<4), (C₄H₉NH₃)₂Pb₍₁₋ₐ₎LiₐBr_{(4+δ-y)}I_{y} (0<a≤0.7, −0.7≤δ≤0, 0<y<4), (C₄H₉NH₃)₂Pb₍₁₋ₐ₎RbₐBr_{(4+δ-y)}I_{y} (0<a≤0.7, −0.7≤δ≤0, 0<y<4), (C₄H₉NH₃)₂Pb₍₁₋ₐ₎NaₐBr_{(4+δ-y)}Cl_{y} (0<a≤0.7, −0.7≤δ<0, 0<y<4), (C₄H₉NH₃)₂Pb₍₁₋ₐ₎LiₐBr_{(4+δ-y)}Cl_{y}(0<a≤0.7, −0.7≤δ≤0, 0<y<4), (C₄H₉NH₃)₂Pb₍₁₋ₐ₎RbₐBr_{(4+δ-y)}Cl_{y} (0<a≤0.7, −0.7≤δ≤0, 0<y<4), (C₄H₉NH₃)₂PbBr₄, (C₇H₁₅NH₃)₂PbBr₄, (C₄H₉NH₃)₂PbBr_{(4-y)}Cl_{y} (0<y<4), (C₄H₉NH₃)₂PbBr_{(4-y)}I_{y} (0<y<4), (C₄H₉NH₃)₂Pb₍₁₋ₐ₎ZnₐBr₄ (0<a≤0.7), (C₄H₉NH₃)₂Pb₍₁₋ₐ₎MgₐBr₄ (0<a≤0.7), (C₄H₉NH₃)₂Pb₍₁₋ₐ₎CoₐBr₄ (0<a≤0.7), (C₄H₉NH₃)₂Pb₍₁₋ₐ₎MnₐBr₄ (0<a≤0.7), (C₇H₁₅NH₃)₂Pb₍₁₋ₐ₎ZnₐBr₄ (0<a≤0.7), (C₇H₁₅NH₃)₂Pb₍₁₋ₐ₎MgₐBr₄ (0<a≤0.7), (C₇H₁₅NH₃)₂Pb₍₁₋ₐ₎CoₐBr₄ (0<a≤0.7), (C₇H₁₅NH₃)₂Pb₍₁₋ₐ₎ MnₐBr₄ (0<a≤0.7), (C₄H₉NH₃)₂Pb₍₁₋ₐ₎ZnₐBr_{(4-y)}I_{y} (0<a≤0.7, 0<y<4), (C₄H₉NH₃)₂Pb₍₁₋ₐ₎MgₐBr_{(4-y)} I_{y} (0<a≤0.7, 0<y<4), (C₄H₉NH₃)₂Pb₍₁₋ₐ₎CoₐBr_{(4-y)}I_{y} (0<a≤0.7, 0<y<4), (C₄H₉NH₃)₂Pb₍₁₋ₐ₎MnₐBr_{(4-y)}I_{y}(0<a≤0.7, 0<y<4), (C₄H₉NH₃)₂Pb₍₁₋ₐ₎ZnₐBr_{(4-y)}Cl_{y} (0<a≤0.7, 0<y<4), (C₄H₉NH₃)₂Pb₍₁₋ₐ₎ MgₐBr_{(4-y)}Cl_{y} (0<a≤0.7, 0<y<4), (C₄H₉NH₃)₂Pb₍₁₋ₐ₎CoₐBr_{(4-y)}Cl_{y} (0<a≤0.7, 0<y<4), (C₄H₉NH₃)₂Pb₍₁₋ₐ₎MnₐBr_{(4-y)}Cl_{y} (0<a≤0.7, 0<y<4)

Preferably, the perovskite emitter E emits light in the visible wavelength range.

In a case where the constituent component X is a bromide ion, the perovskite emitter E is capable of emitting fluorescence having a maximum peak of the intensity in a wavelength range of typically 480 nm or greater, preferably 500 nm or greater, and more preferably 510 nm or greater; and typically 700 nm or less, preferably 600 nm or less, and more preferably 580 nm or less.

As another aspect of the present disclosure, in a case where the constituent component X is a bromide ion, the perovskite emitter E is capable of emitting fluorescence having a maximum peak of the intensity in a wavelength range of 480 nm to 700 nm, preferably in a wavelength range of 500 nm to 600 nm, and more preferably in a wavelength range of 510 nm to 580 nm.

In a case where the constituent component X is an iodide ion, the perovskite emitter E is capable of emitting fluorescence having a maximum peak of the intensity in a wavelength range of typically 520 nm or greater, preferably 530 nm or greater, and more preferably 540 nm or greater; and typically 800 nm or less, preferably 750 nm or less, and more preferably 730 nm or less.

As another aspect of the present disclosure, in a case where the constituent component X is an iodide ion, the perovskite emitter E is capable of emitting fluorescence having a maximum peak of the intensity in a wavelength range of 520 nm to 800 nm, preferably in a wavelength range of 530 nm to 750 nm, and more preferably in a wavelength range of 540 nm to 730 nm.

In a case where the constituent component X is a chloride ion, the perovskite emitter E is capable of emitting fluorescence having a maximum peak of the intensity in a wavelength range of typically 300 nm or greater, preferably 310 nm or greater, and more preferably 330 nm or greater; and typically 600 nm or less, preferably 580 nm or less, and more preferably 550 nm or less.

As another aspect of the present disclosure, in a case where the constituent component X is a chloride ion, the perovskite emitter E is capable of emitting fluorescence having a maximum peak of the intensity in a wavelength range of 300 nm to 600 nm, preferably in a wavelength range of 310 nm to 580 nm, and more preferably in a wavelength range of 330 nm to 550 nm.

Other material syntheses, process, device techniques, applications, and information useful to the present disclosure relating to perovskite materials are described in the following patents CN112029493A, CN113784925A, CN113748088A, CN111417643A, CN110799626A, CN110088231A, CN107924933A, CN107743530A, CN108473865A. The patent documents listed above are specially incorporated herein by reference in their entirety.

In the mixture as described herein, the organic compound H has relatively high extinction coefficient. The extinction coefficient is also known as the molar extinction coefficient, which refers to the absorption coefficient at a concentration of 1 mol/L, and is represented by the symbol ε, in unit of Lmol⁻¹ cm⁻¹. The extinction coefficient (ε) preferably ≥1*10³; more preferably ≥1*10⁴; particularly preferably ≥5*10⁴; and most preferably ≥1*10⁵. Preferably, the extinction coefficient refers to the extinction coefficient at the wavelength corresponding to the absorption peak.

In some embodiments, the absorption spectrum of the organic compound H is between 380 nm and 500 nm.

In some embodiments, the emission spectrum of the organic compound H is between 440 nm and 500 nm.

In some embodiments, the wavelength of the emission peak of the organic compound H<500 nm.

In some embodiments, the emission spectrum of the organic compound H is between 500 nm and 580 nm.

As used herein, the energy level structure of the organic material, triplet energy level (T1), singlet energy level (S1), highest occupied molecular orbital (HOMO), lowest unoccupied molecular orbital (LUMO), and oscillator strength f play key roles on its optoelectronic performance and stability. The determination of these parameters is introduced as follows.

HOMO and LUMO energy levels can be measured by optoelectronic effect, for example by XPS (X-ray photoelectron spectroscopy), UPS (UV photoelectron spectroscopy), or by cyclic voltammetry (hereinafter referred to as CV). Recently, quantum chemical methods, such as density functional theory (hereinafter referred to as DFT) are becoming effective method for calculating the molecular orbital energy levels.

The triplet energy level T1 of an organic material can be measured by low-temperature time-resolved spectroscopy, or calculated by quantum simulation (for example, by Time-dependent DFT), for instance with the commercial software Gaussian 03W (Gaussian Inc.), the specific simulation method as described below.

The singlet energy level S1 of the organic material can be determined by the absorption spectrum or the emission spectrum, and can also be calculated by quantum simulation (such as Time-dependent DFT); the oscillator strength f can also be calculated by quantum simulation (such as Time-dependent DFT)

It should be noted that the absolute values of HOMO, LUMO, T1 and S1 may vary depending on the measurement method or calculation method used. Even for the same method, different ways of evaluation, for example, using either the onset or peak value of a CV curve as reference, may result in different (HOMO/LUMO) values. Therefore, reasonable and meaningful comparison should be carried out by using the same measurement and evaluation methods. In the embodiments of the present disclosure, the values of HOMO, LUMO, T1 and S1 are based on the Time-dependent DFT simulation, which however should not exclude the applications of other measurement or calculation methods.

Preferably, the organic compound H as described herein has relatively large S1−T1, where the S1−T1 generally ≥0.70 eV, preferably ≥0.80 eV, more preferably ≥0.90 eV, further preferably ≥1.00 eV, and most preferably ≥1.10 eV.

In some embodiments, the organic compound H has relatively large ΔHOMO and/or ΔLUMO, generally ≥0.50 eV, preferably ≥0.60 eV, more preferably ≥0.70 eV, further preferably ≥0.80 eV, and most preferably ≥0.90 eV; where ΔHOMO=HOMO−(HOMO−1), ΔLUMO=(LUMO+1)−LUMO.

For the purposes of the present disclosure, (HOMO−1) is defined as the energy level of the second highest occupied molecular orbital, (HOMO−2) is defined as the energy level of the third highest occupied molecular orbital, and so on. (LUMO+1) is defined as the energy level of the second lowest unoccupied molecular orbital, (LUMO+2) is defined as the energy level of the third lowest occupied molecular orbital, and so on; these energy levels can be determined by the following simulation method.

In some embodiments, the organic compound H has relatively large oscillator strength f(Sn) (n≥1); f(S1) generally ≥0.20 eV, preferably ≥0.30 eV, more preferably ≥0.40 eV, further preferably ≥0.50 eV, and most preferably ≥0.60 eV.

In some embodiments, the organic compound H has relatively low HOMO, generally ≤−5.0 eV, preferably ≤−5.1 eV, more preferably ≤−5.2 eV, further preferably ≤−5.3 eV, and most preferably ≤−5.4 eV.

In some embodiments, the organic compound H has relatively high LUMO, generally ≥−3.0 eV, preferably ≥−2.9 eV, more preferably ≥−2.8 eV, further preferably ≥−2.7 eV, and most preferably ≥−2.6 eV.

The suitable organic compounds H may be selected from organic small molecules, polymers, or metal complexes.

In some embodiments, the organic compound H may be selected from cyclic aromatic hydrocarbon compound, such as benzene, biphenyl, triphenylbenzene, benzophenanthrene, triphenylene, anthracene, phenalene, phenanthrene, fluorene, pyrene, chrysene, perylene, azulene. The organic compound used as the singlet host material may be also selected from aromatic heterocyclic compound, such as dibenzothiophene, dibenzofuran, dibenzothiophene, furan, thiophene, benzofuran, benzothiophene, benzoselenophene, carbazole, indocarbazole, pyridindole, pyrroledipyridine, pyrazole, imidazole, triazole, isoxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indolizine, benzoxazole, Benzoisoxazole benzothiazole, quinoline, isoquinoline, cinnoline, quinazoline, quinoxaline, naphthalene, phthalein pteridine, xanthene, acridine, phenazine, phenothiazine, phenoxazine, benzofuranopyridine, furandipyridine, benzothienopyridine, thiophenedipyridine, benzoselenophenopyridine, or selenophenodipyridine. The organic compound used as the singlet host material may be selected from groups containing 2 to 10 ring structures, which may be the same or different types of cyclic aryl or heterocyclic aryl, and are linked to each other directly or by at least one of the following groups, such as oxygen atom, nitrogen atom, sulfur atom, silicon atom, phosphorus atom, boron atom, chain structure unit, or aliphatic ring group.

In some embodiments, the organic compound H may be selected from the compounds comprising at least one of the following groups:

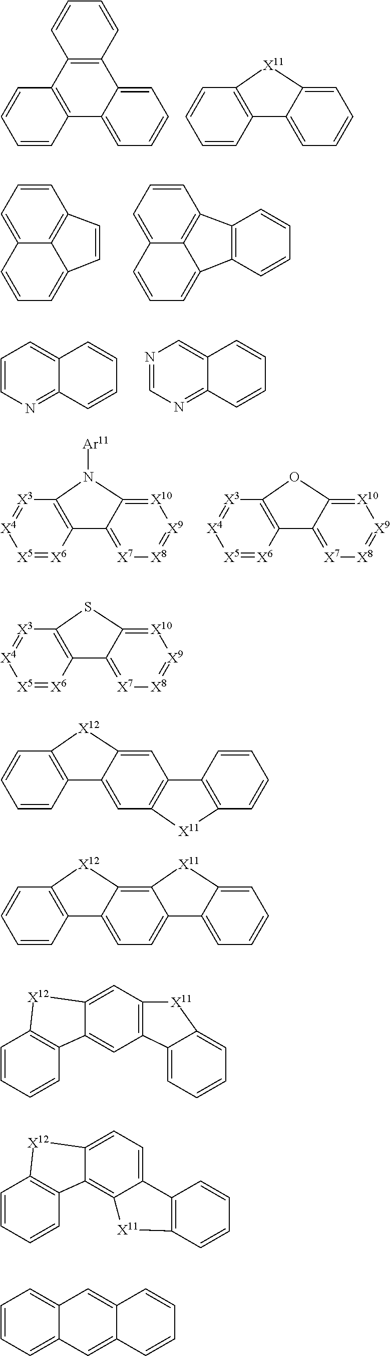

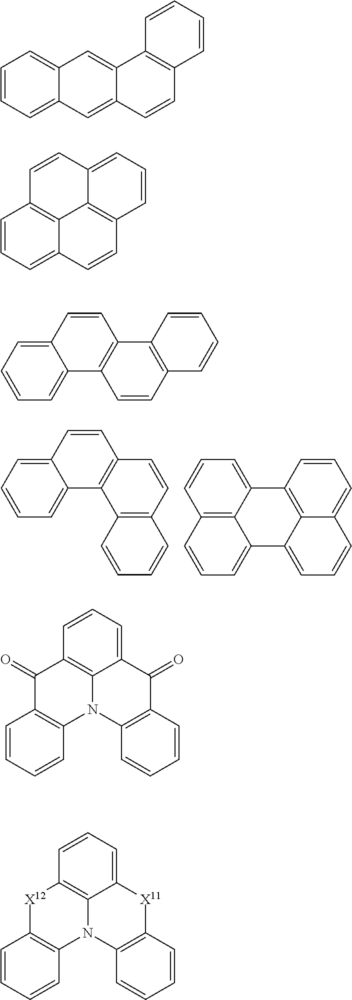

Where Ar¹¹ is aryl or heteroaryl; each of X³ to X¹⁰ is CR¹ or N; X¹¹ and X¹² are independently selected from CR¹R², NR¹ or O; R¹ and R² are independently selected from the group consisting of —H, -D, C₁-C₂₀ linear alkyl groups, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ substituted ketone group, a C₂-C₂₀ alkoxycarbonyl group, a C₇-C₂₀ aryloxycarbonyl group, a cyano group (—CN), a carbamoyl group (—C(═O)NH₂), a haloformyl group (—C(═O)—X where X represents a halogen atom), a formyl group (—C(═O)—H), an isocyano group, an isocyanate group, a thiocyanate group, an isothiocyanate group, a hydroxyl group, a nitro group, —NO₂, —CF₃, —Cl, —Br, —F, —I, a cross-linkable group, a substituted/unsubstituted aromatic or heteroaromatic group containing 5 to 40 ring atoms, an aryloxy or heteroaryloxy group containing 5 to 40 ring atoms, an arylamine or heteroarylamine group containing 5 to 40 ring atoms, and a disubstituted unit in any position of the above substituents or a combination thereof, where one or more R¹-R² may form a monocyclic or polycyclic aliphatic or aromatic ring system with each other and/or with the rings bonded thereto.

In some embodiments, the organic compound H comprising a structure of one of formulas (III-I)-(III-V):

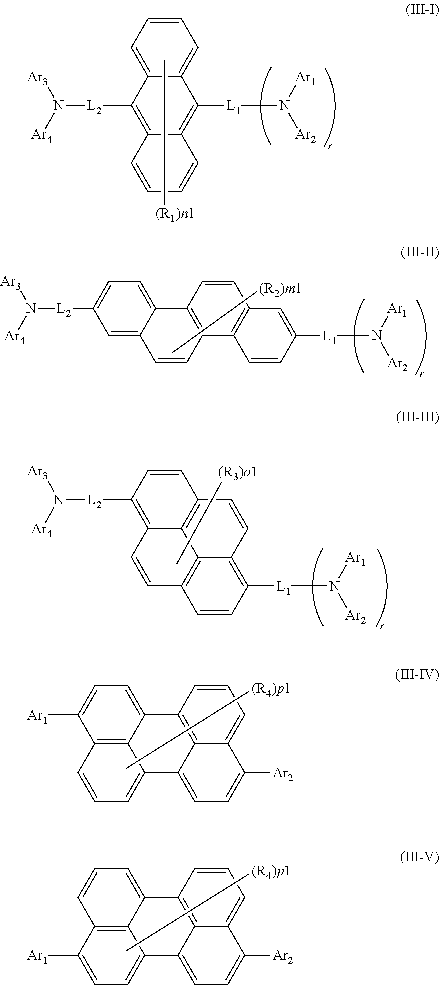

Where n1, o1 are integers from 1 to 8; m1, p1 are integers from 1 to 10; r is 0 or 1; R₁ to R₄ are substituents and are independently selected from the group consisting of a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ substituted ketone group, a C₂-C₂₀ alkoxycarbonyl group, a C₇-C₂₀ an aryloxycarbonyl group, a cyano group, a carbamoyl group, a haloformyl group, a formyl group (—C(═O)—H), an isocyano group, an isocyanate group, a thiocyanate group, an isothiocyanate group, a hydroxyl group, a nitro group, —NO₂, —CF₃, —Cl, —Br, —F, —I, a cross-linkable group, a substituted/unsubstituted aromatic or heteroaromatic group containing 5 to 40 ring atoms, an aryloxy or heteroaryloxy group containing 5 to 40 ring atoms, an arylamine or heteroarylamine group containing 5 to 40 ring atoms, and a disubstituted unit in any position of the above substituents or a combination thereof, where one or more R₁-R₄ may form a monocyclic or polycyclic aliphatic or aromatic ring system with each other and/or with the rings bonded thereto; each of Ar₁ to Ar₄ at each occurrence is independently selected from the group consisting of a substituted/unsubstituted aromatic or heteroaromatic group containing 5 to 40 ring atoms, an aryloxy or heteroaryloxy group containing 5 to 40 ring atoms, and any combination thereof; each of L₁ and L₂ at each occurrence is independently selected from the group consisting of a single bond, a substituted/unsubstituted aromatic or heteroaromatic group containing 6 to 30 ring atoms.

In some embodiments, the organic compound H has a long conjugated π-electron system. Hitherto, there have been many examples of styryl amines and derivatives thereof as disclosed in JP2913116B and WO2001021729A1, and indenofluorenes and derivatives thereof as disclosed in WO2008006449 and WO2007140847.

In some embodiments, the organic compound H can be selected from the group consisting of monostyrylamines, distyrylamines, tristyrylamines, tetrastyrylamines, styrenphosphines, styrenethers, and arylamines.

A monostyrylamine refers to a compound which comprises one unsubstituted or substituted styryl group and at least one amine, most preferably an aryl amine. Distyrylamine refers to a compound comprising two unsubstituted or substituted styryl groups and at least one amine, most preferably an aryl amine. Ternarystyrylamine refers to a compound which comprises three unsubstituted or substituted styryl groups and at least one amine, most preferably an aryl amine. Quaternarystyrylamine refers to a compound comprising four unsubstituted or substituted styryl groups and at least one amine, most preferably an aryl amine. Preferred styrene is stilbene, which may be further substituted. The corresponding phosphines and ethers are defined similarly as amines. Aryl amine or aromatic amine refers to a compound comprising three unsubstituted or substituted cyclic or heterocyclic aryl systems directly attached to nitrogen. At least one of these cyclic or heterocyclic aryl systems is preferably selected from fused ring systems and most preferably has at least 14 aryl ring atoms. Among the preferred examples are aryl anthramine, aryl anthradiamine, aryl pyrene amines, aryl pyrene diamines, aryl chrysene amines and aryl chrysene diamine. Aryl anthramine refers to a compound in which one diarylamino group is directly attached to anthracene, most preferably at position 9. Aryl anthradiamine refers to a compound in which two diarylamino groups are directly attached to anthracene, most preferably at positions 9,10. Aryl pyrene amines, aryl pyrene diamines, aryl chrysene amines and aryl chrysene diamine are similarly defined, where the diarylarylamino group is most preferably attached to position 1 or 1,6 of pyrene.

Examples of organic compounds H based on vinylamines and arylamines may be found in the following patent documents: WO2006000388, WO2006058737, WO2006000389, WO2007065549, WO2007115610, U.S. Pat. No. 7,250,532B2, DE102005058557A1, CN1583691A, JP08053397A, U.S. Pat. No. 6,251,531B1, US2006210830A, EP1957606A1, and US20080113101A1. The patent documents listed above are specially incorporated herein by reference in their entirety.

Examples of organic compounds H based on stilbene and its derivatives may be found in U.S. Pat. No. 5,121,029.

Further preferred organic compound H can be selected from the group consisting of indenofluorene-amine and indenofluorene-diamine, as disclosed in WO2006122630, benzoindenofluorene-amine and benzoindenofluorene-diamine, as disclosed in WO2008006449, dibenzoindenofluorene-amine and dibenzoindenofluorene-diamine, as disclosed in WO2007140847.

Other materials that can be used as organic compound H include polycyclic aromatic hydrocarbon compounds, in particular selected from the derivatives of the following compounds: anthracene such as 9,10-di(2-naphthyl)anthracene, naphthalene, tetraphenyl, phenanthrene, perylene such as 2,5,8,11-tetra-t-butylatedylene, indenoperylene, phenylene (benzo fused ring such as 4,4′-(bis (9-ethyl-3-carbazovinylene)-1,1′-biphenyl)), periflanthene, decacyclene, coronene, fluorene, spirobifluorene, arylpyren (e.g., US20060222886), arylenevinylene (e.g. U.S. Pat. Nos. 5,121,029, 5,130,603), cyclopentadiene such as tetraphenylcyclopentadiene, rubrene, coumarine, rhodamine, quinacridone, pyrane such as 4 (dicyanoethylene)-6-(4-dimethylaminostyryl-2-methyl)-4H-pyrane (DCM), thiapyran, bis (azinyl) imine-boron compounds (e.g. US20070092753A1), bis (azinyl) methene compounds, carbostyryl compounds, oxazone, benzoxazole, benzothiazole, benzimidazole, or diketopyrrolopyrrole. Some singlet emitter materials may be found in the following patent documents: US20070252517A1, U.S. Pat. Nos. 4,769,292, 6,020,078. The patent documents listed above are specially incorporated herein by reference in their entirety.

The publications of organic functional material presented above are incorporated herein by reference for the purpose of disclosure.

In some embodiments, the organic compound H comprises at least one alcohol-soluble or water-soluble group; preferably comprises at least two alcohol-soluble or water-soluble groups; and most preferably comprises at least three alcohol-soluble or water-soluble groups; as disclosed in patent with the application No. PCT/CN2022/085363. The entire contents of the patent document are hereby incorporated herein for reference.

In some embodiments, the organic compound H comprises at least one cross-linkable group; preferably comprises at least two cross-linkable groups; and most preferably comprises at least three cross-linkable groups; as disclosed in patent with the application No. PCT/CN2022/085362. The entire contents of the patent document are hereby incorporated herein for reference.

Examples of some suitable organic compounds H are listed below (but not limited to), which may be further substituted arbitrarily:

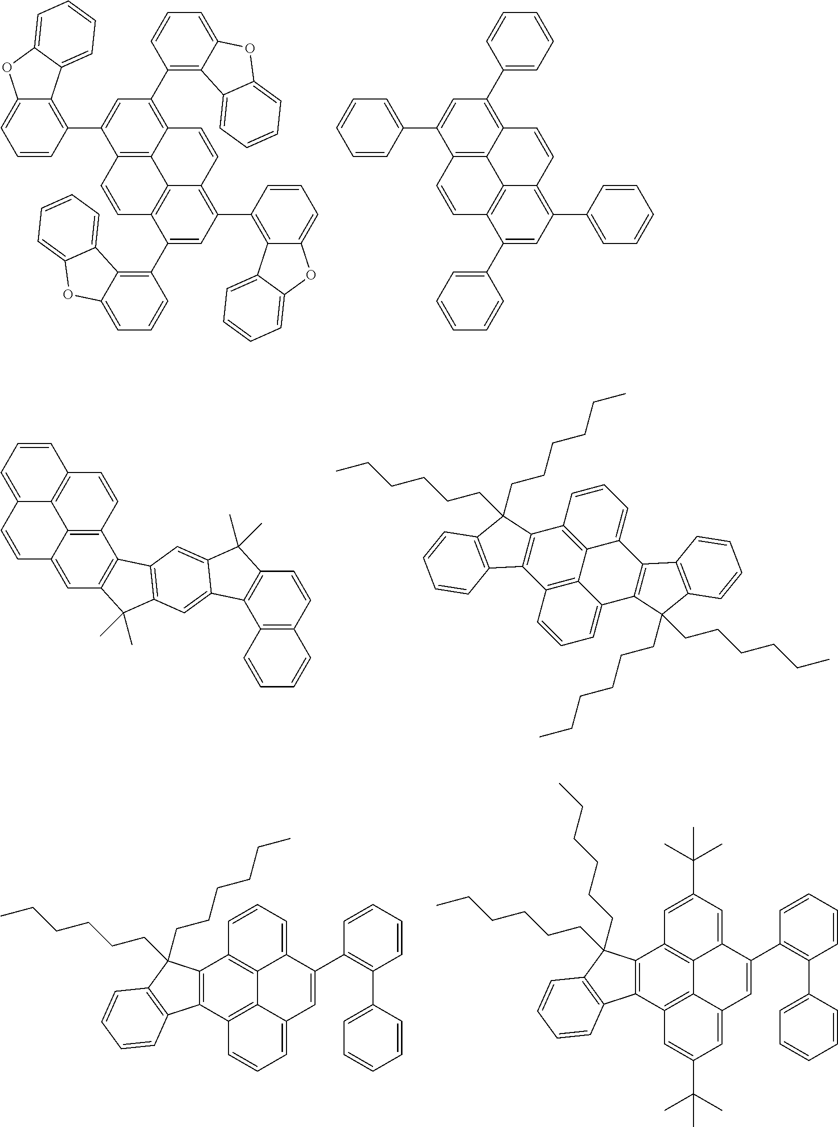

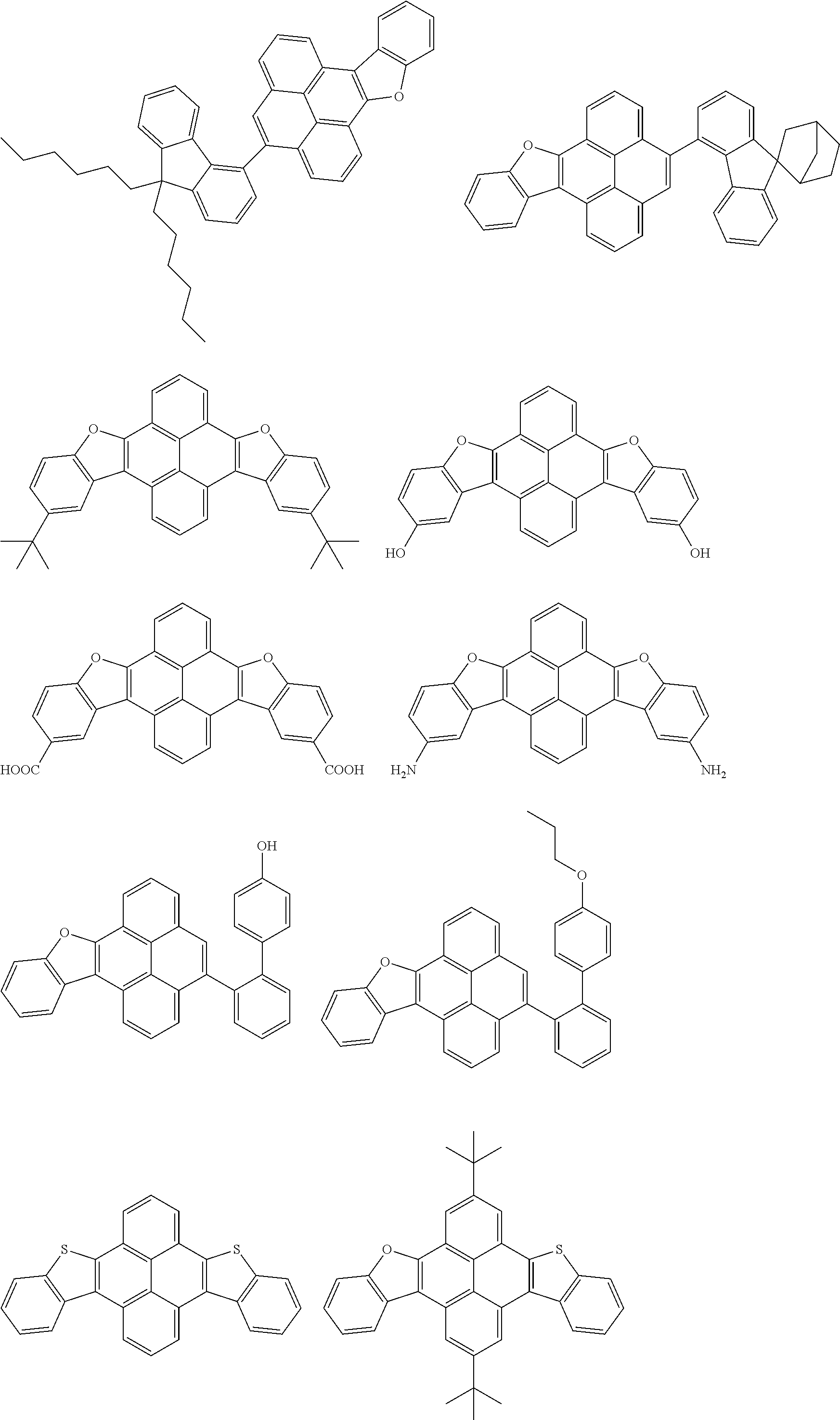

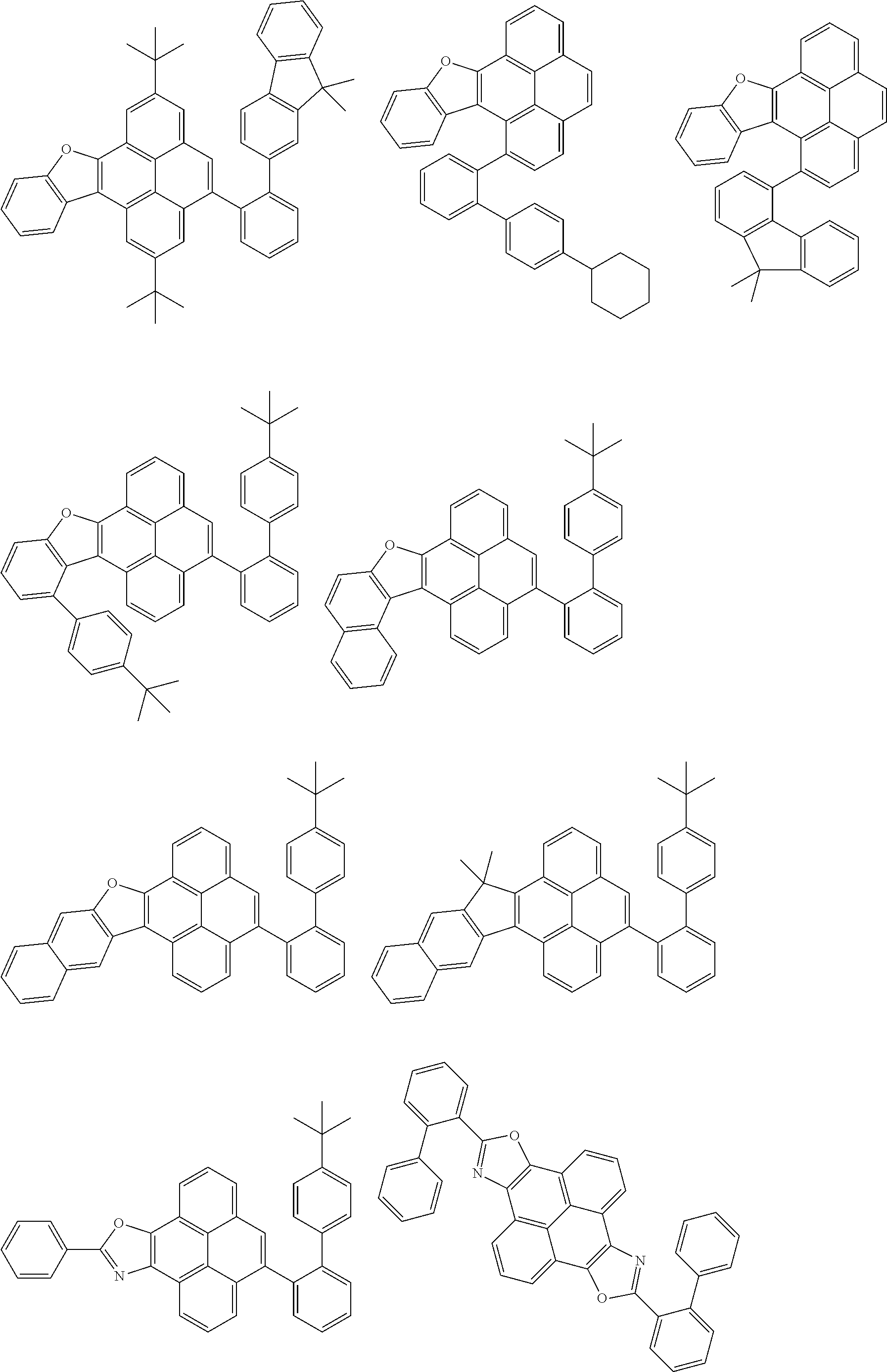

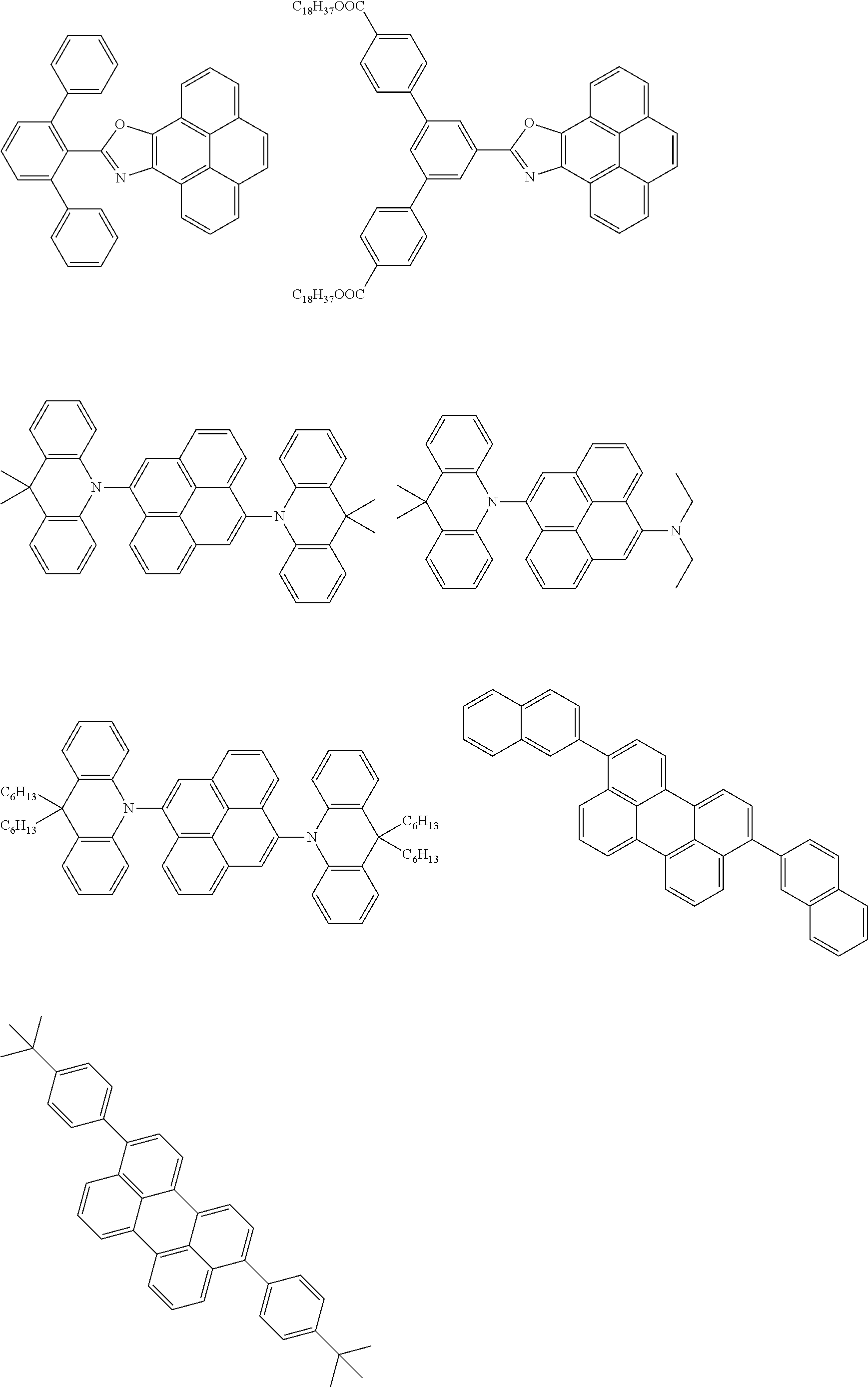

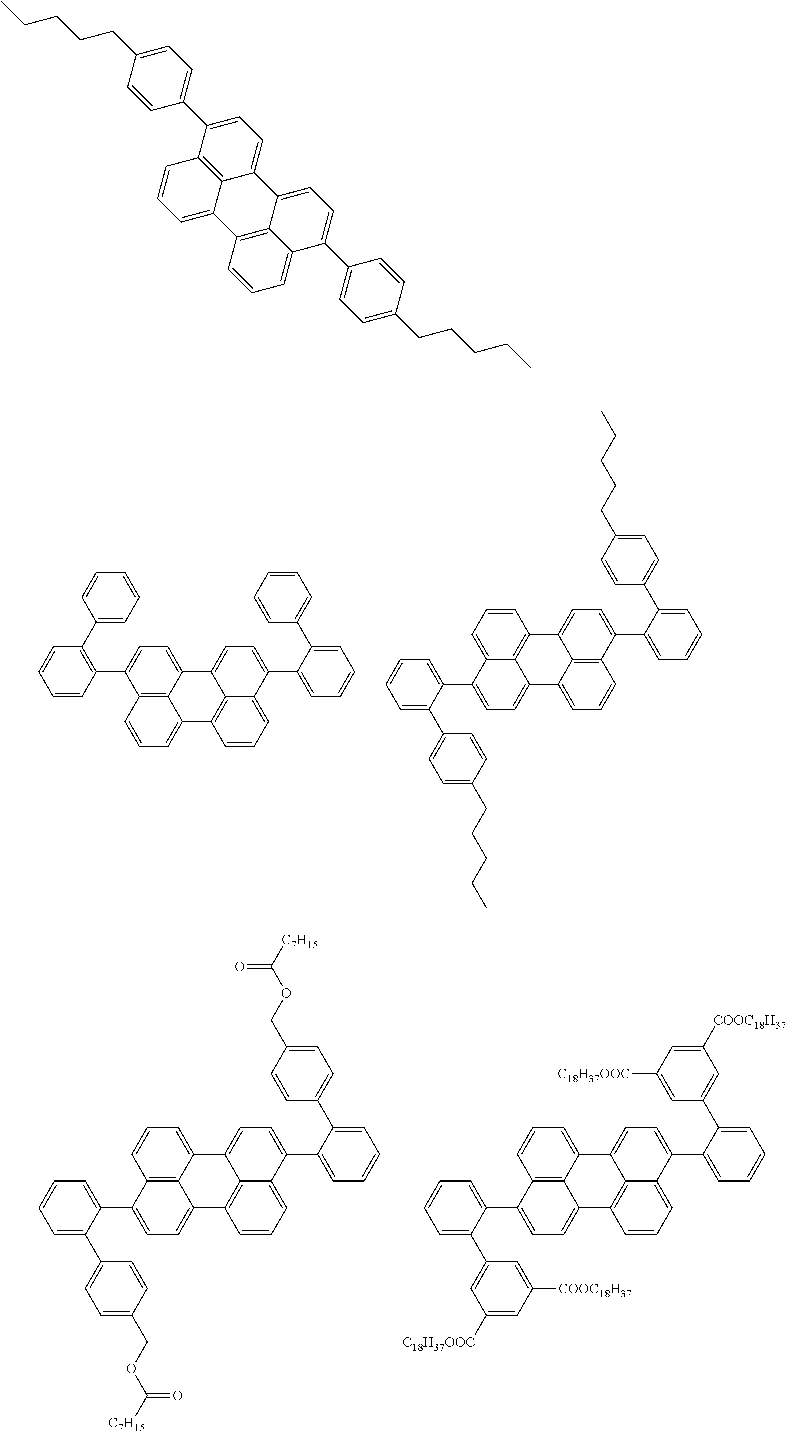

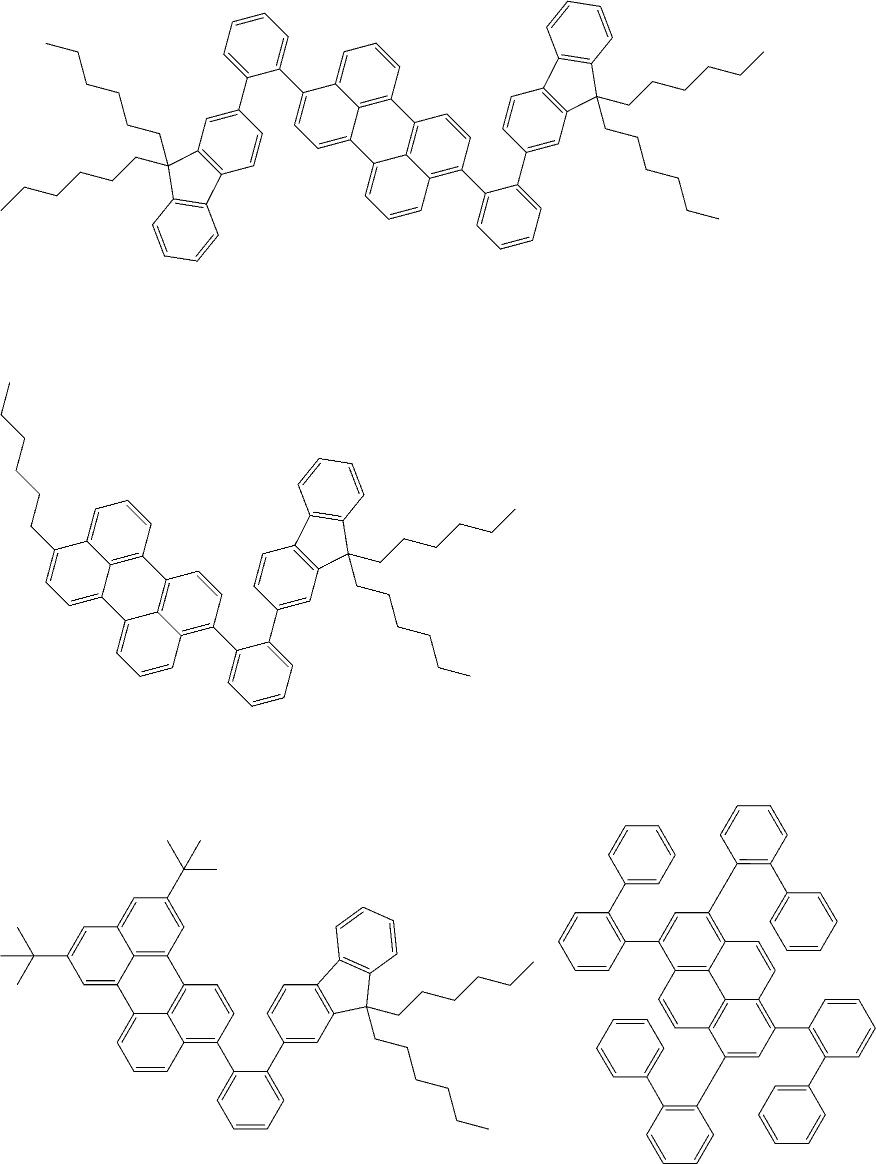

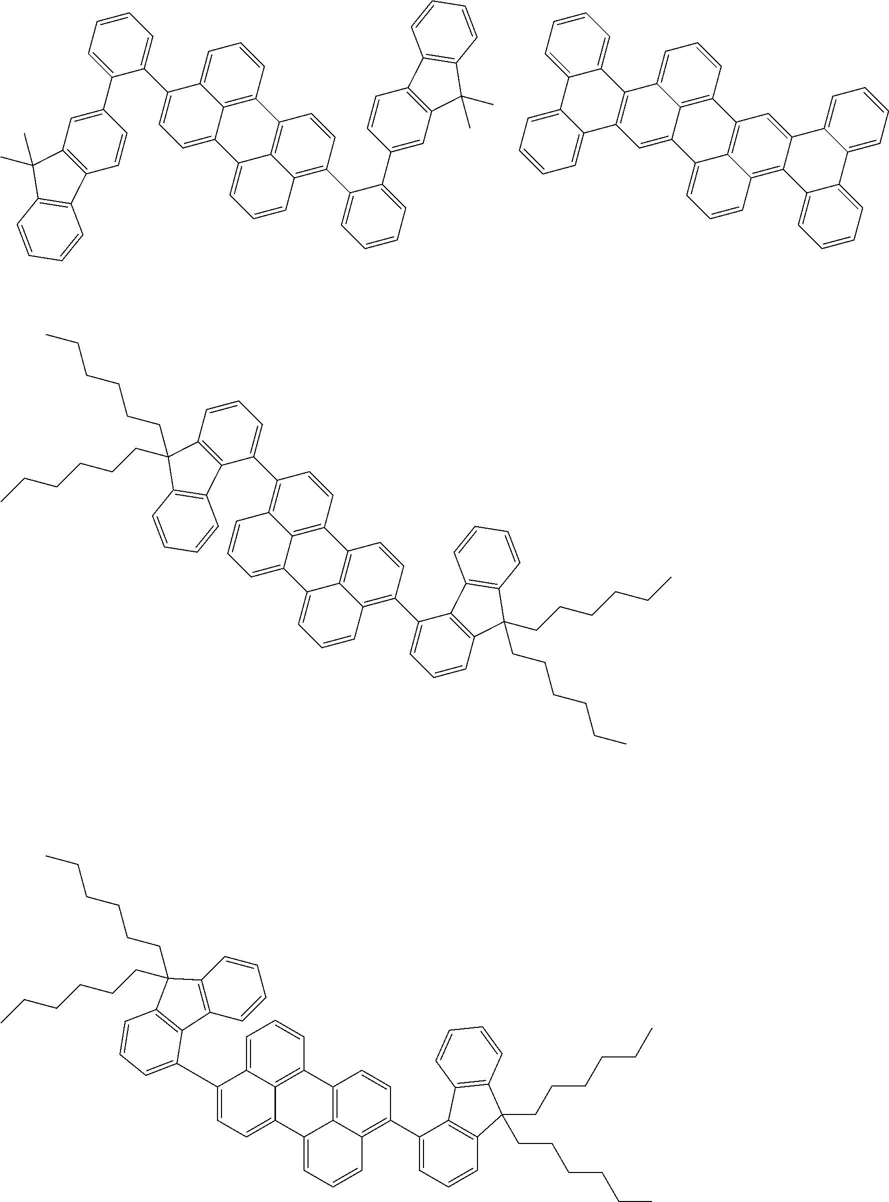

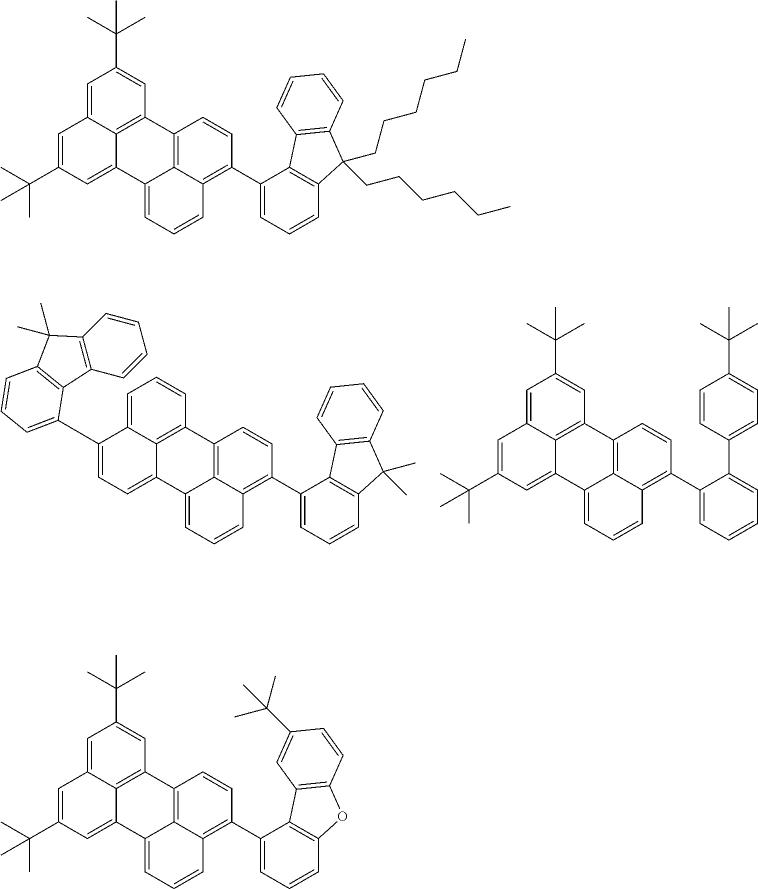

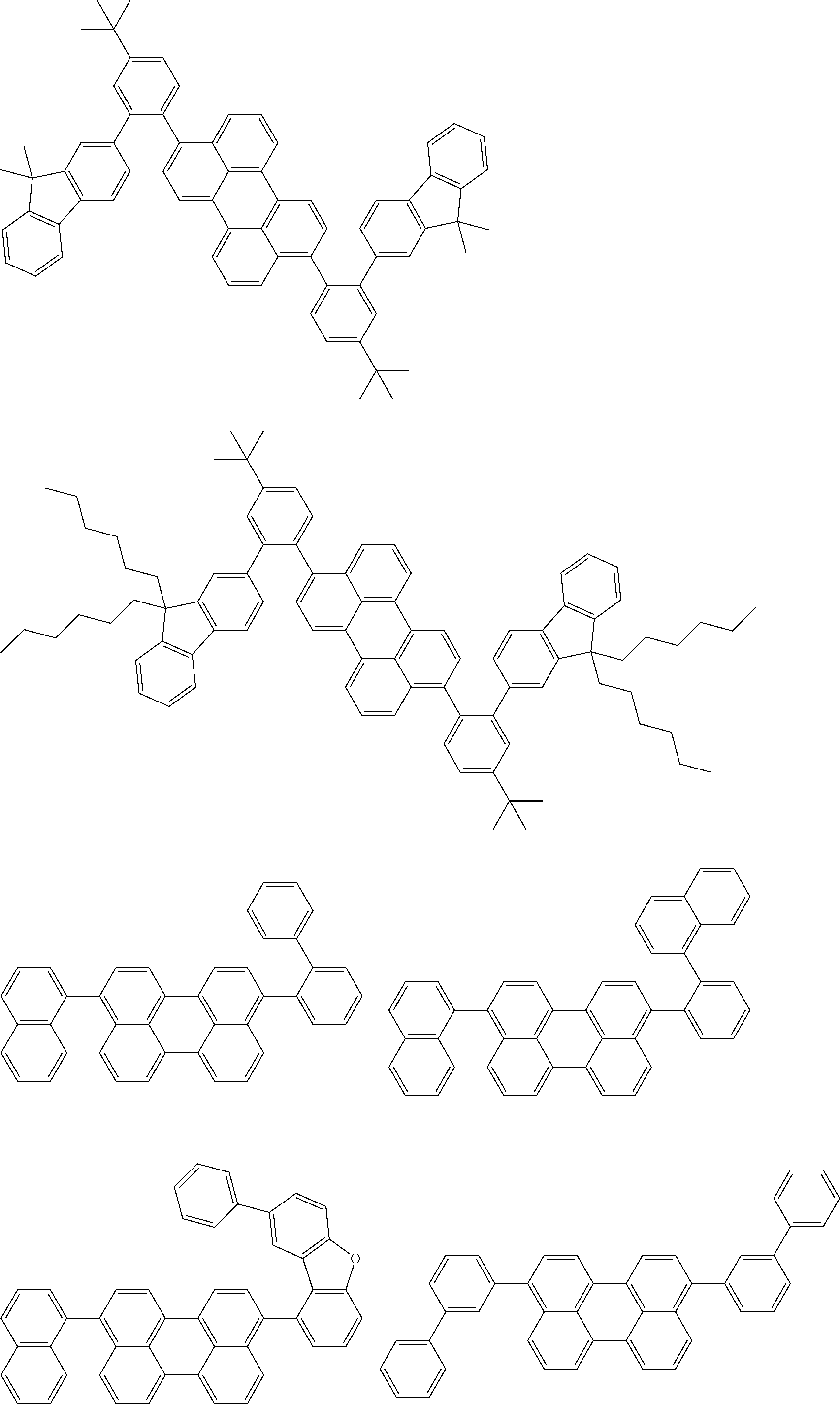

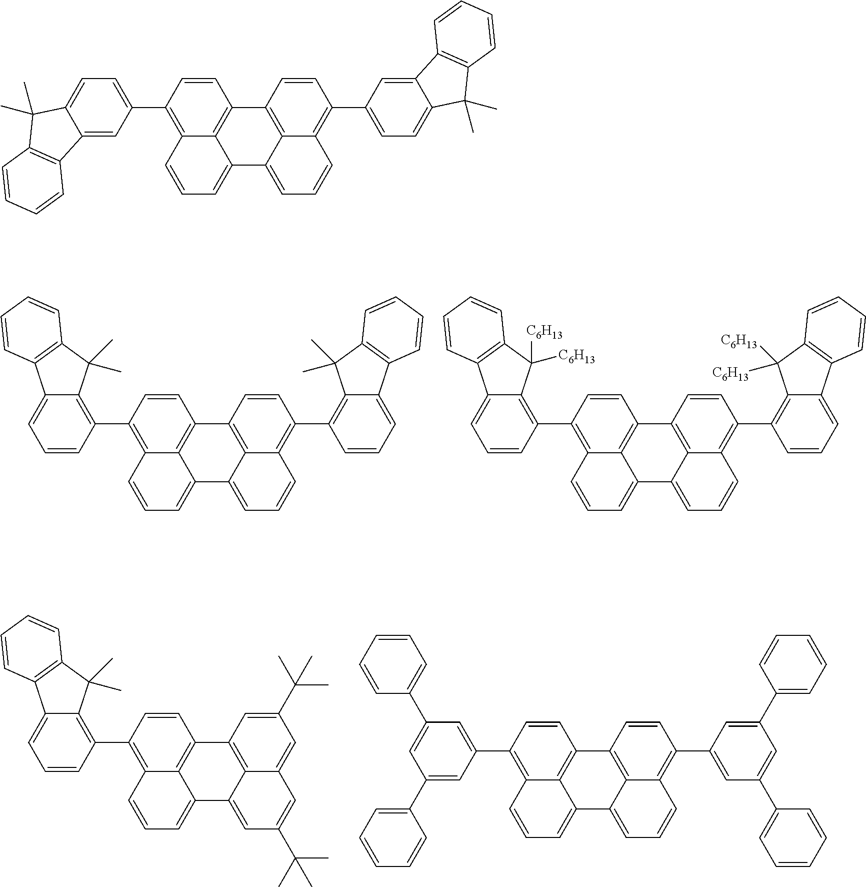

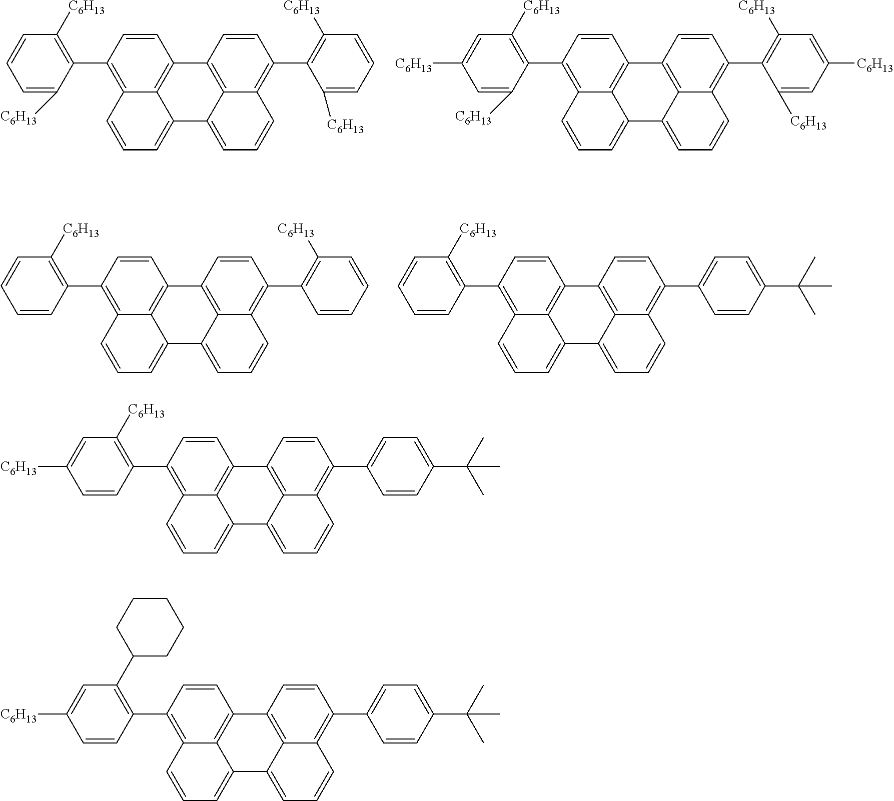

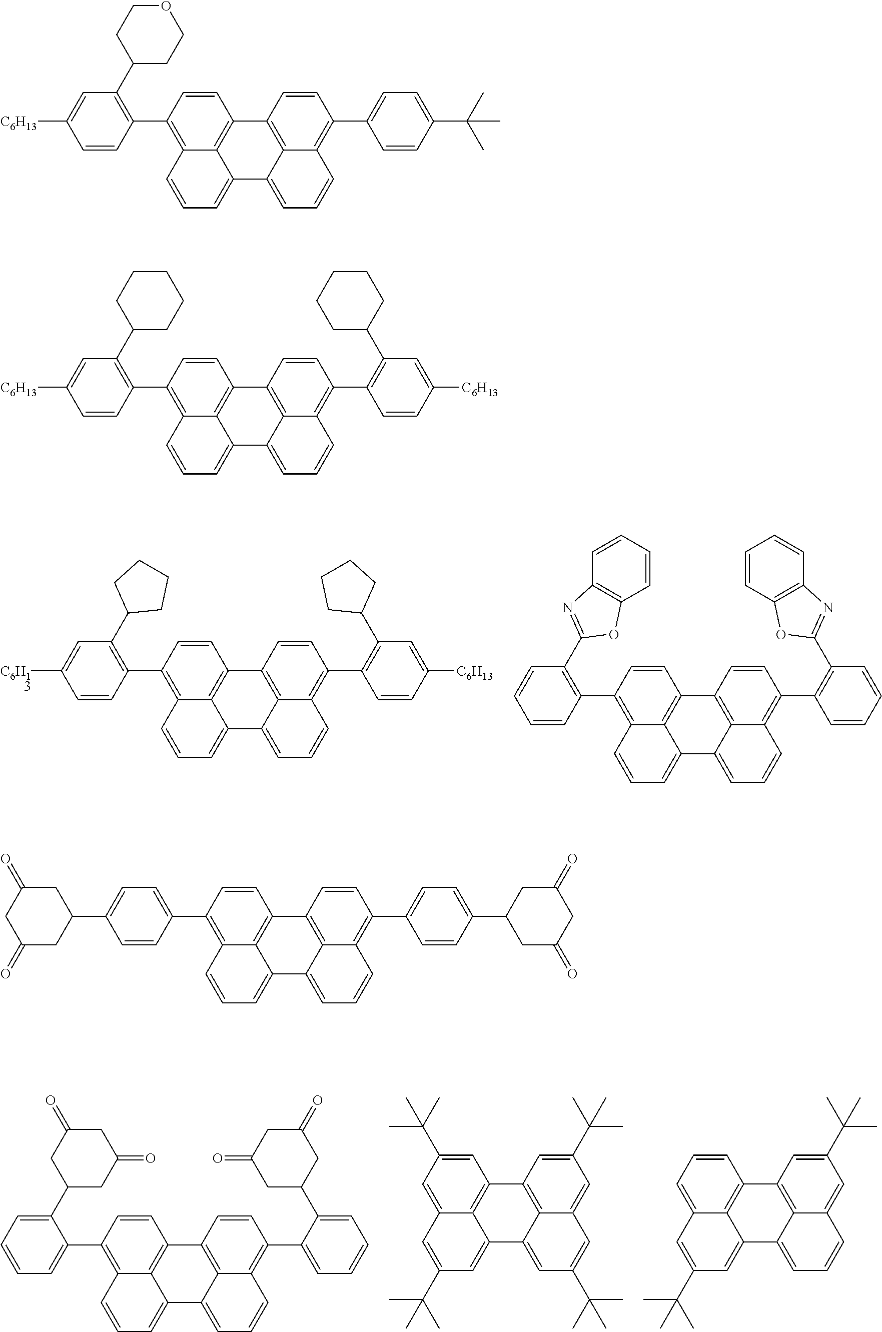

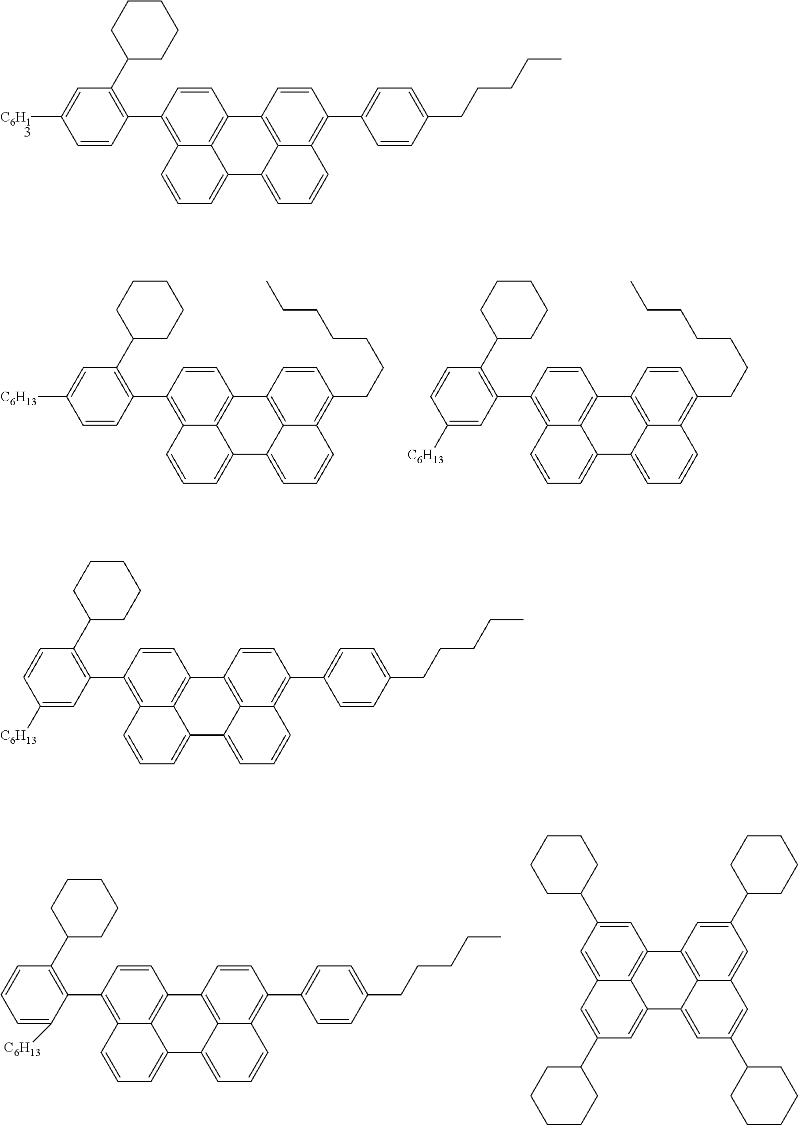

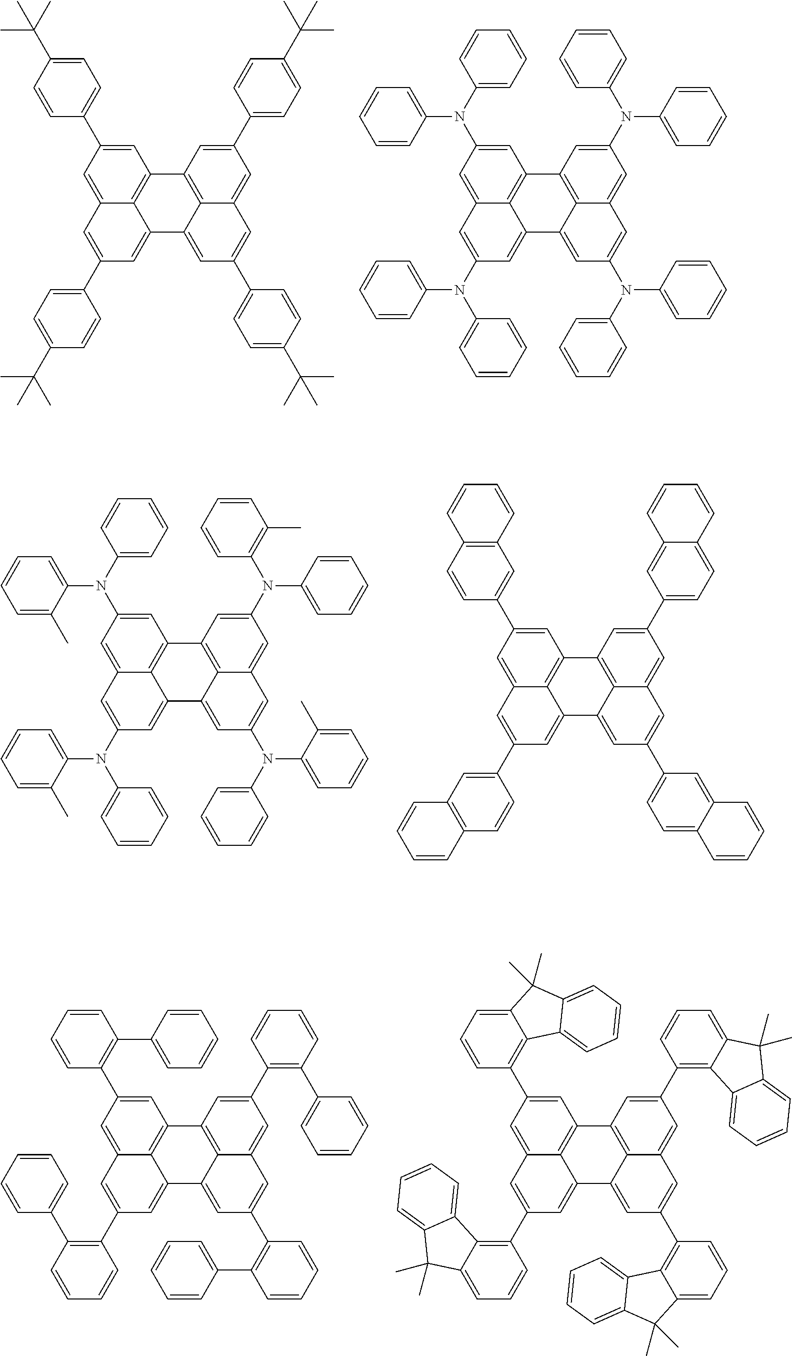

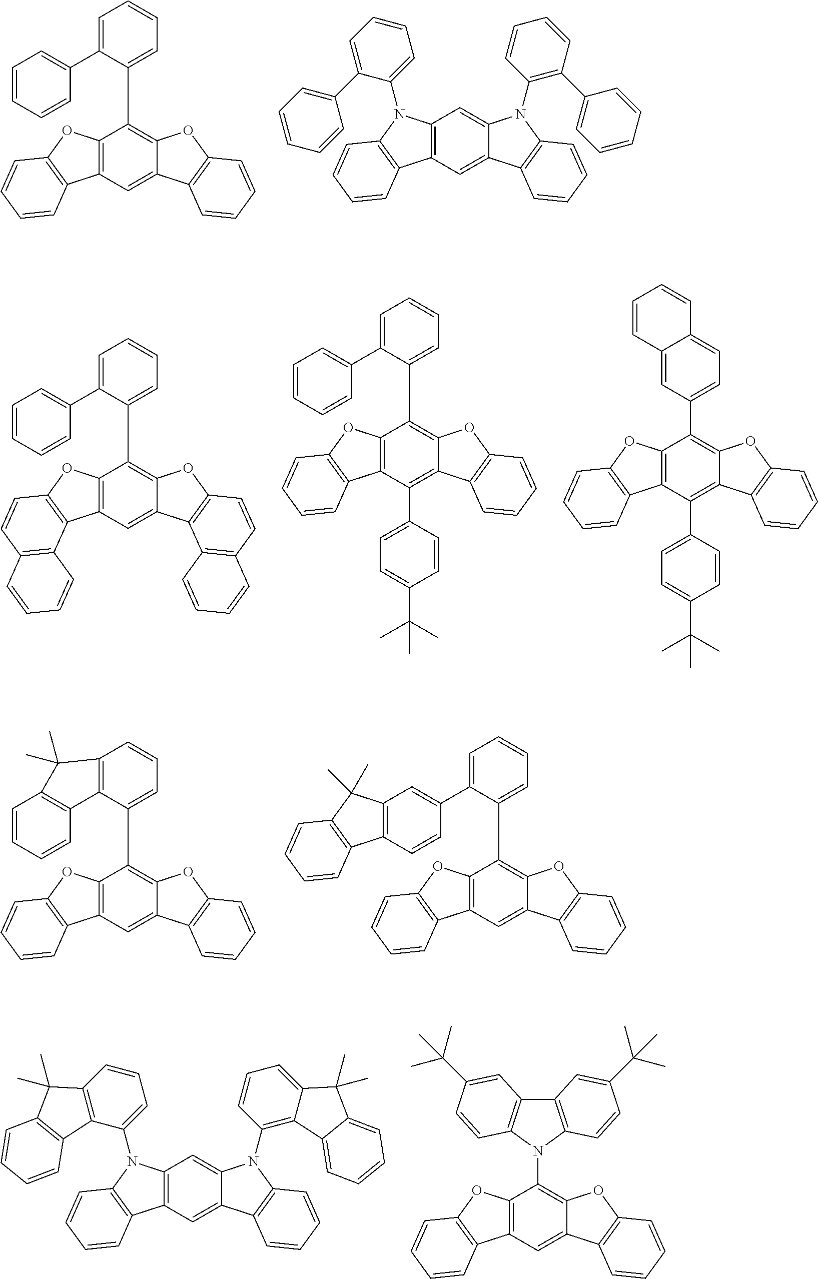

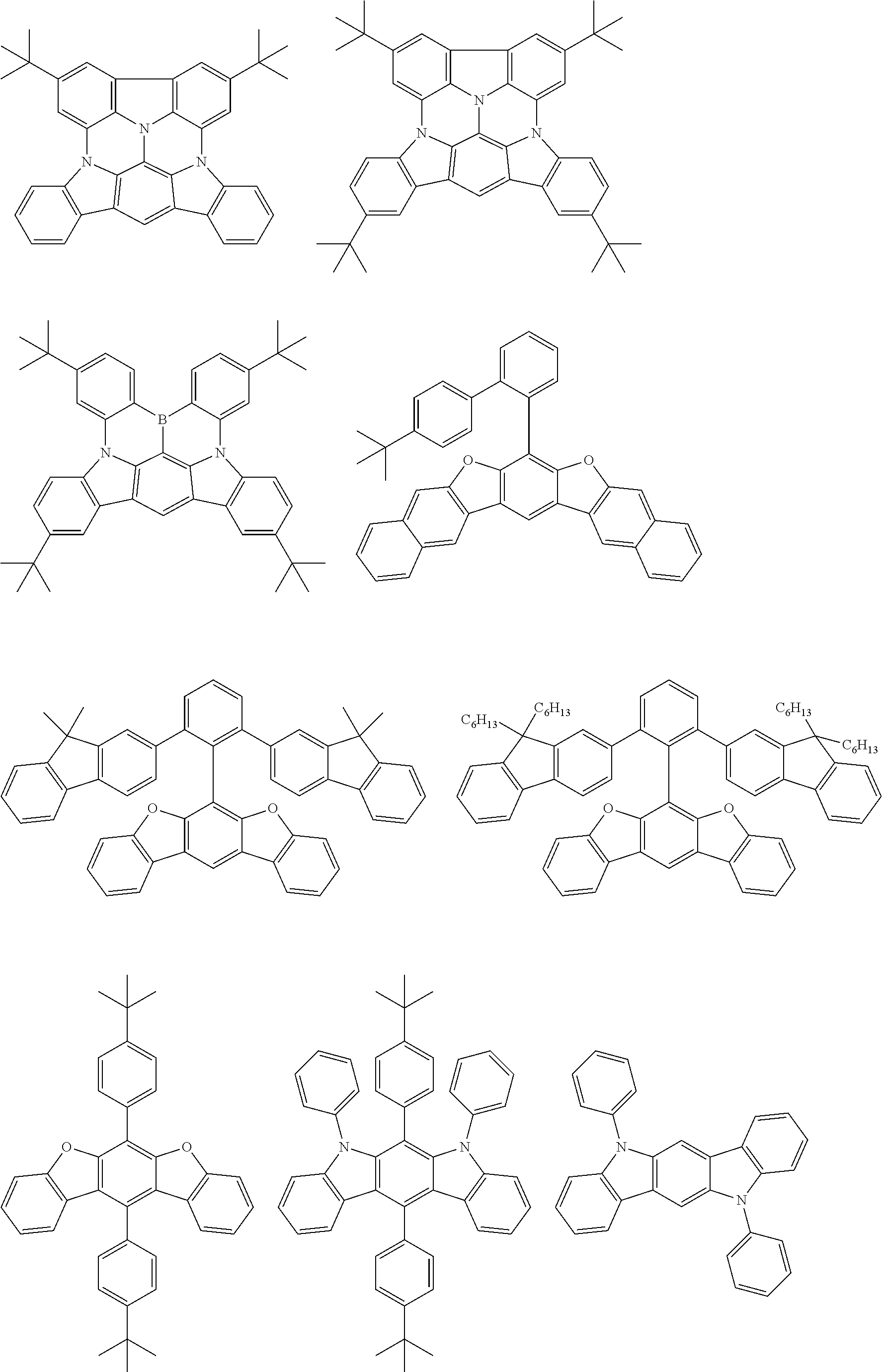

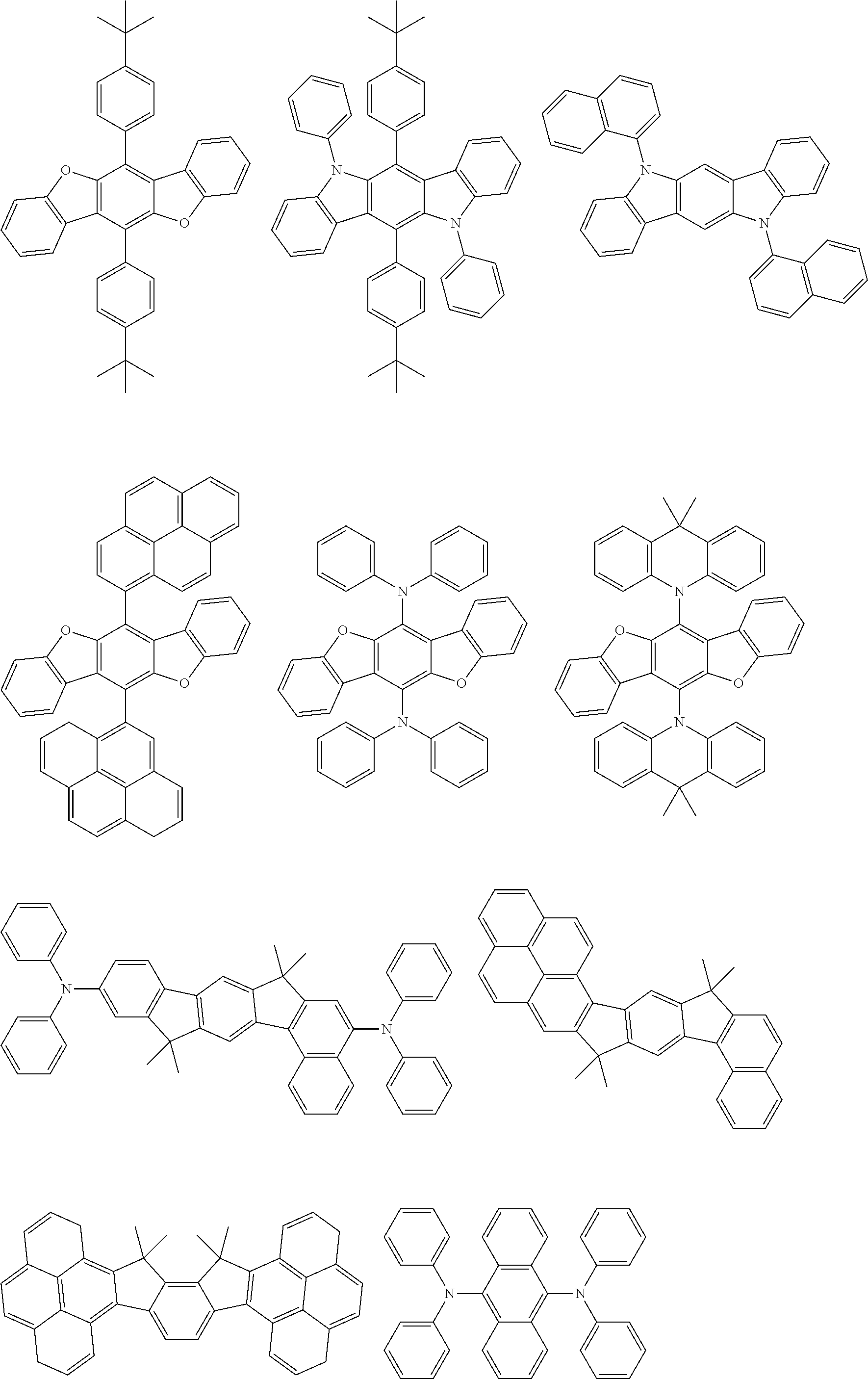

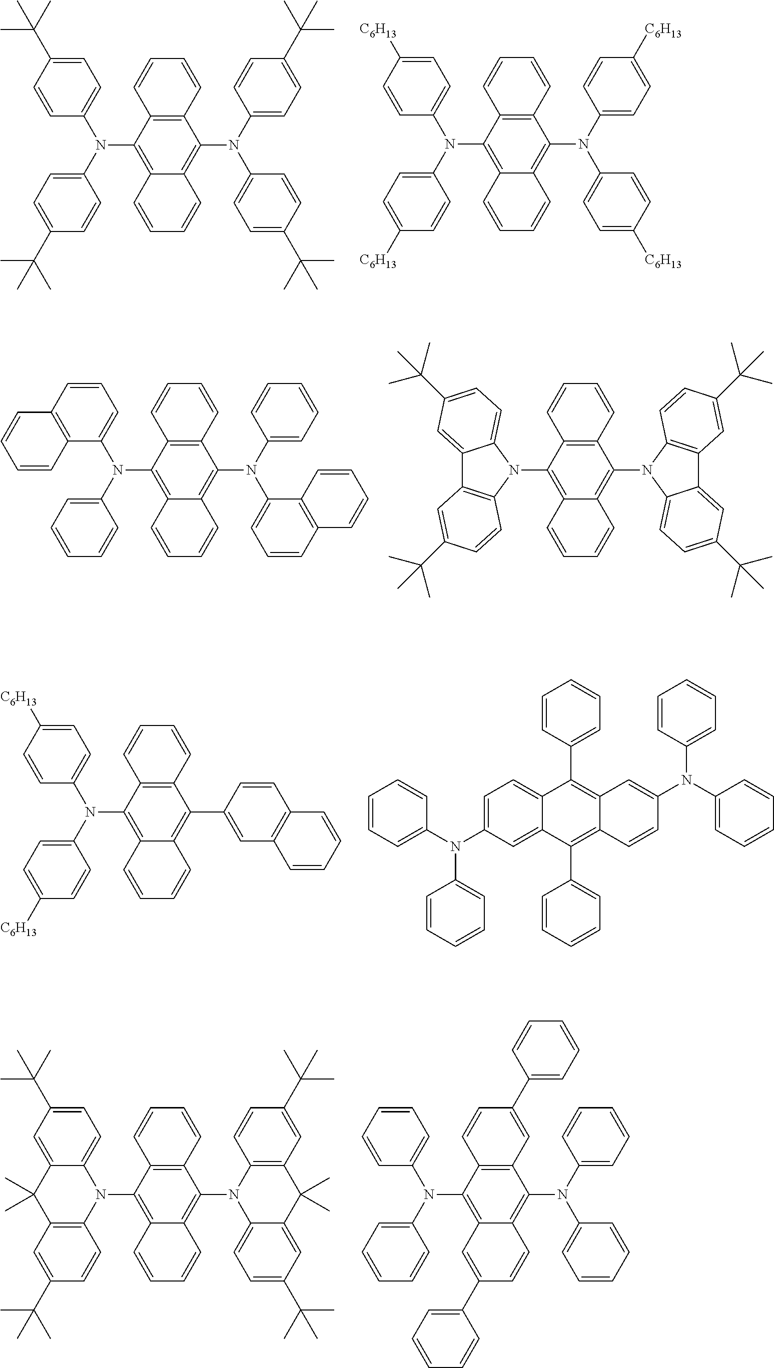

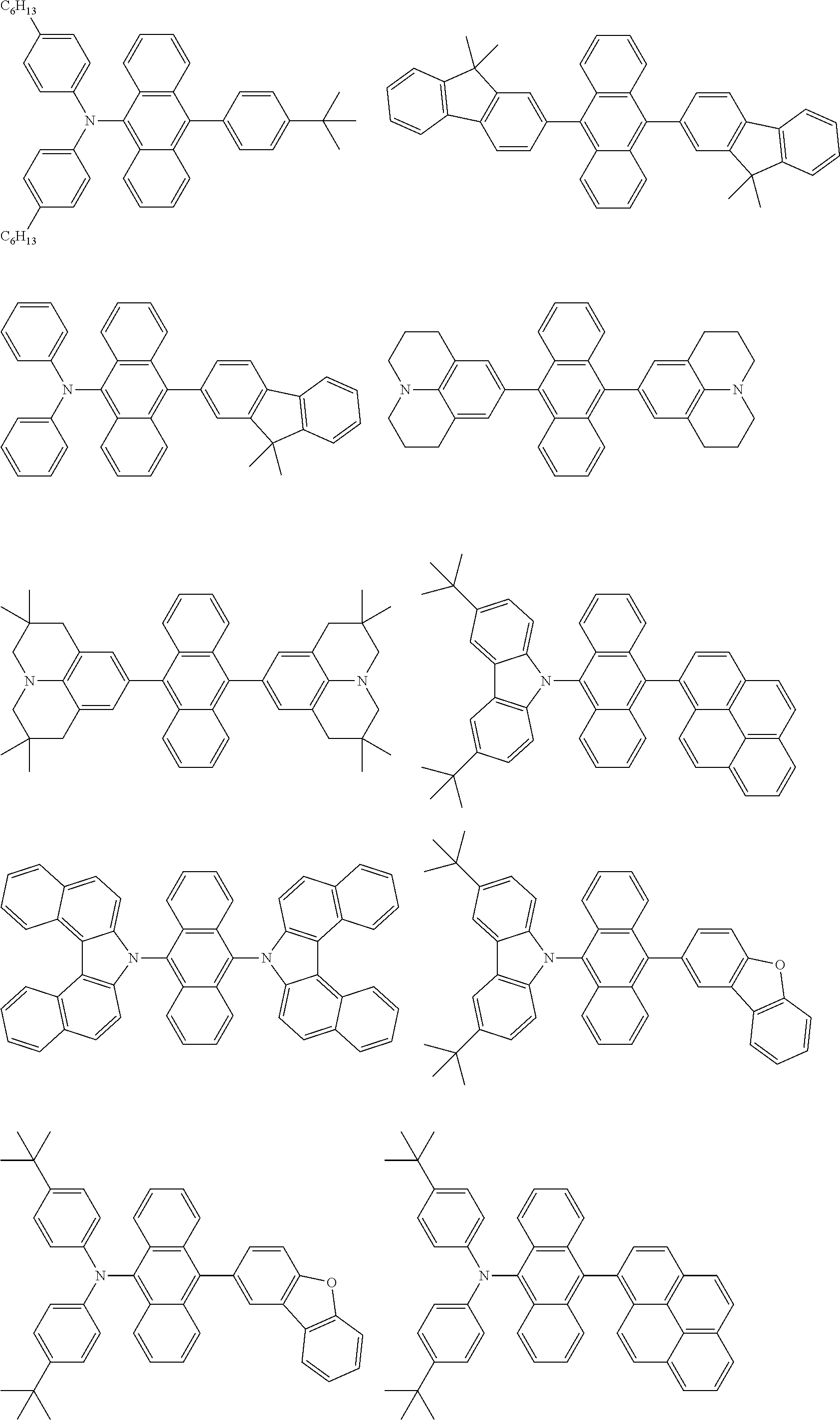

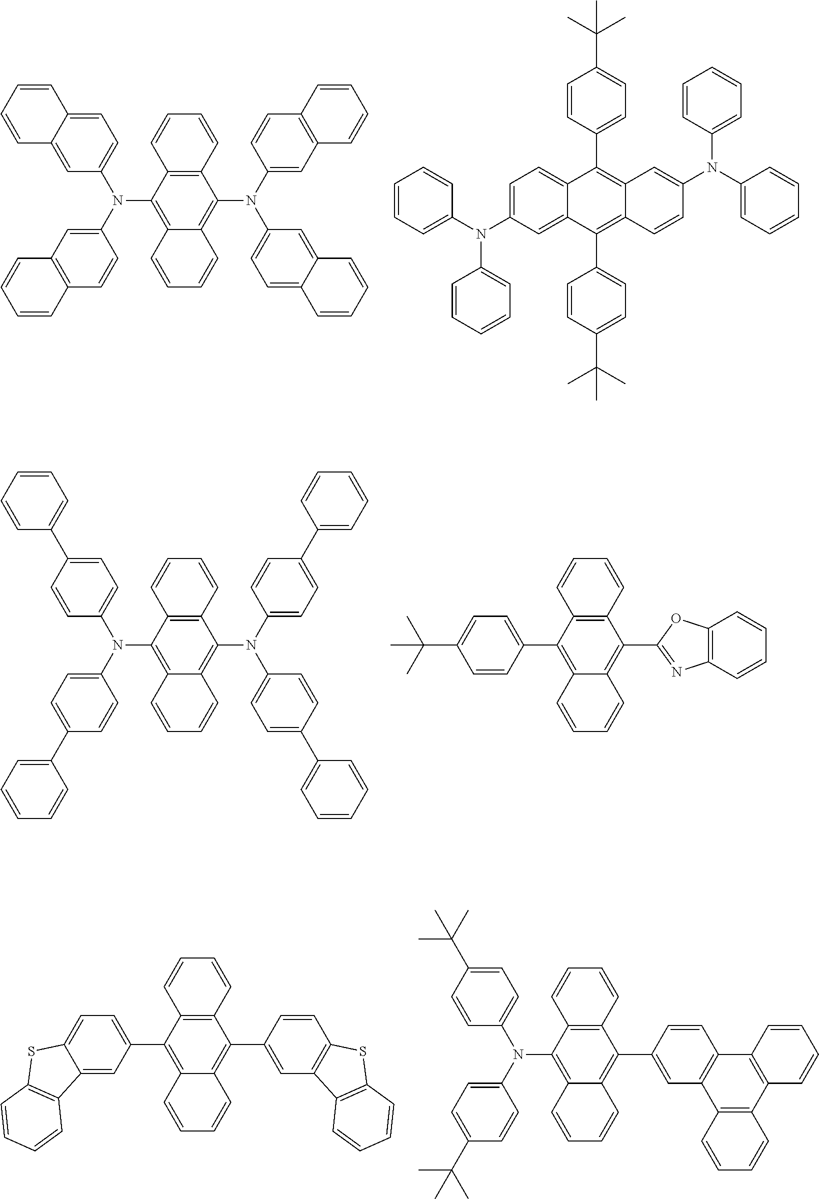

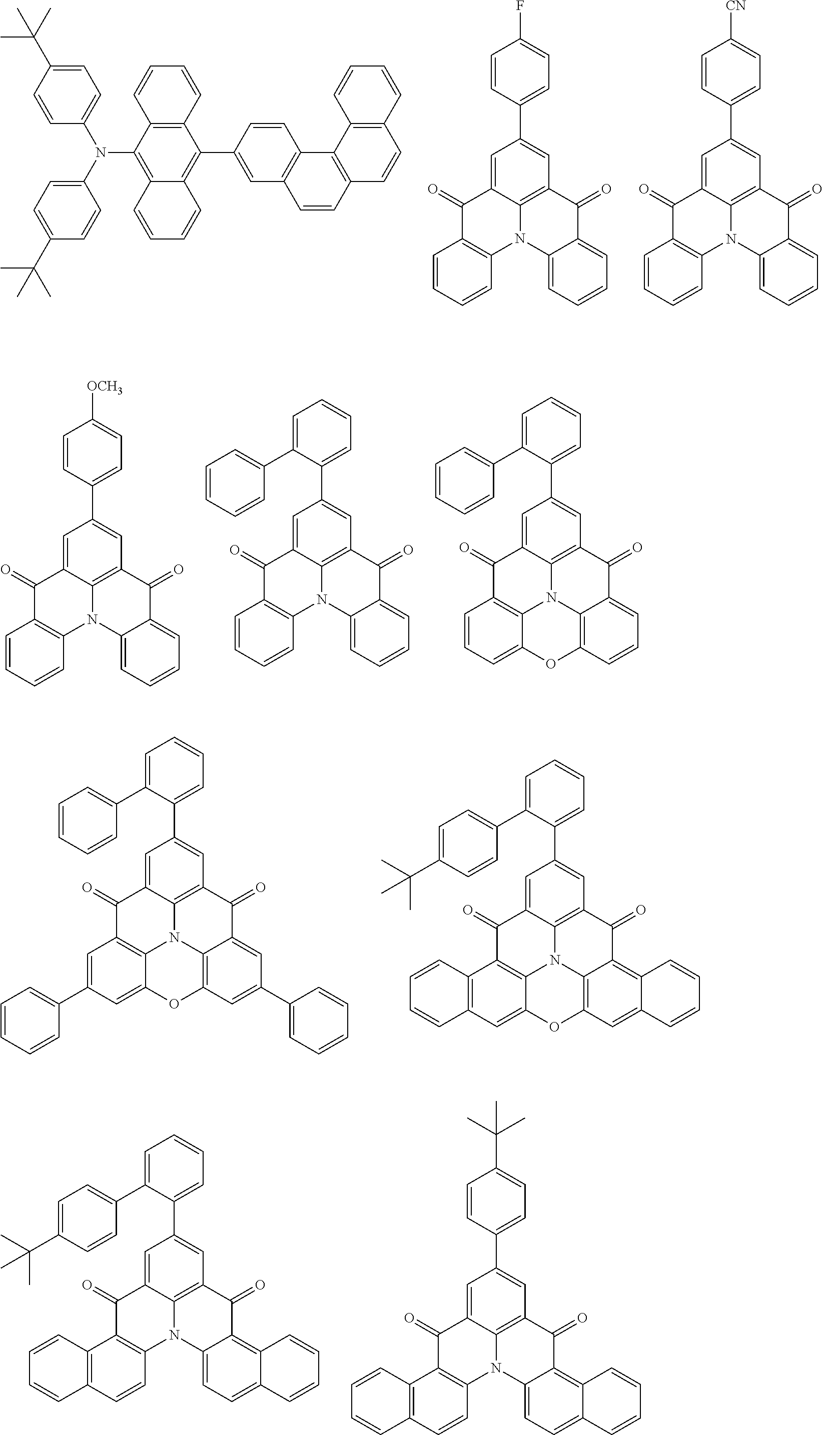

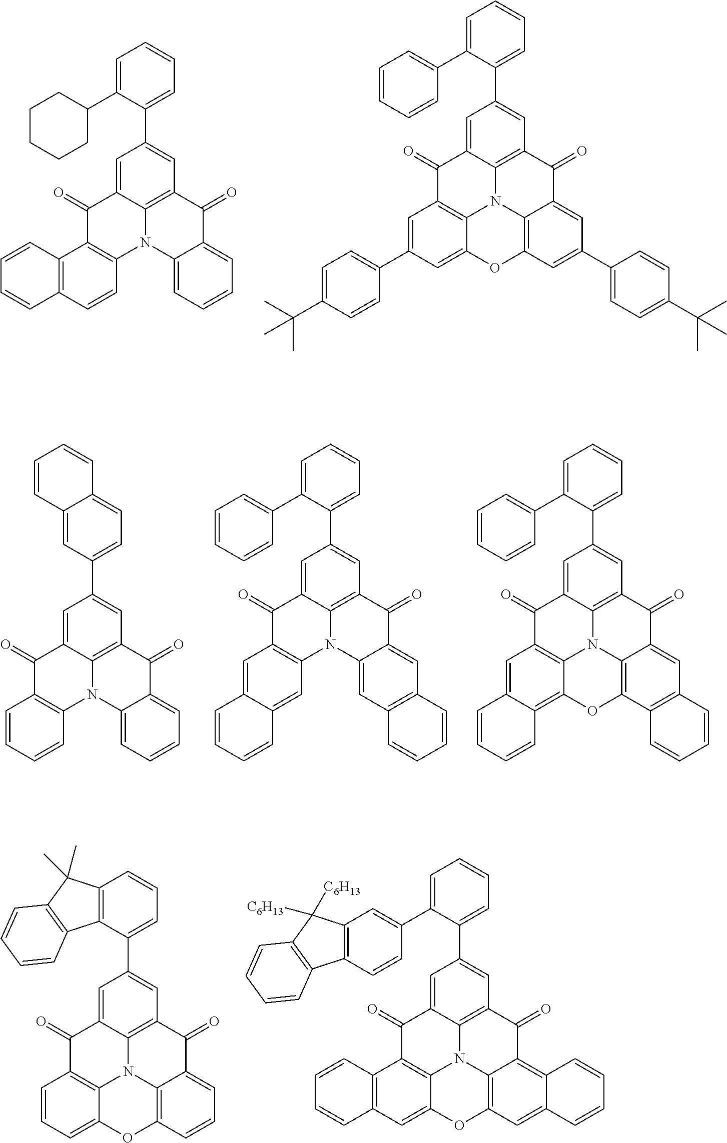

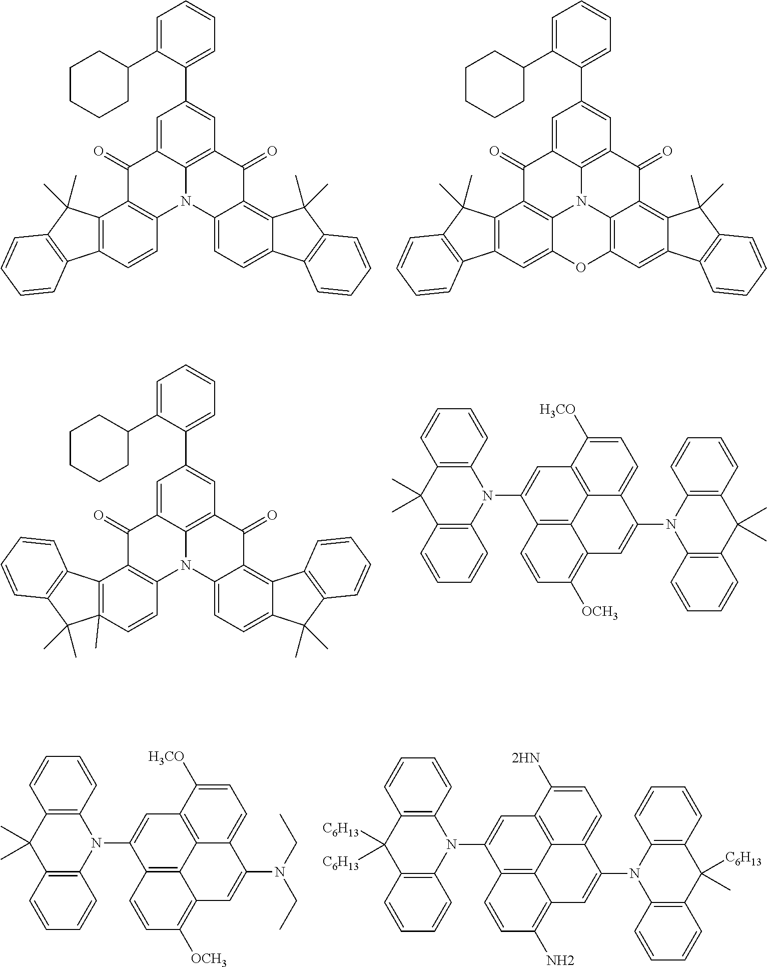

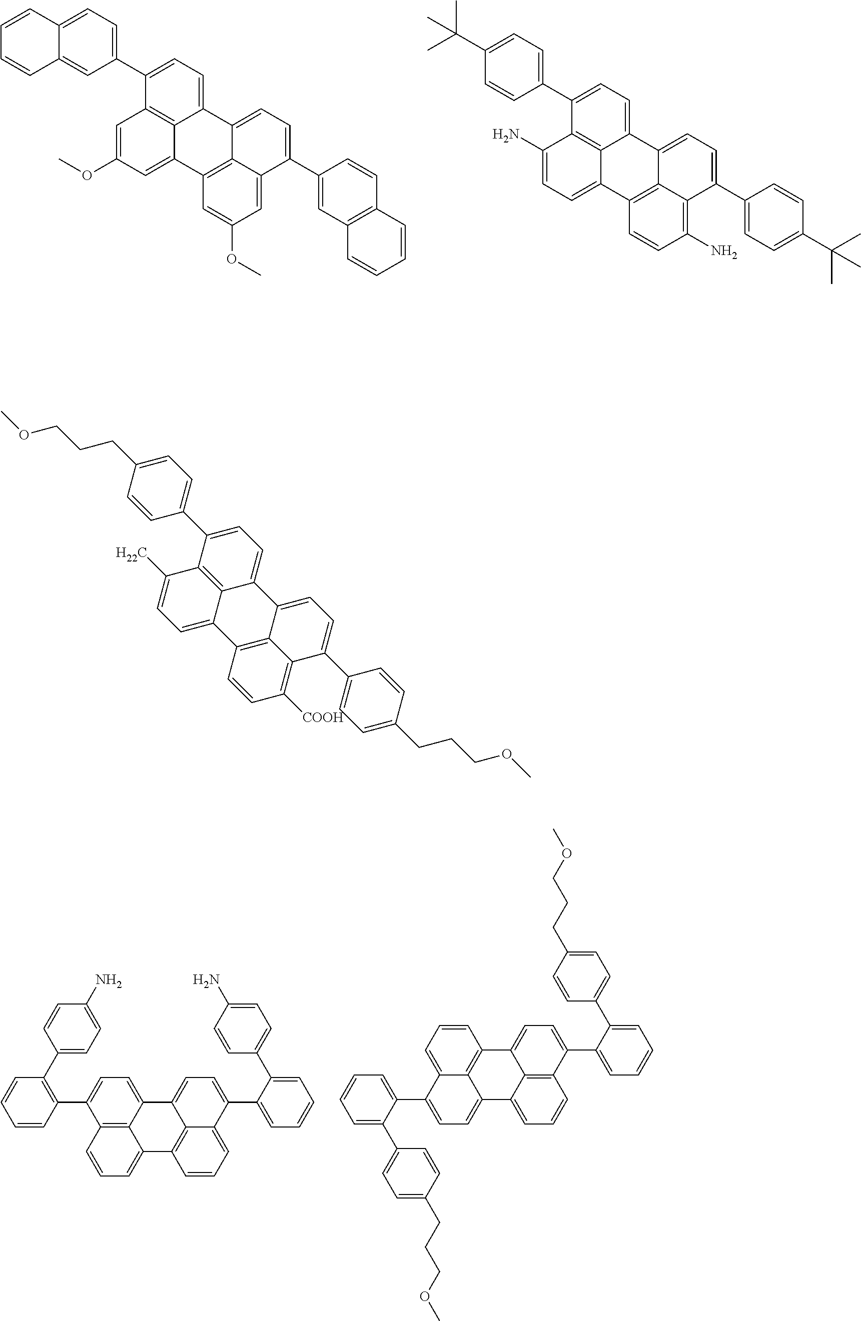

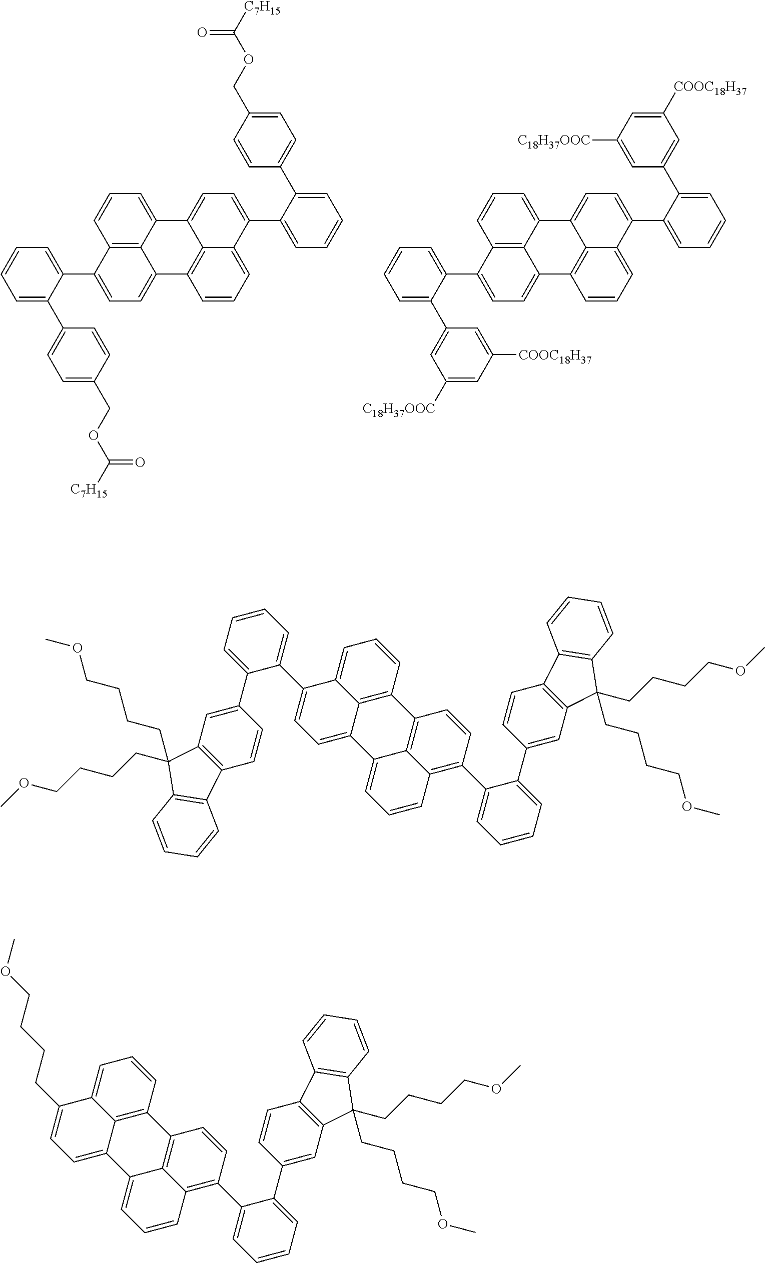

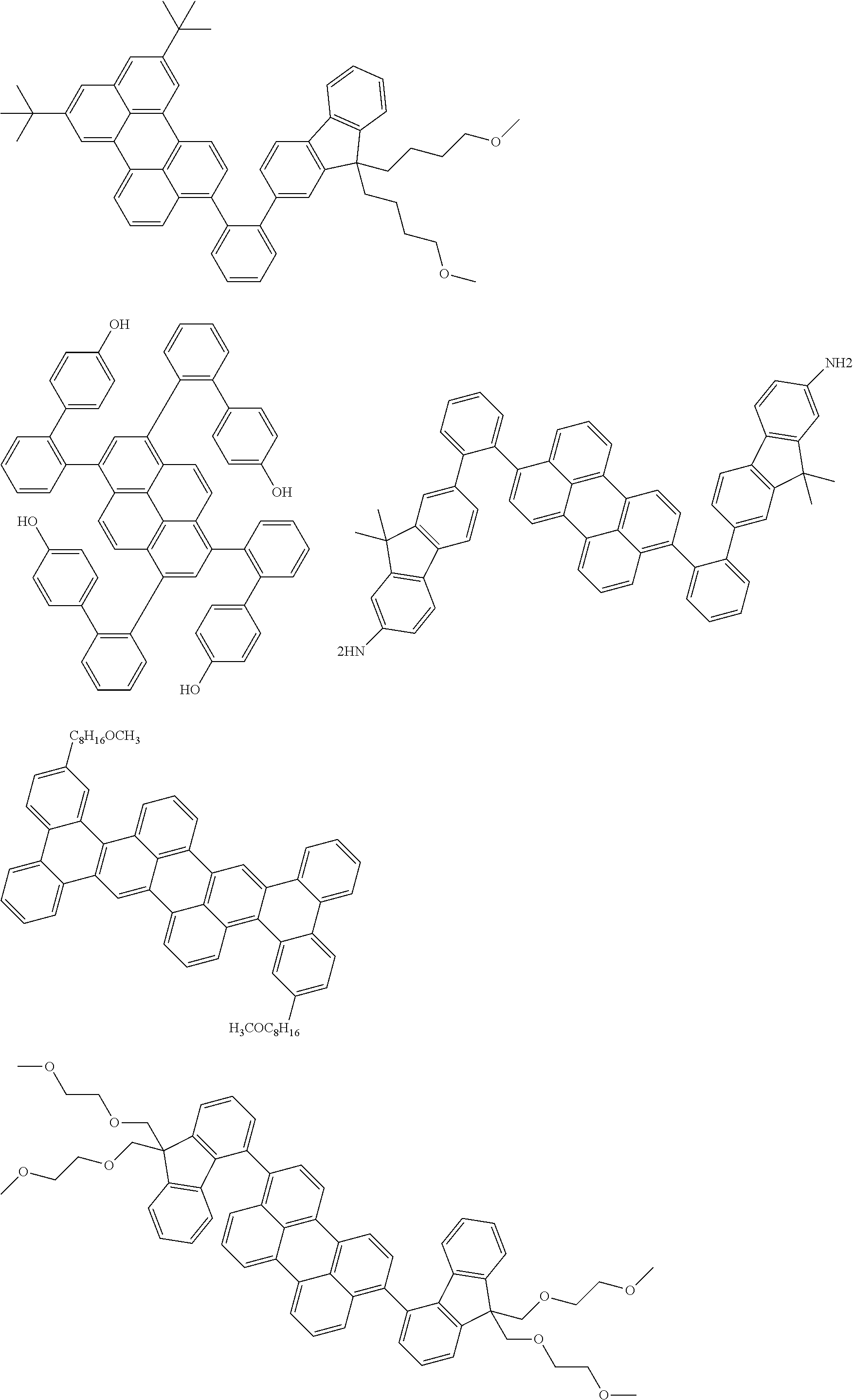

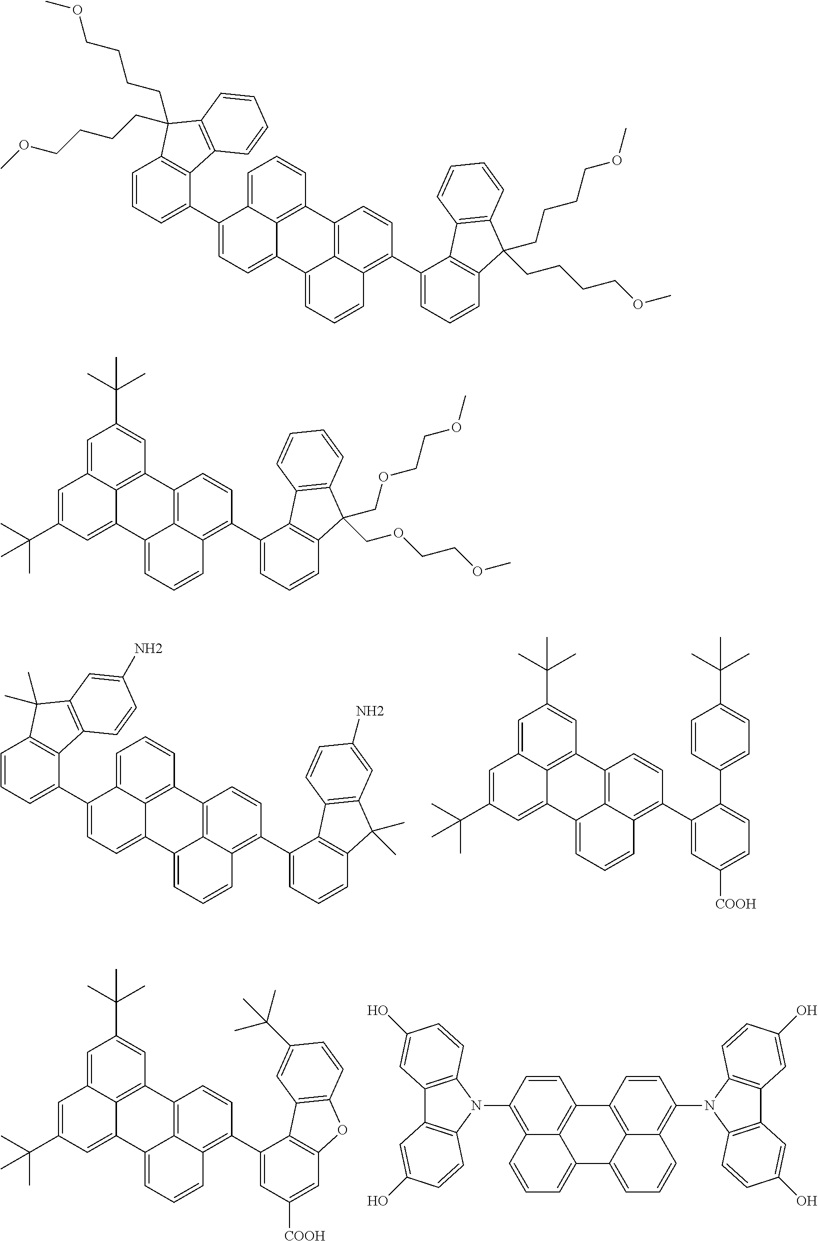

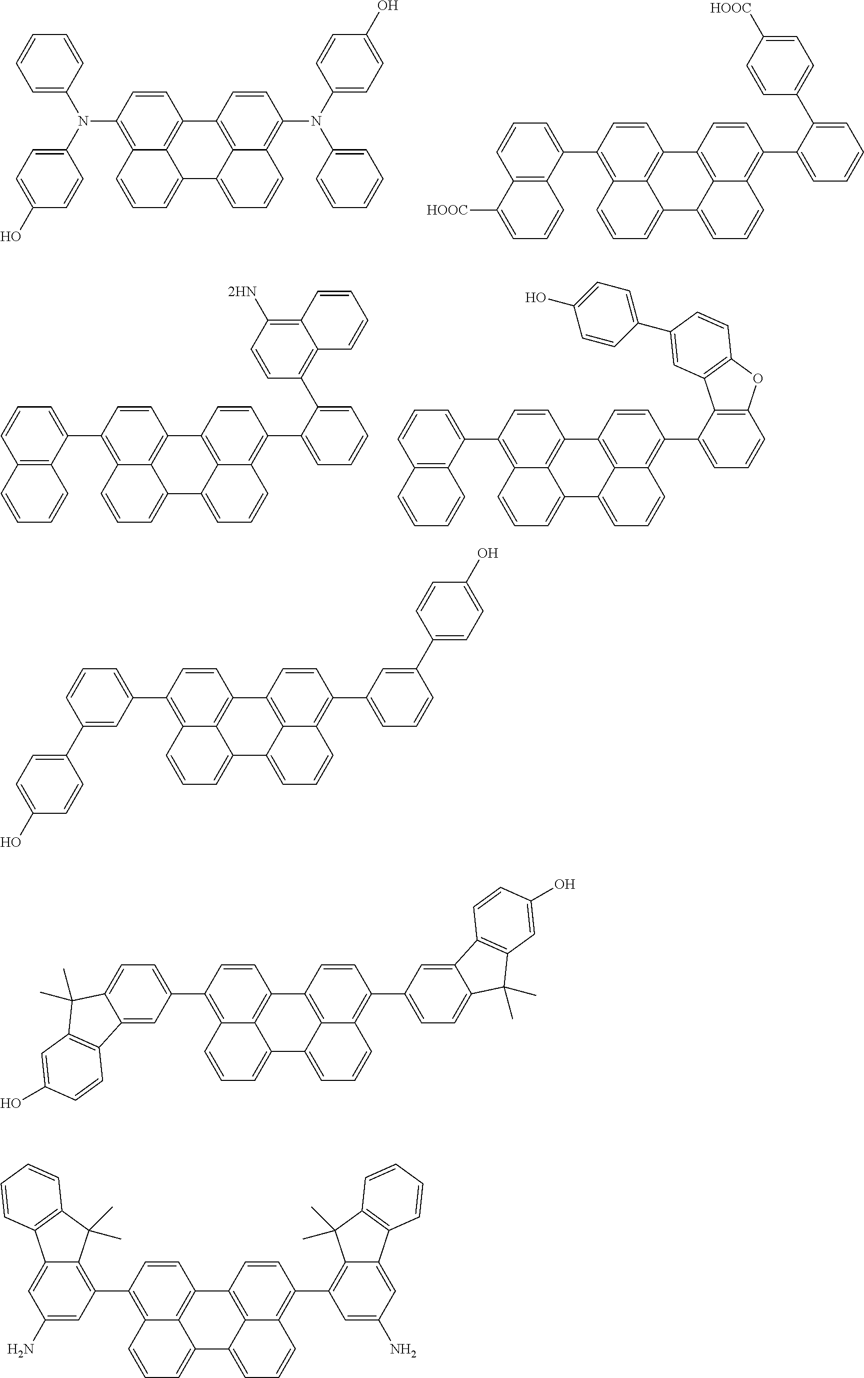

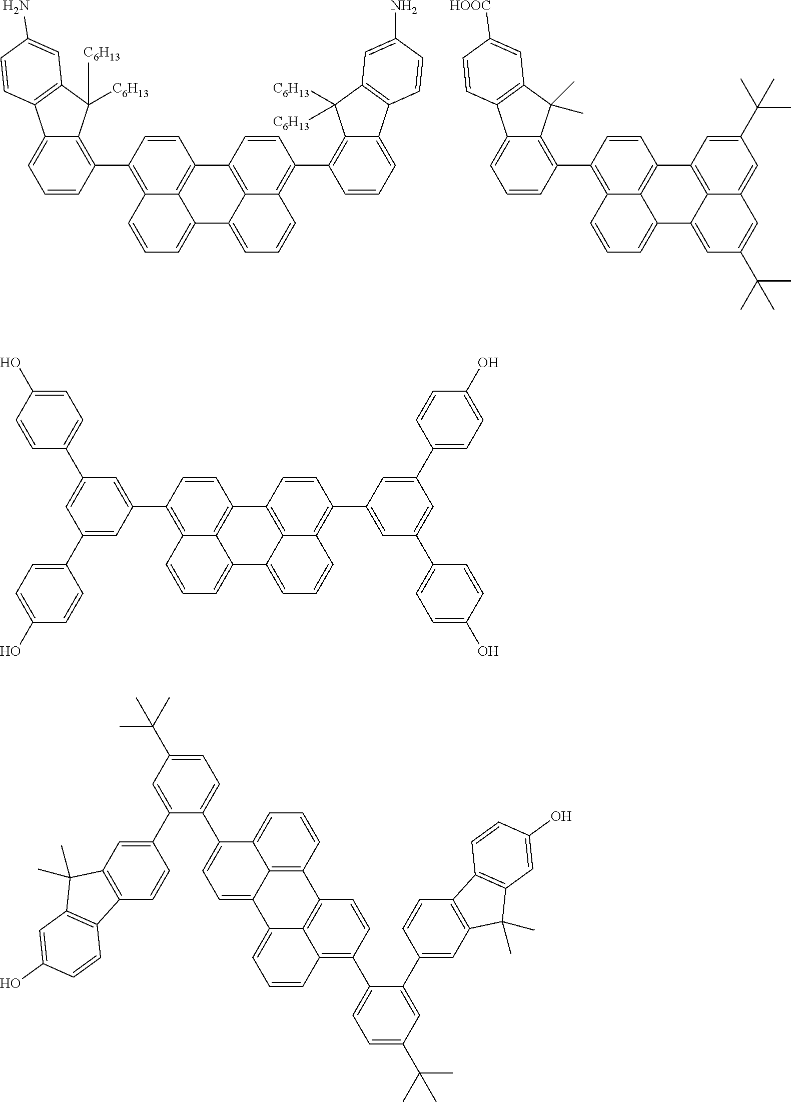

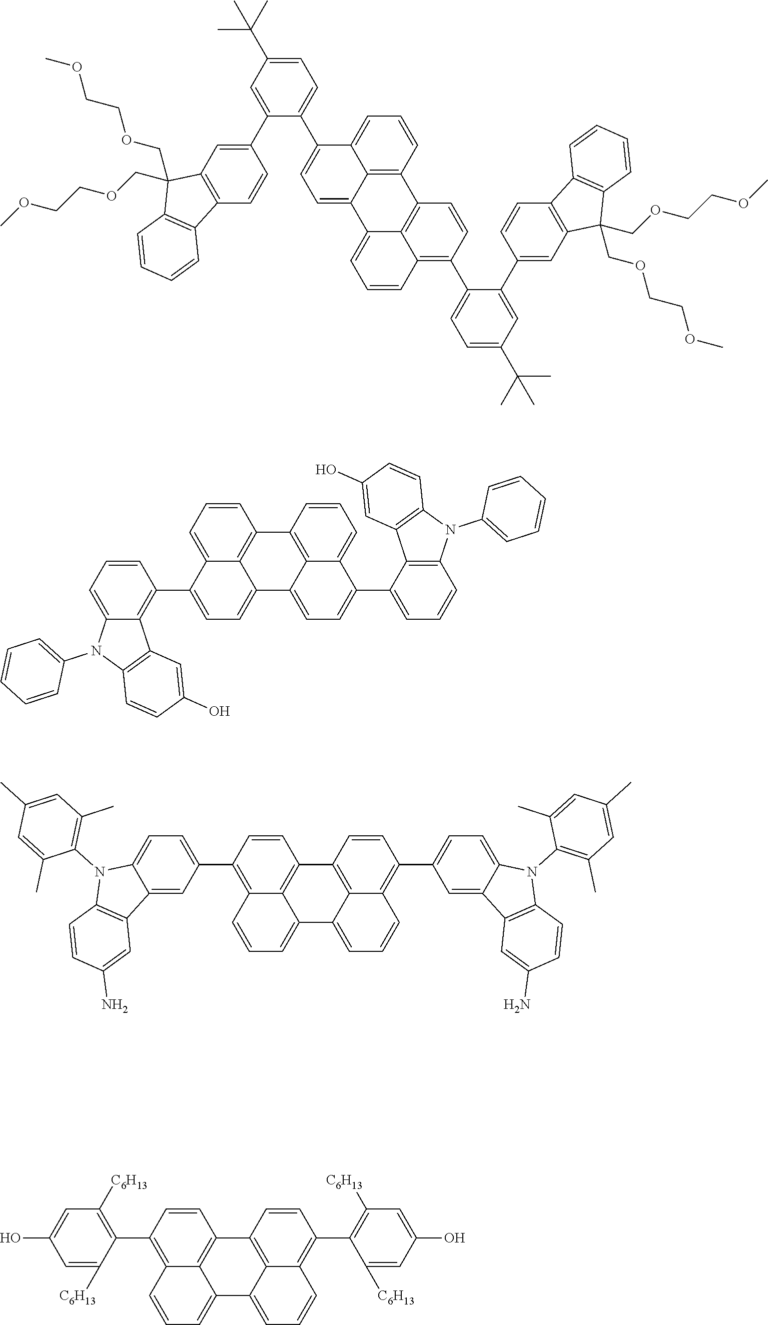

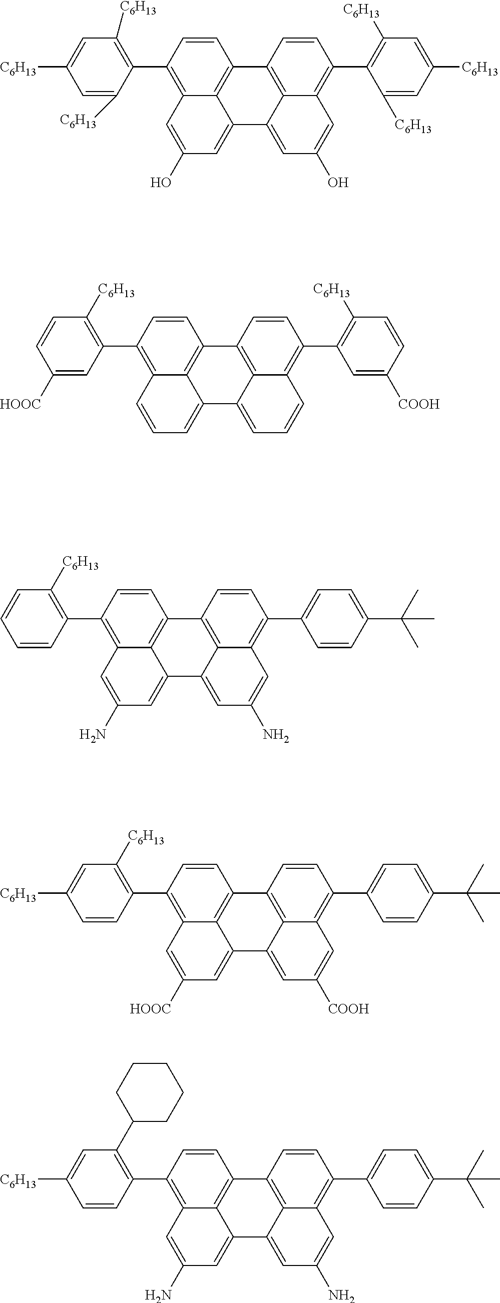

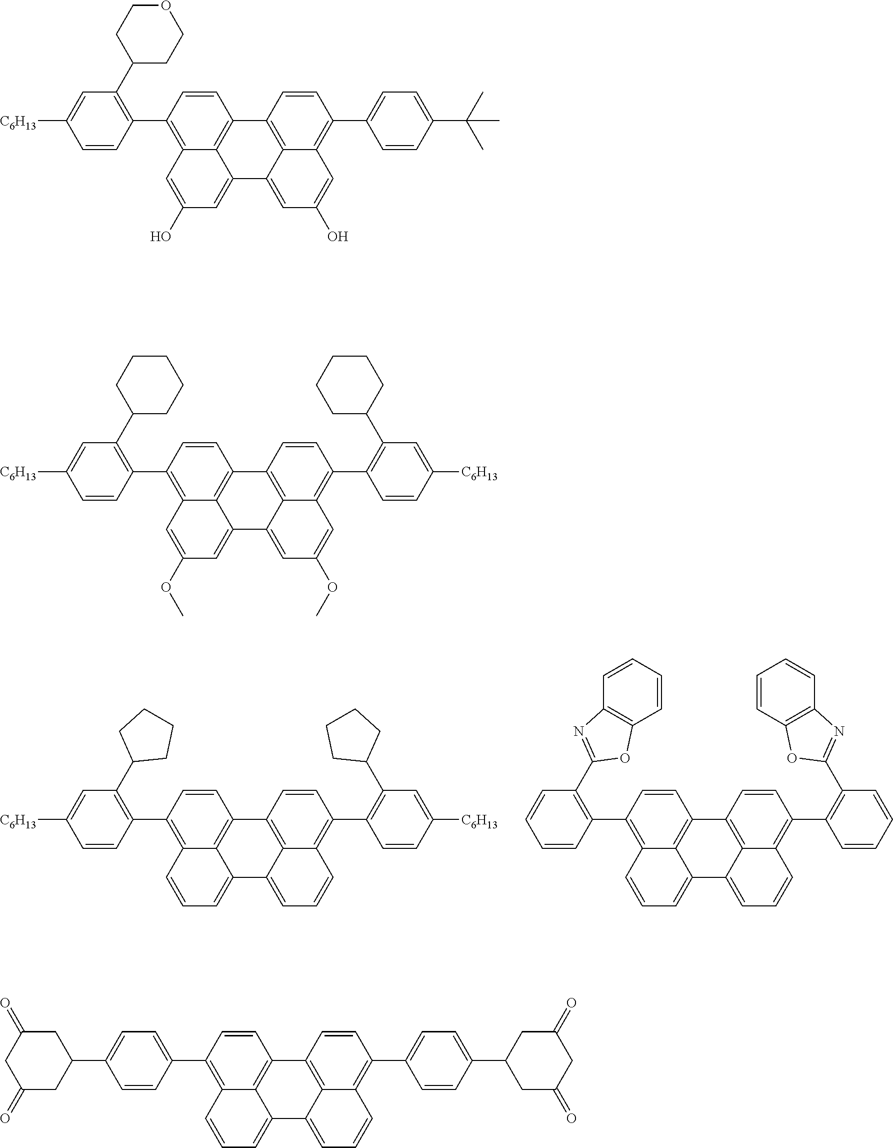

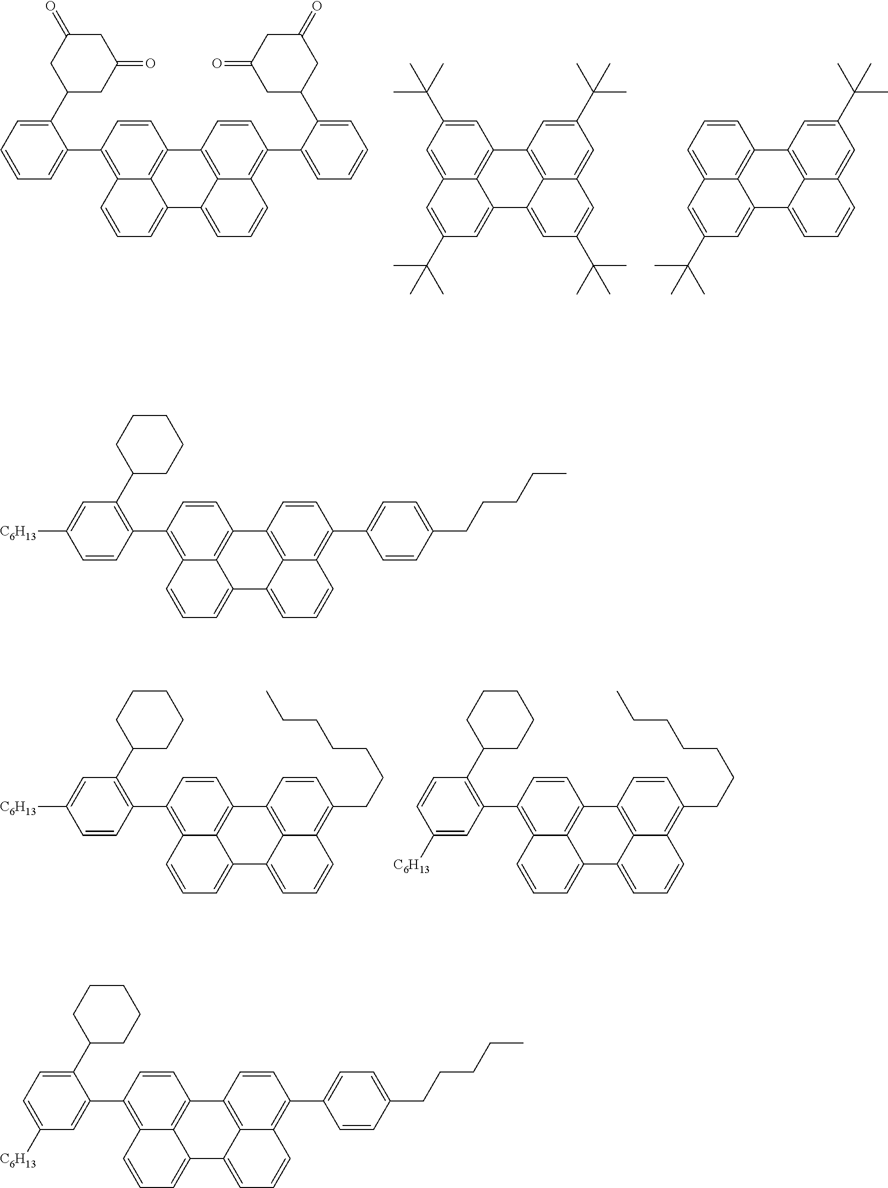

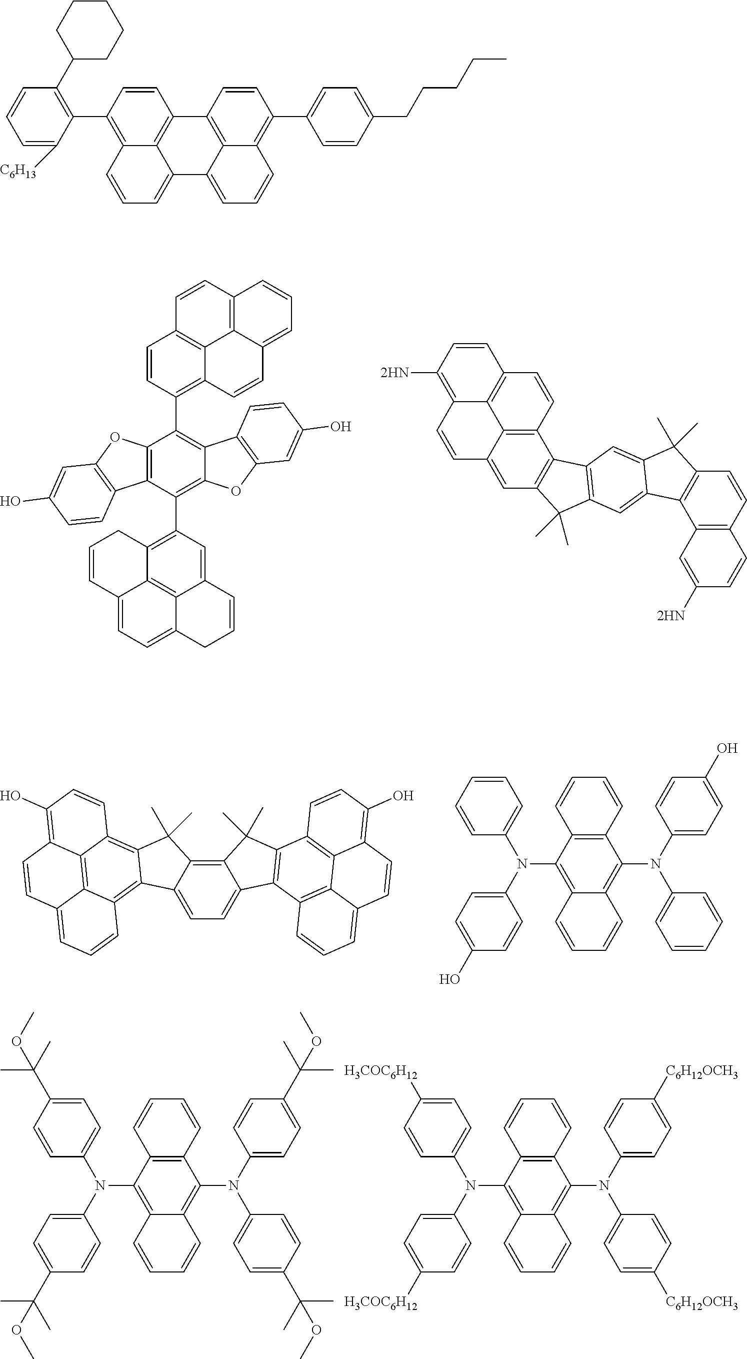

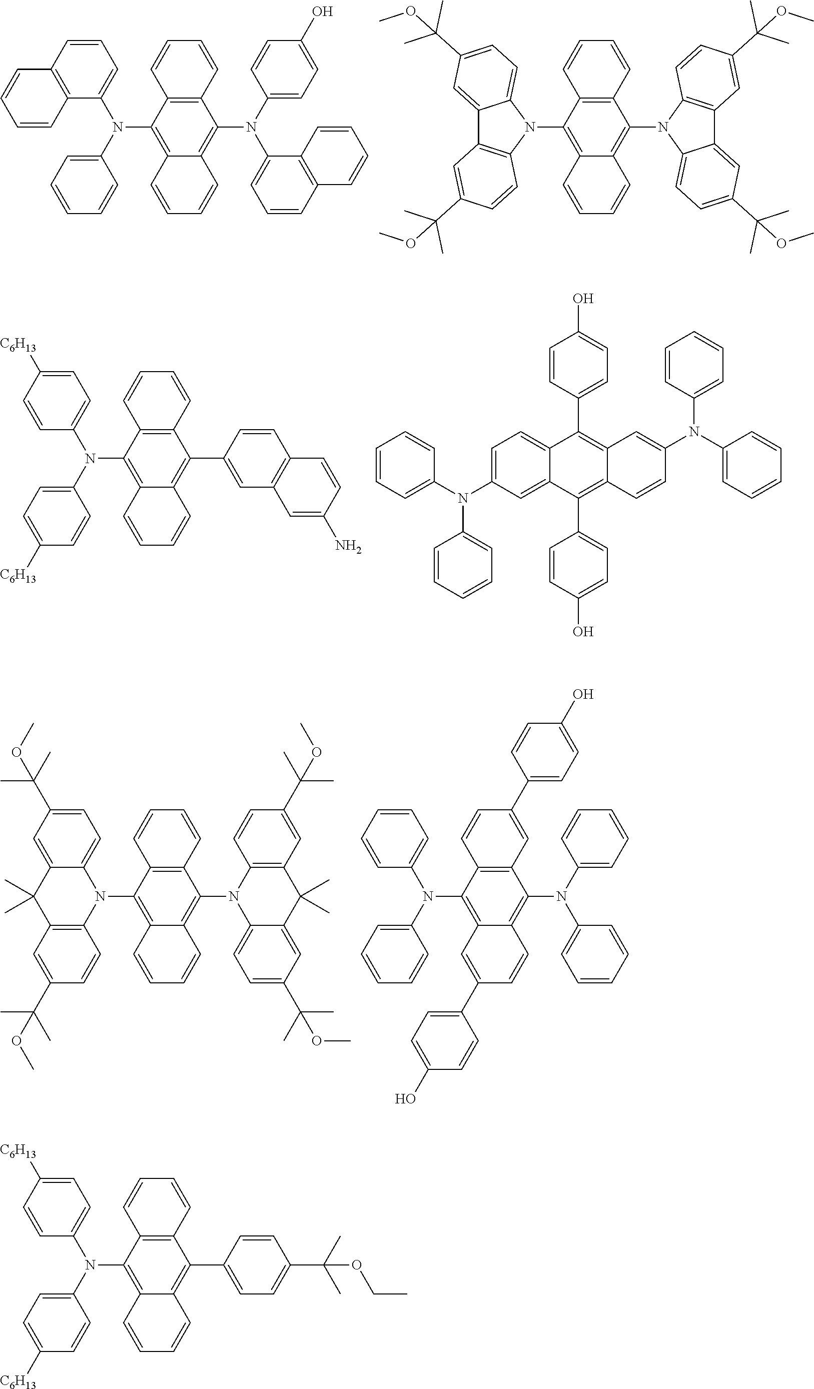

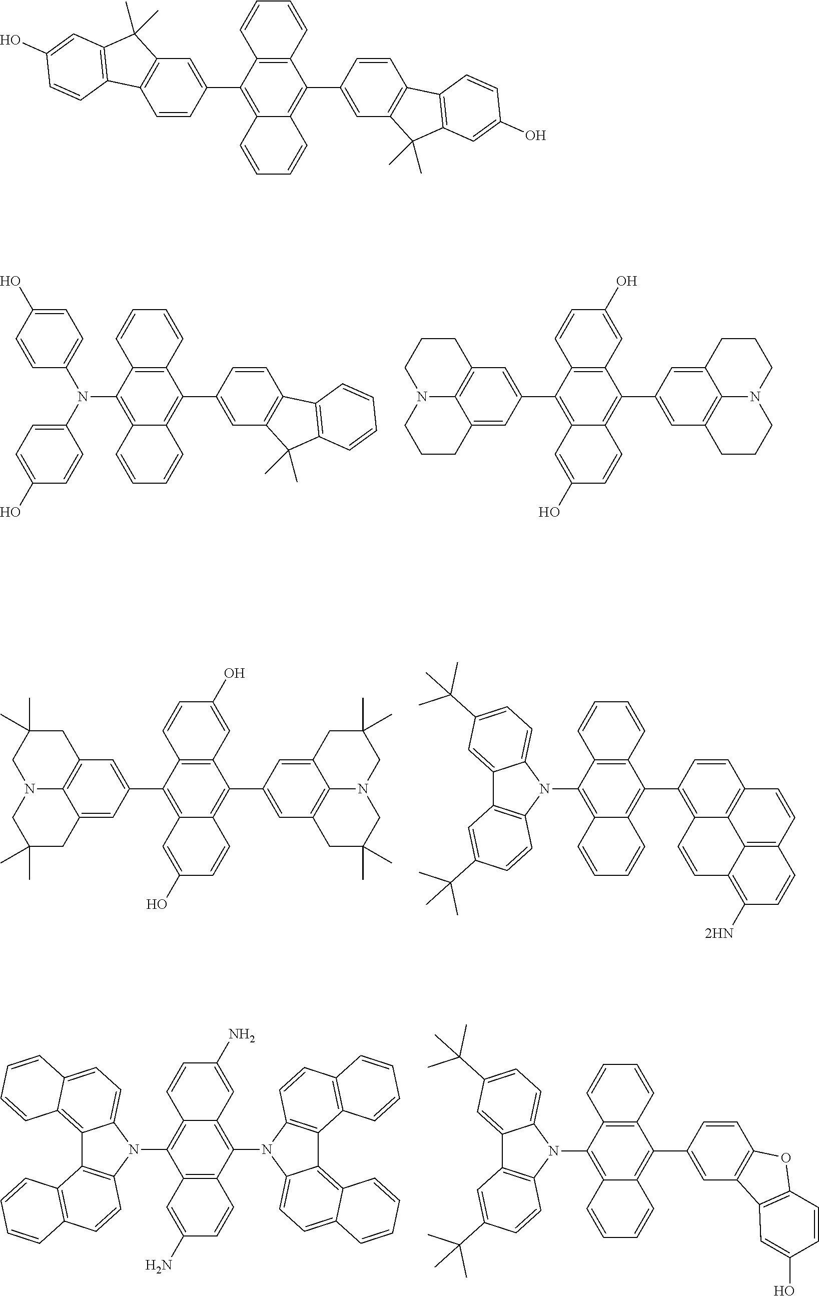

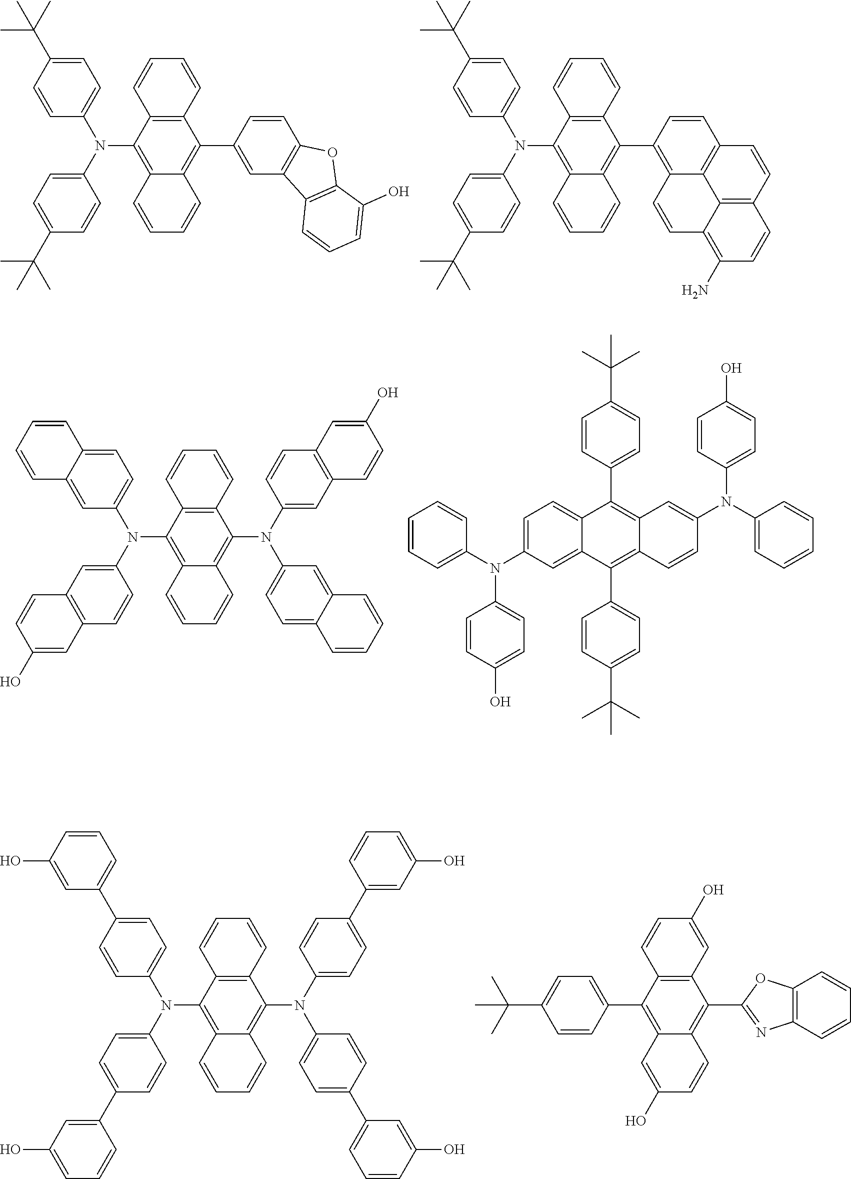

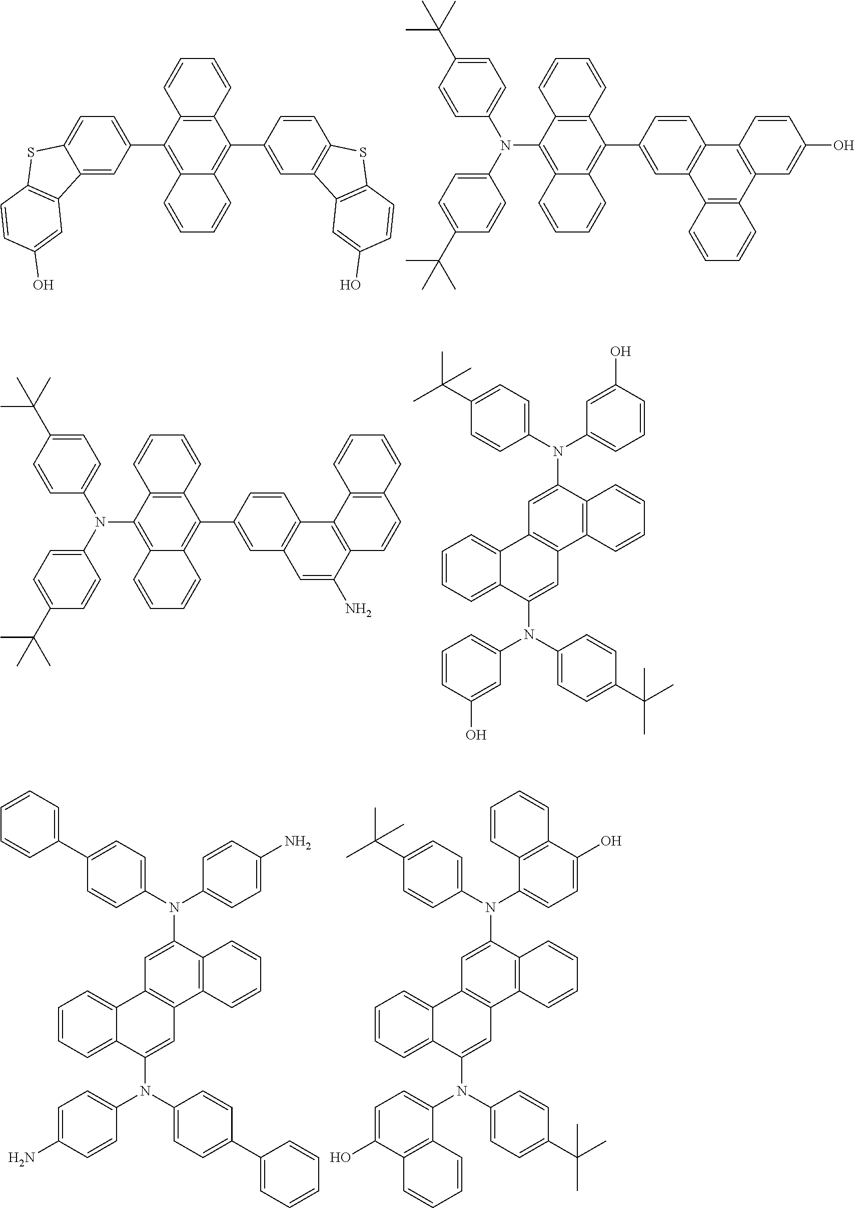

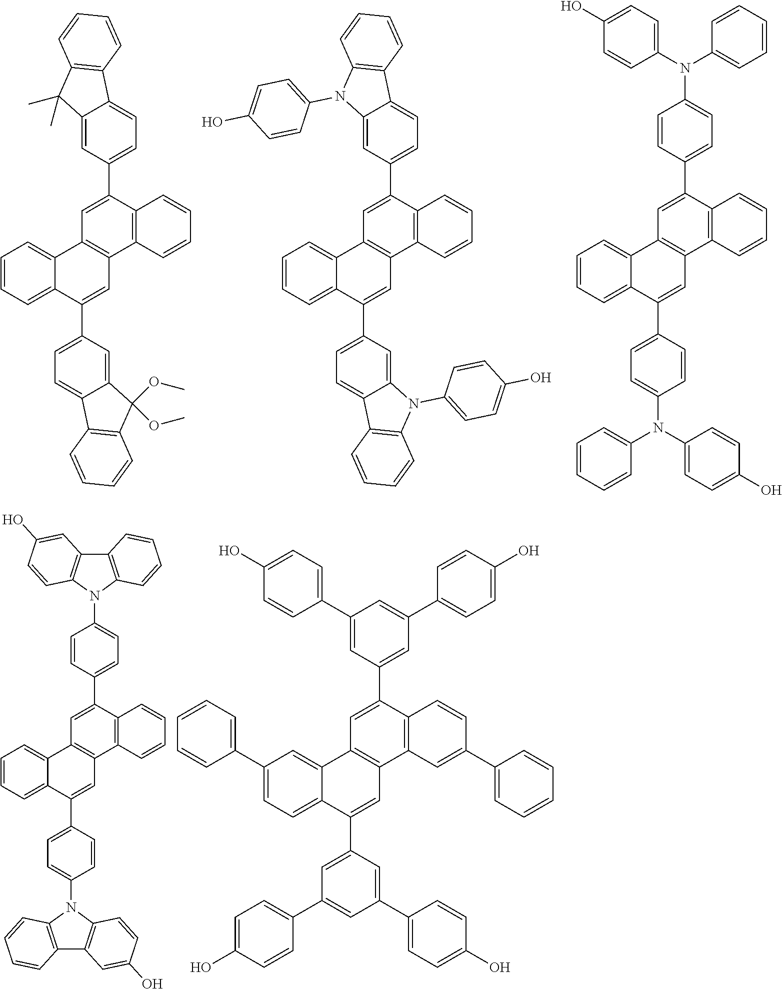

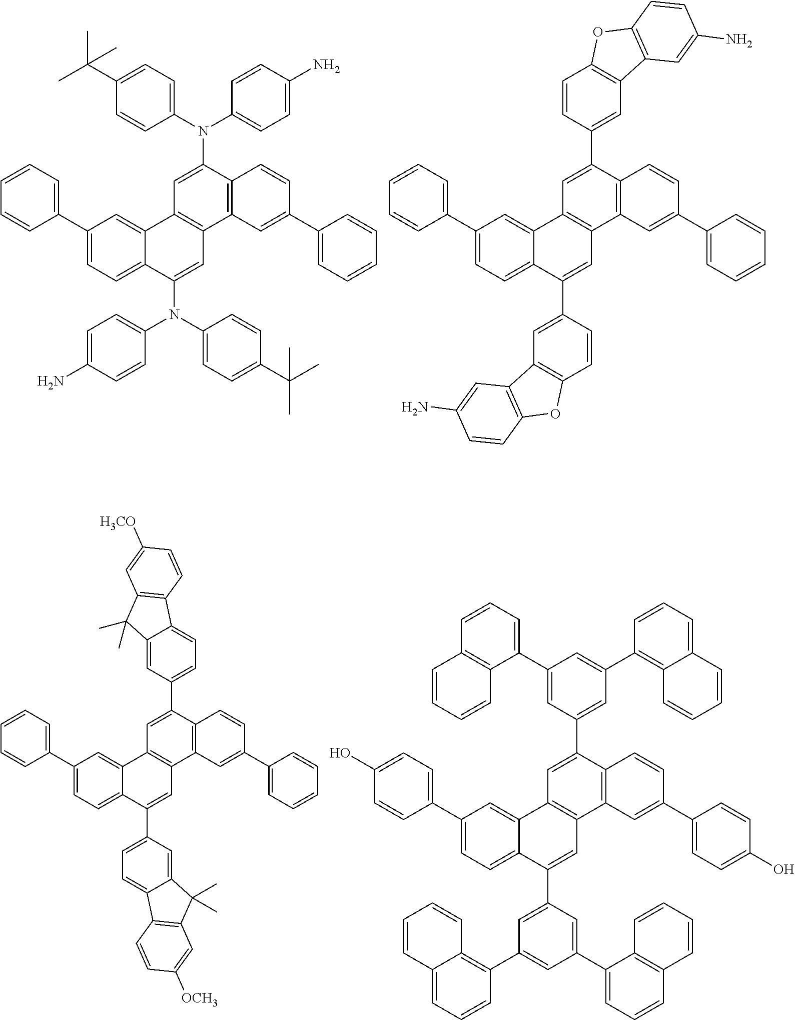

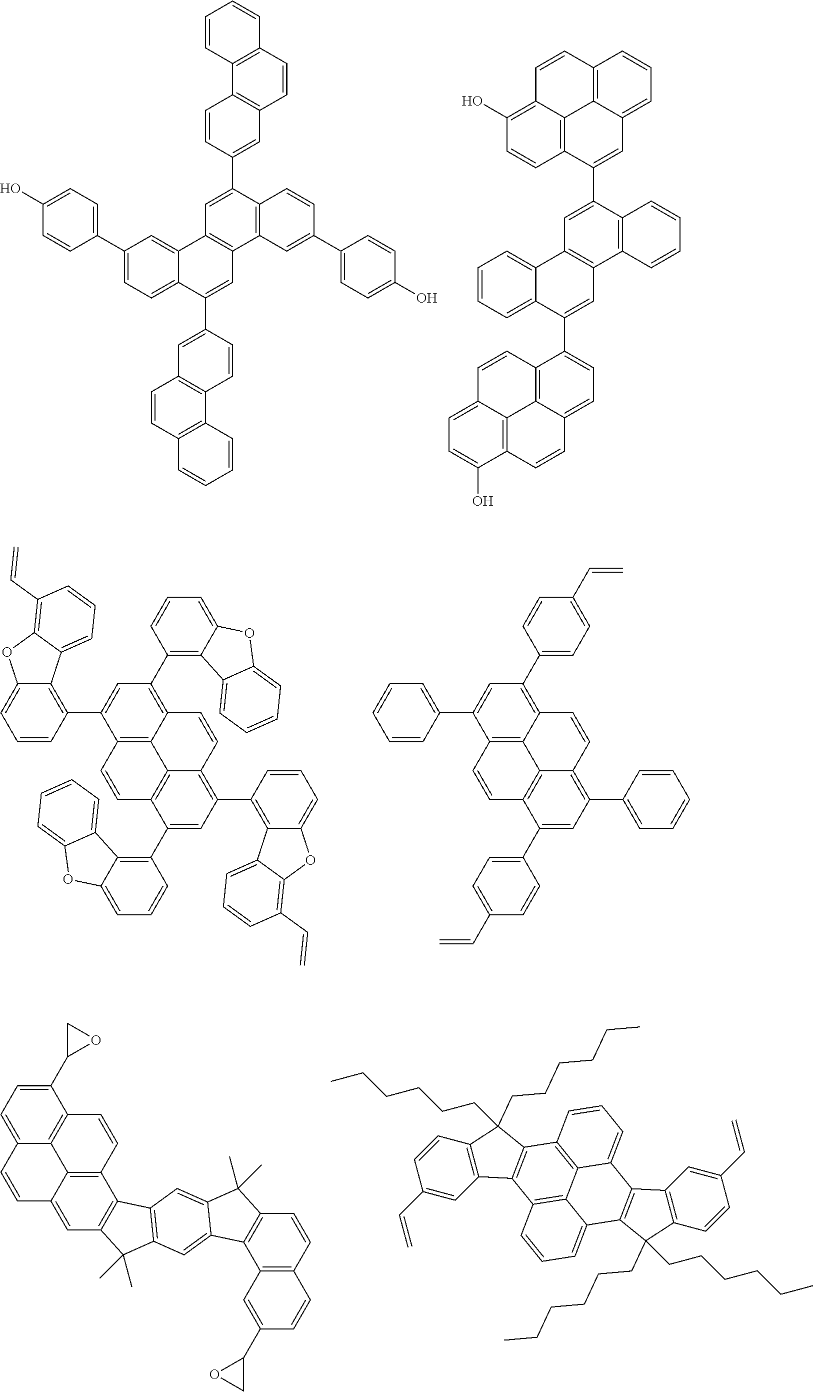

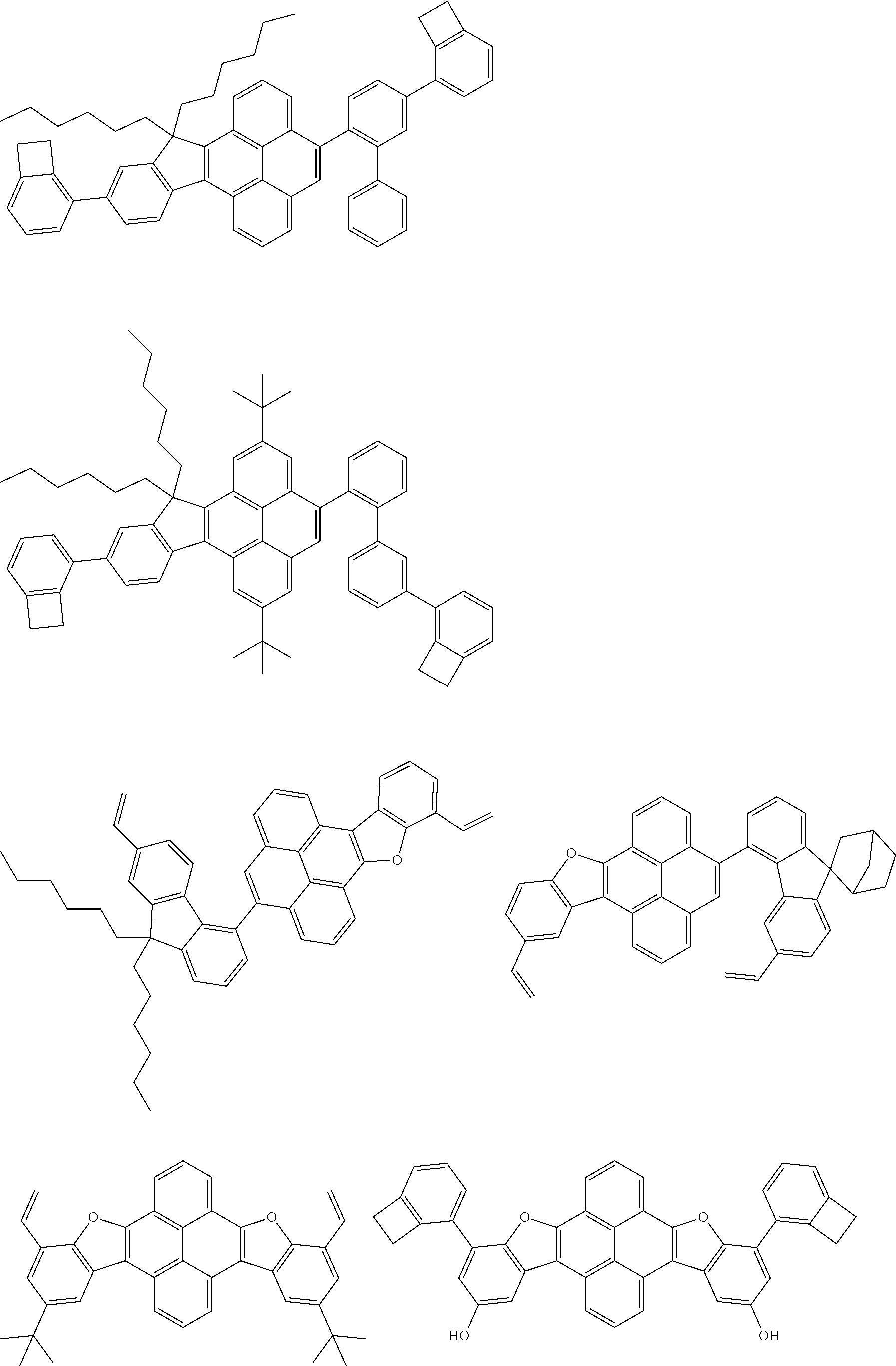

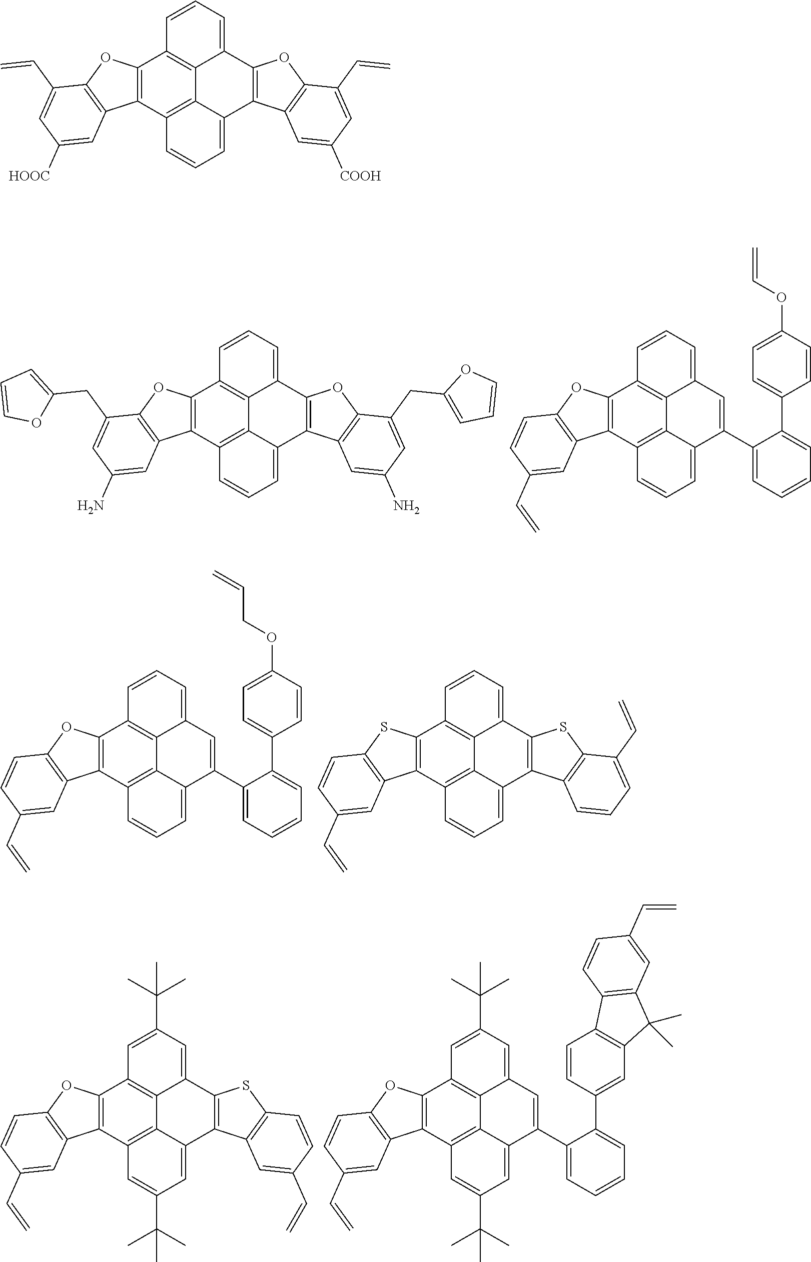

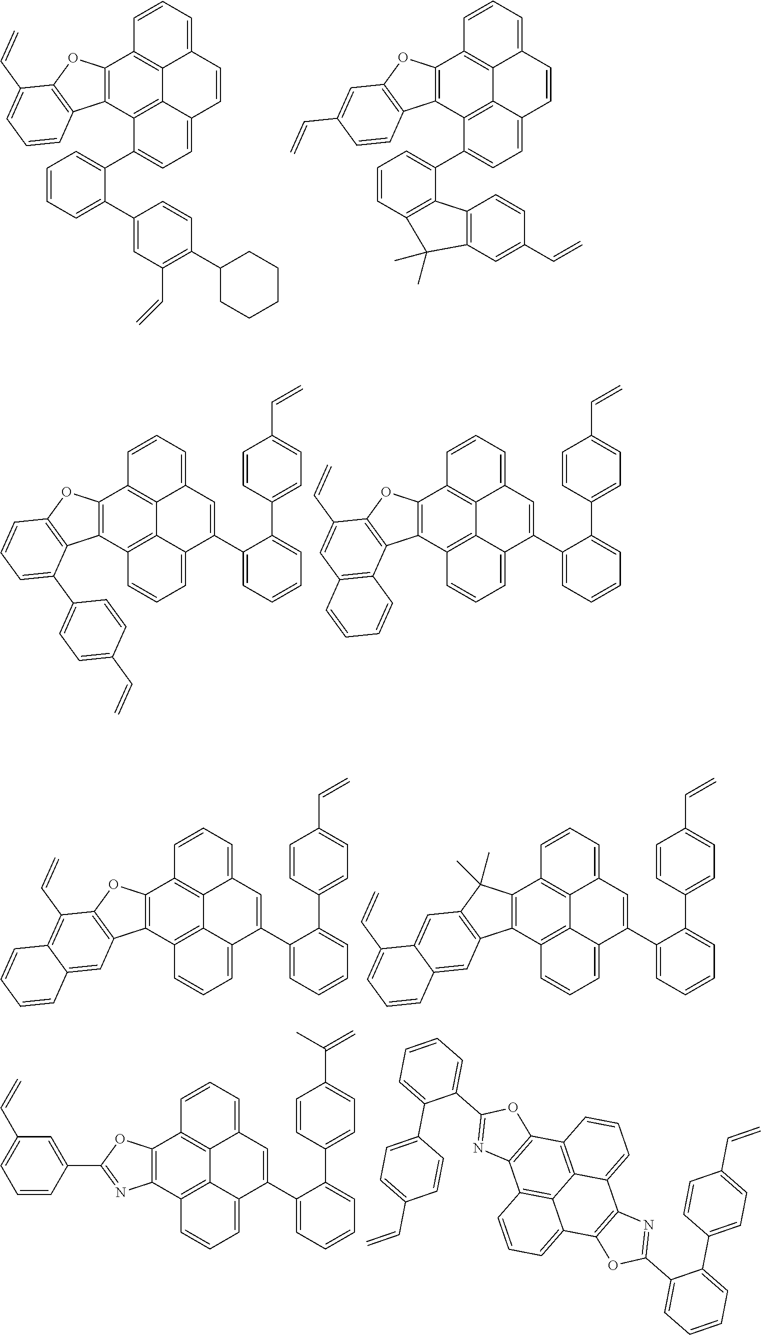

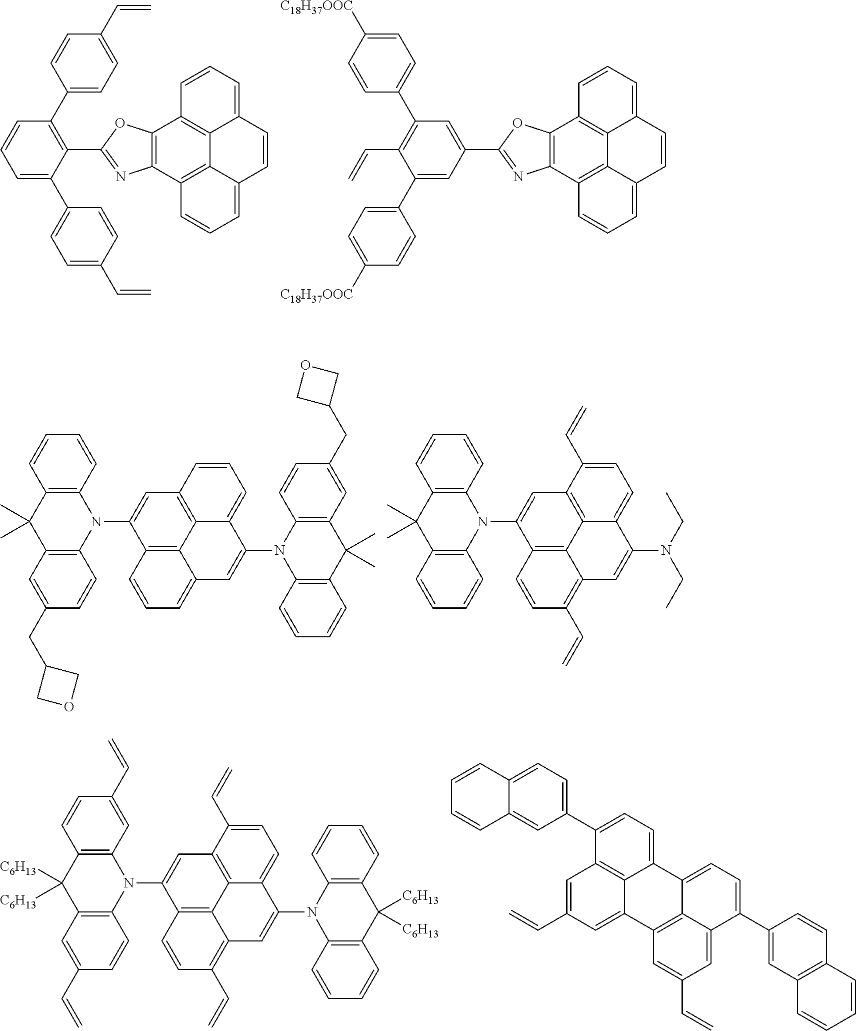

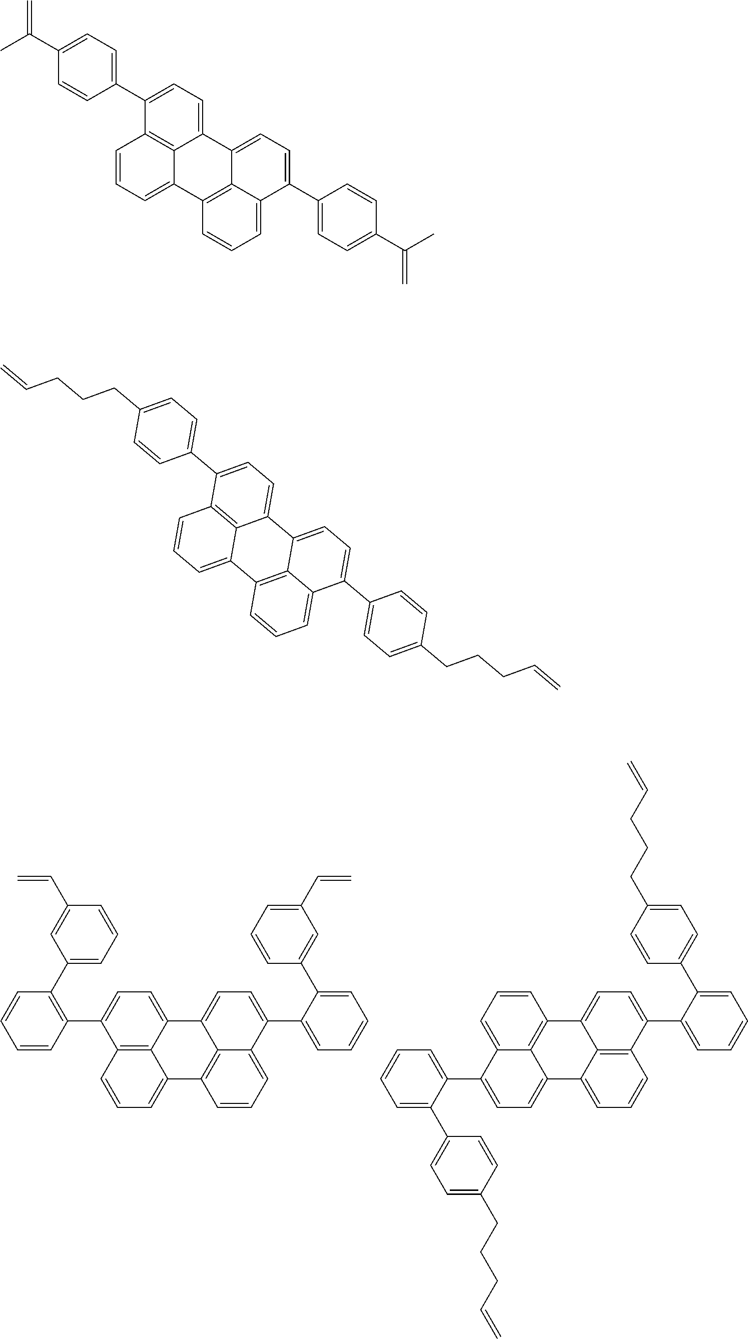

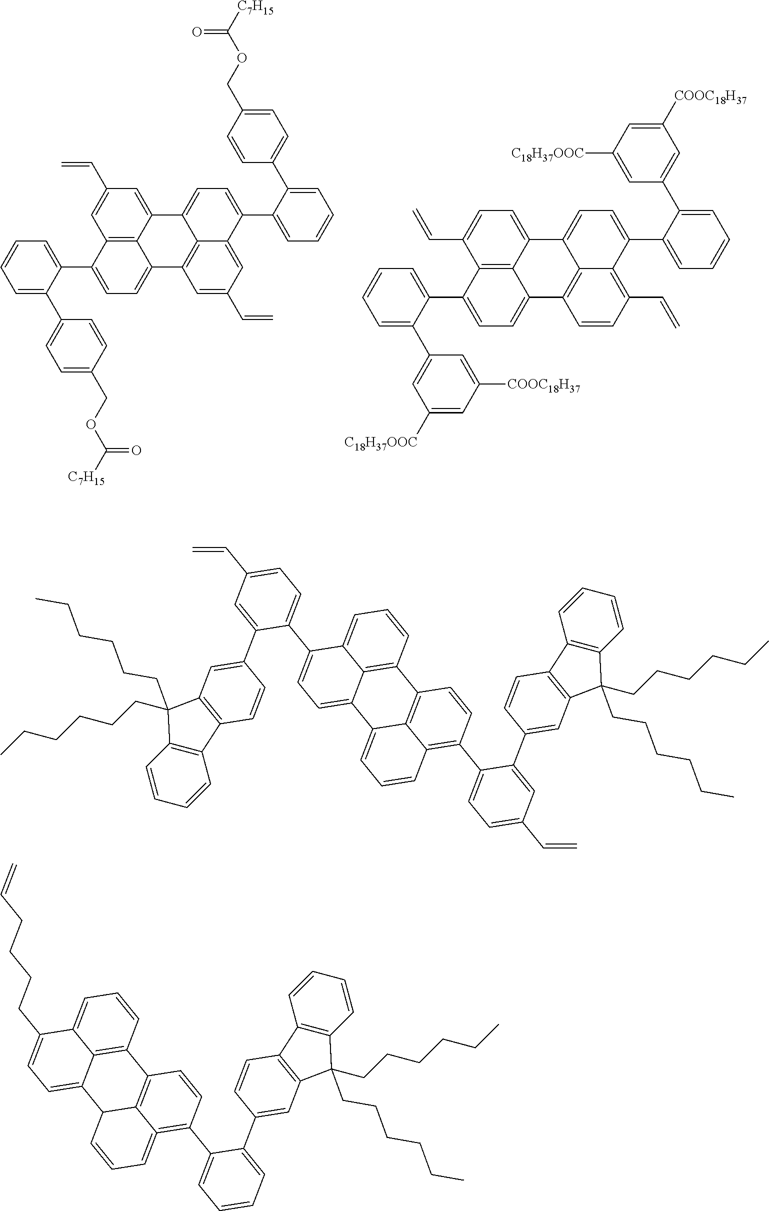

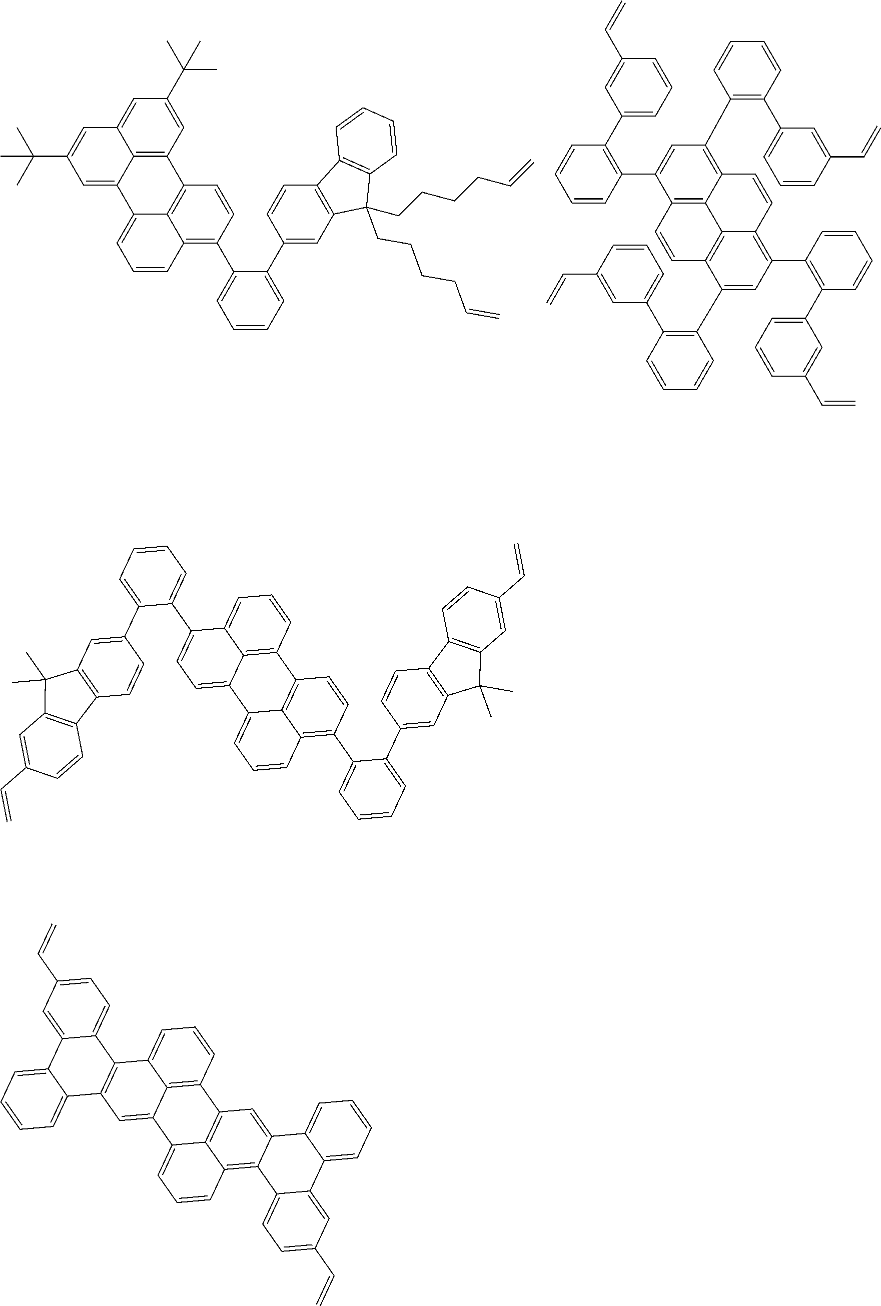

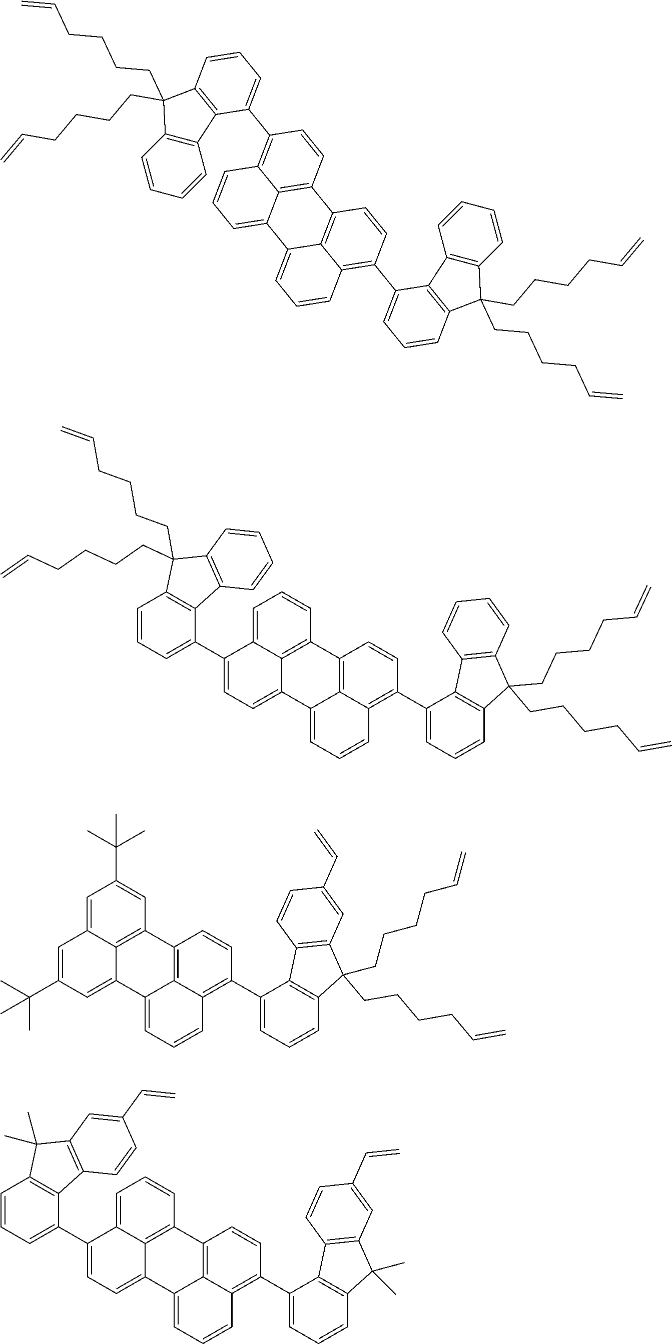

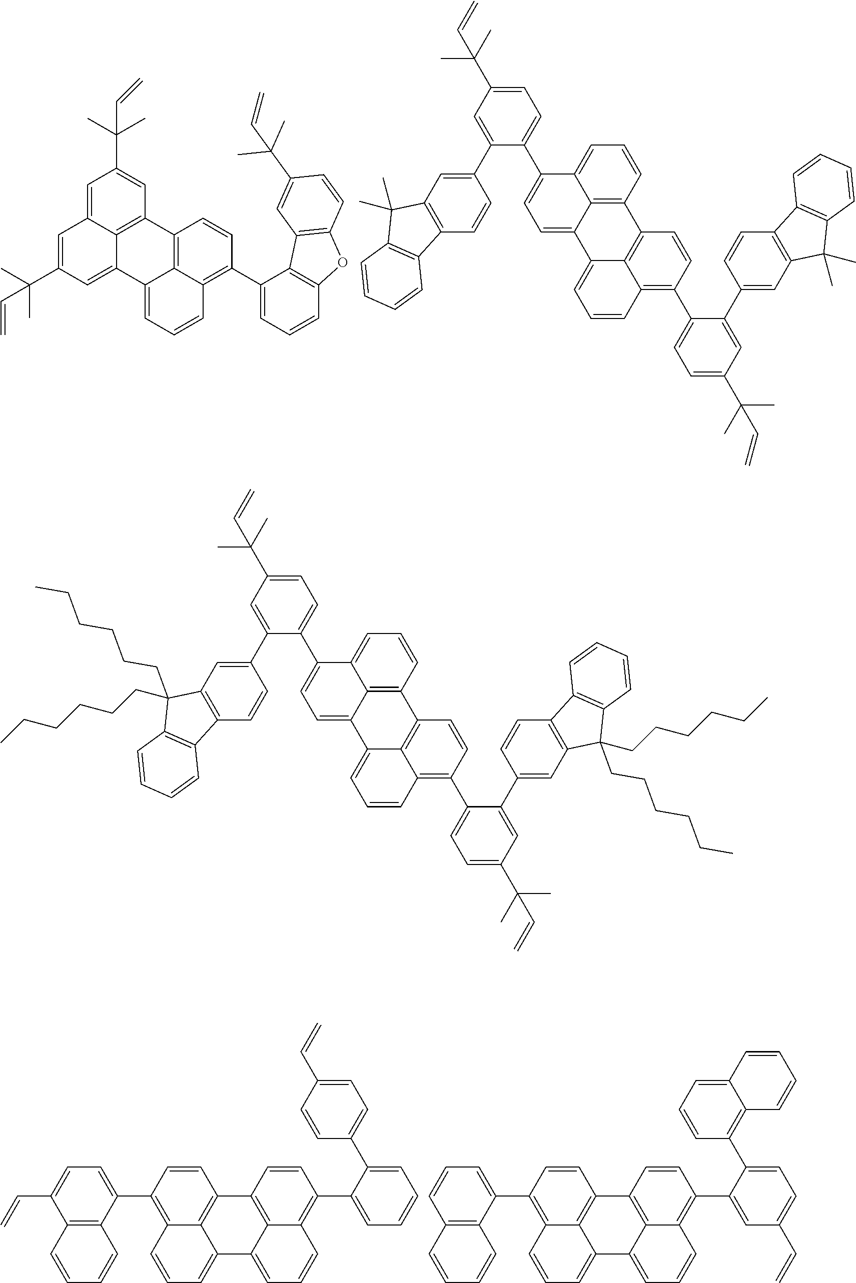

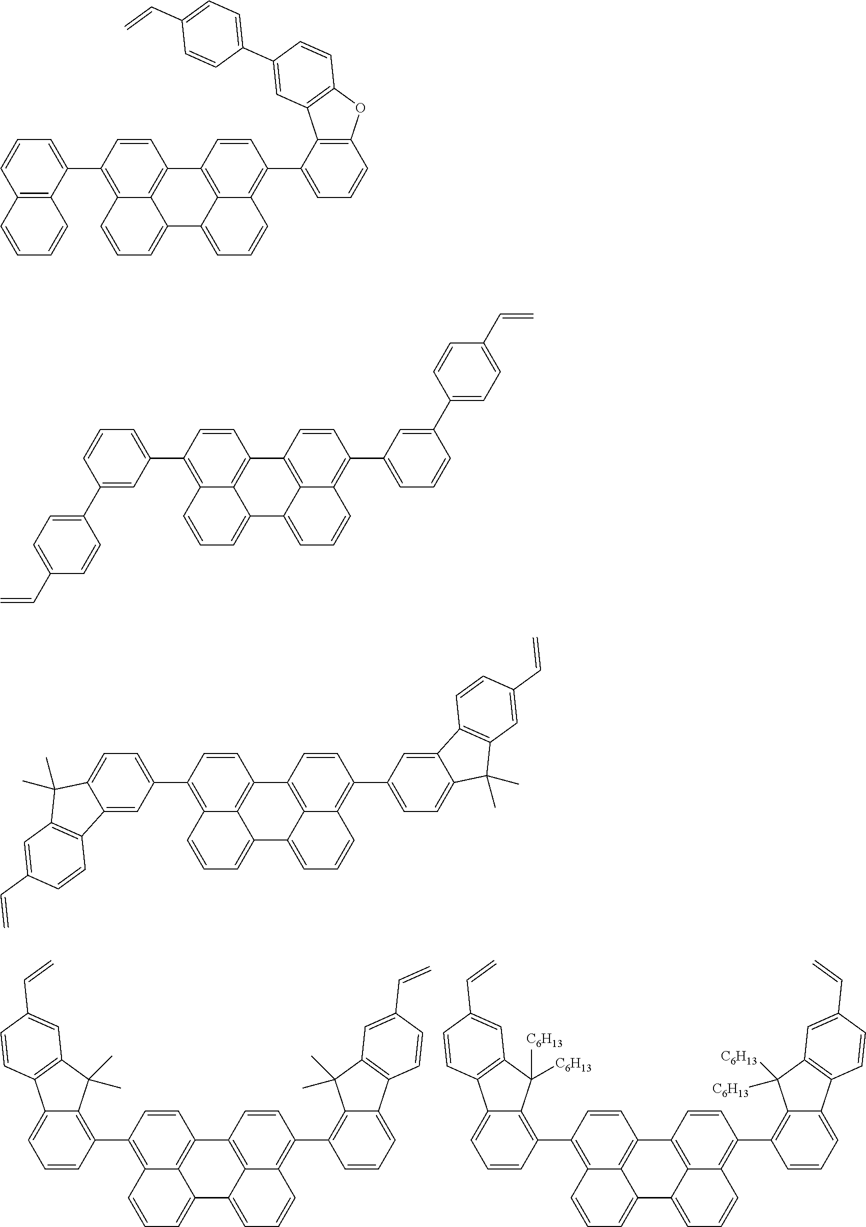

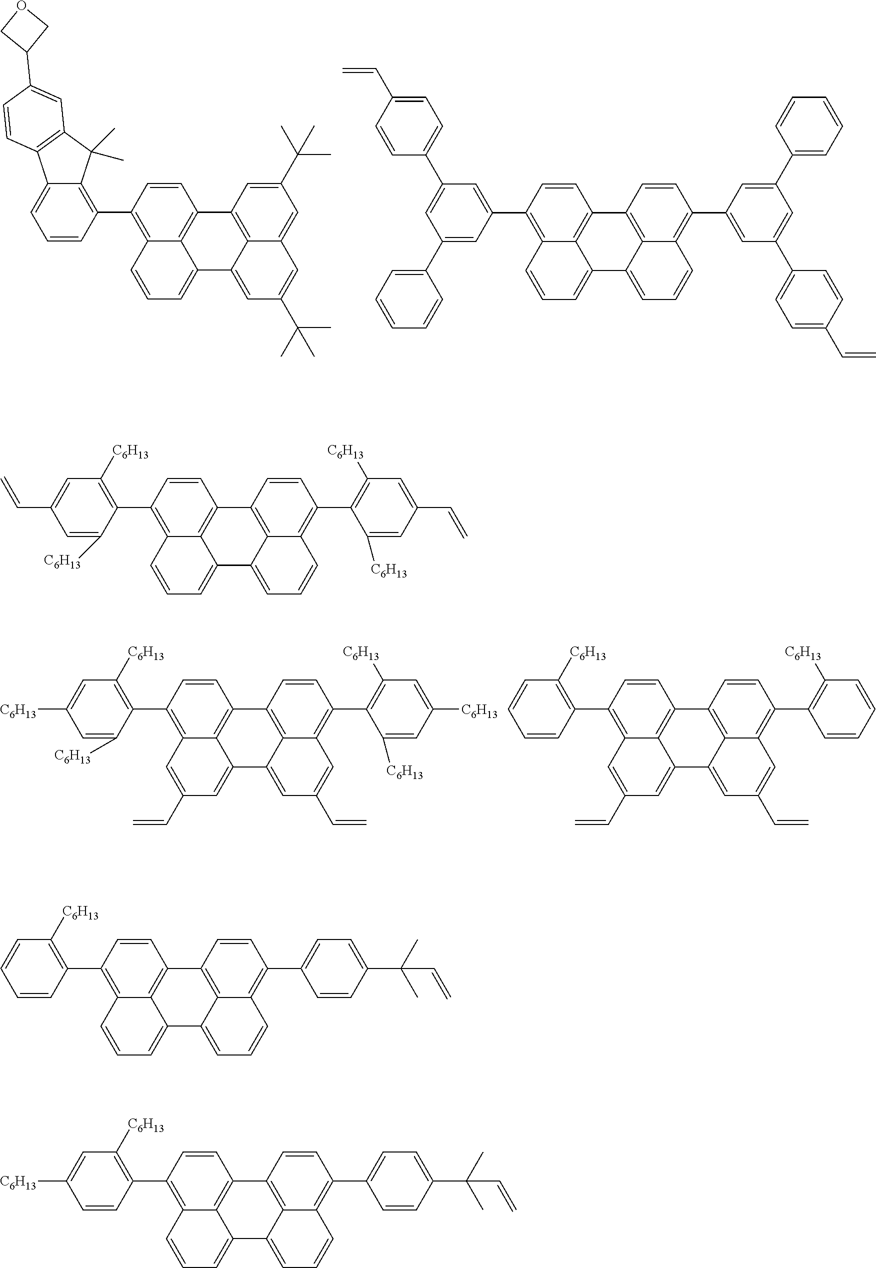

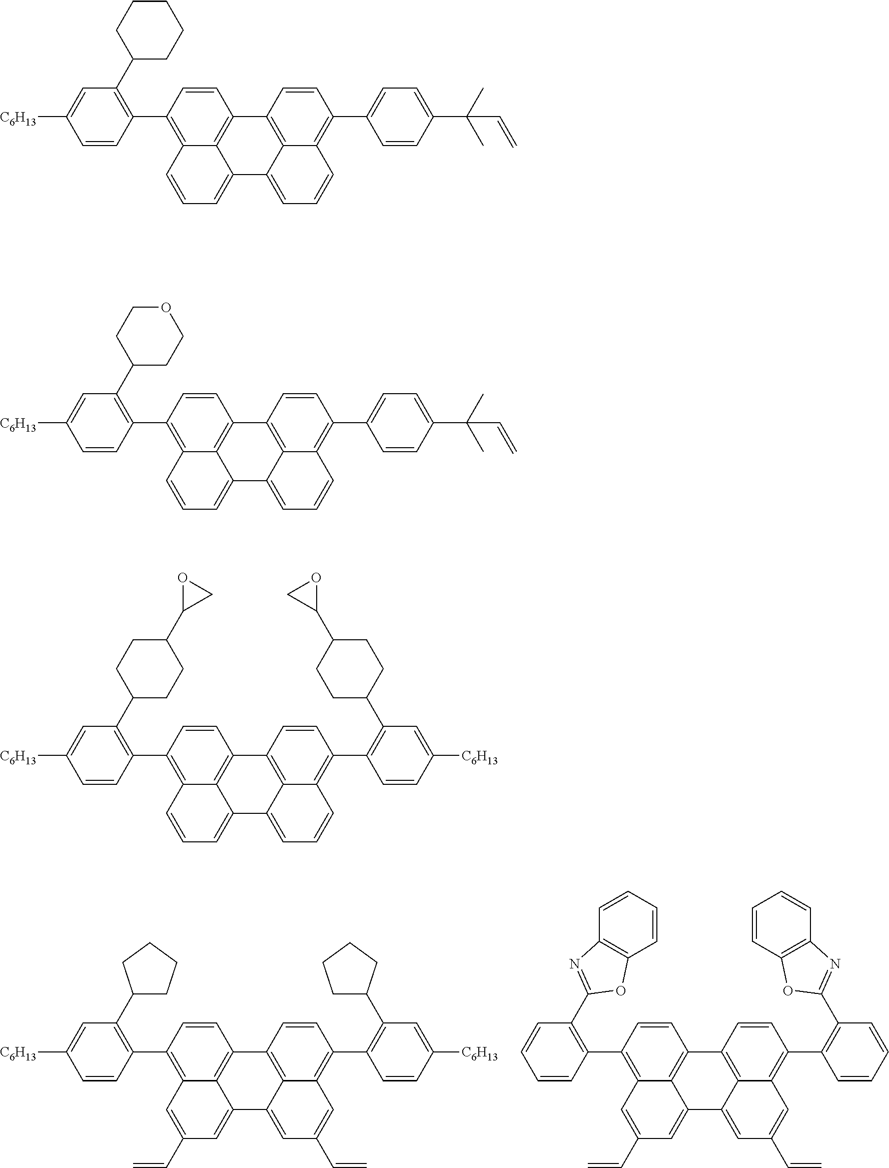

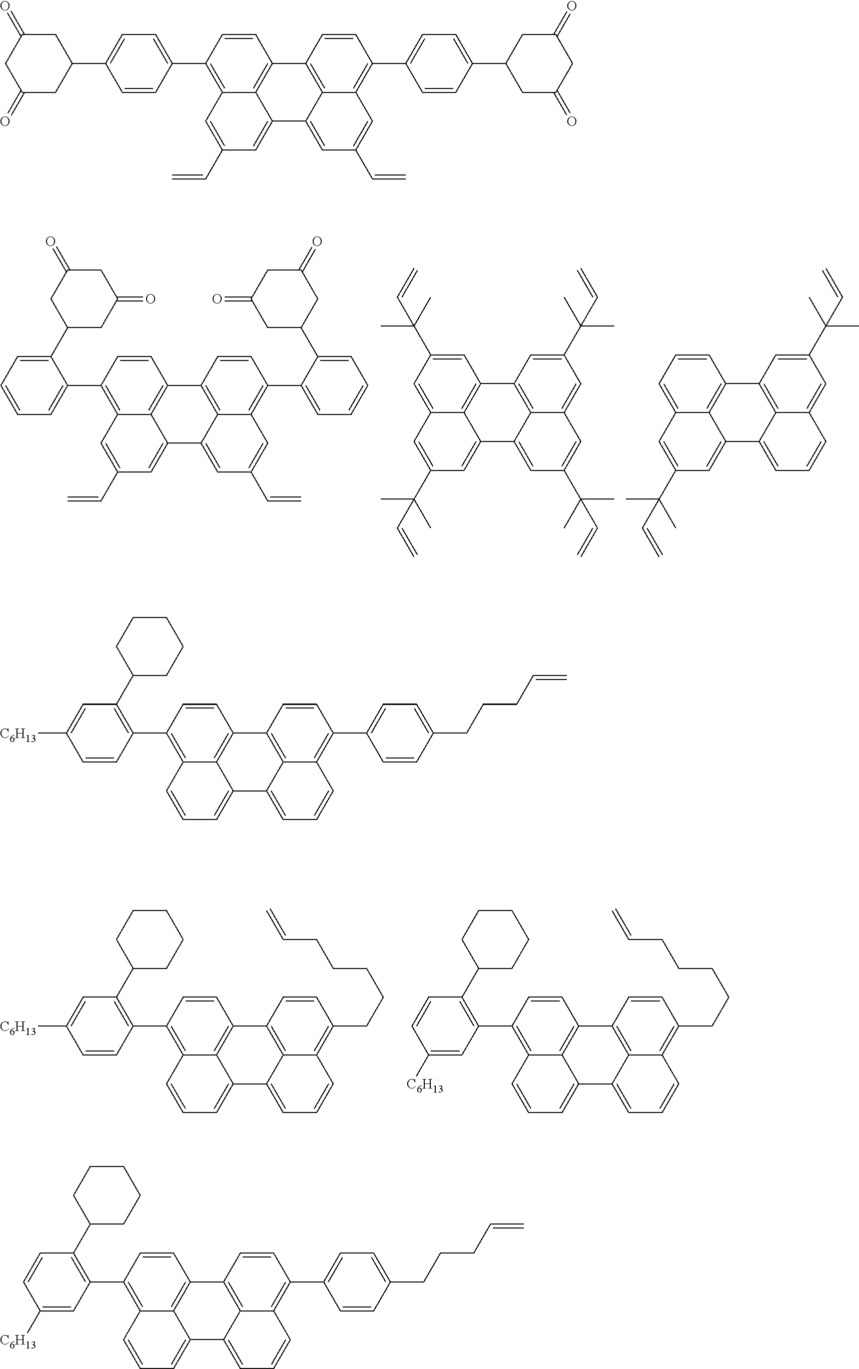

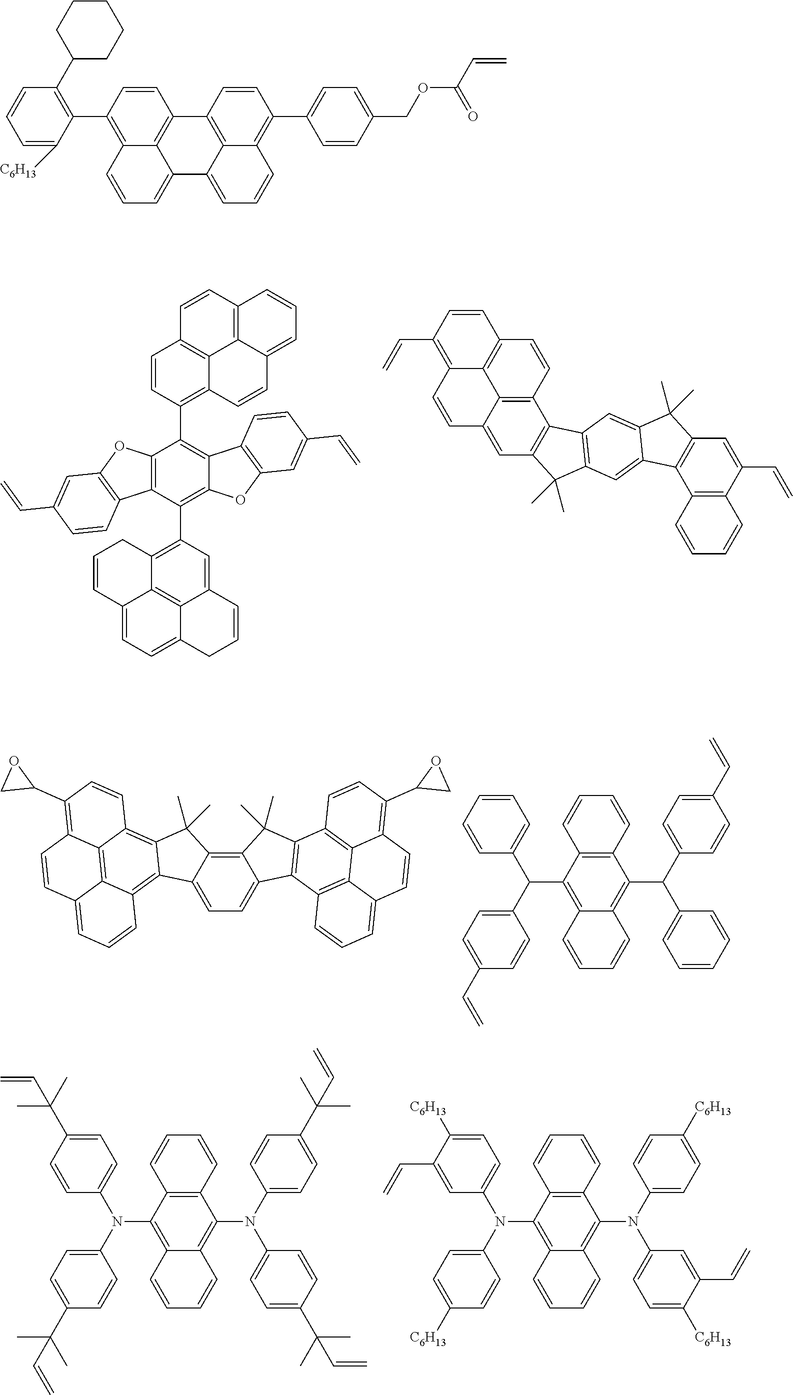

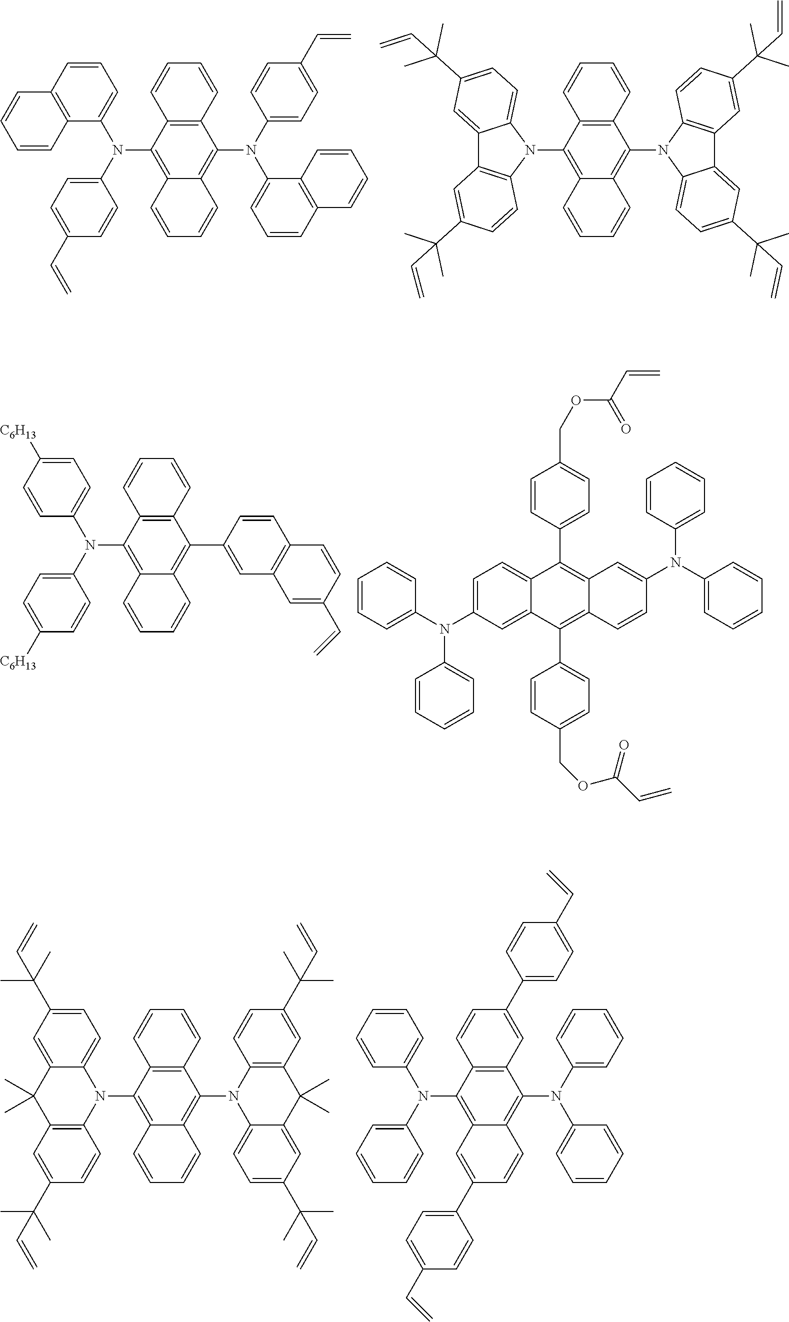

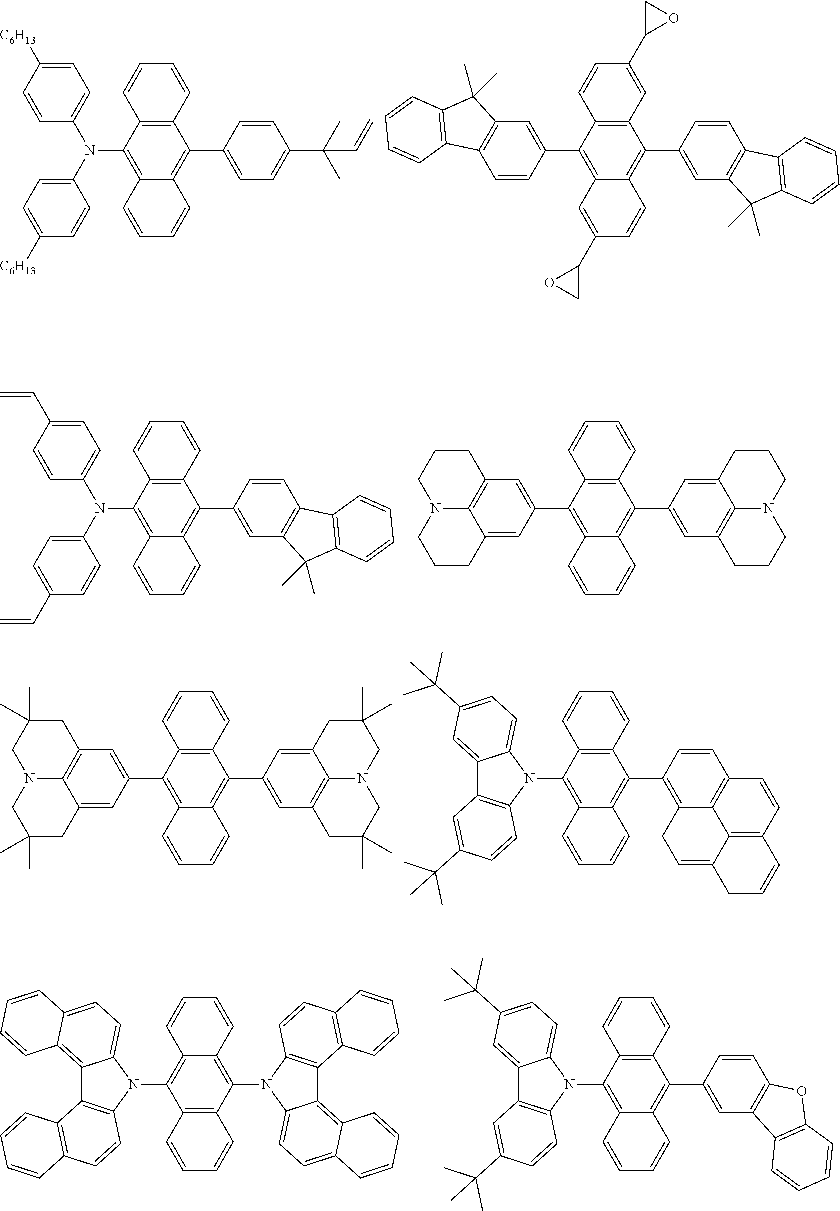

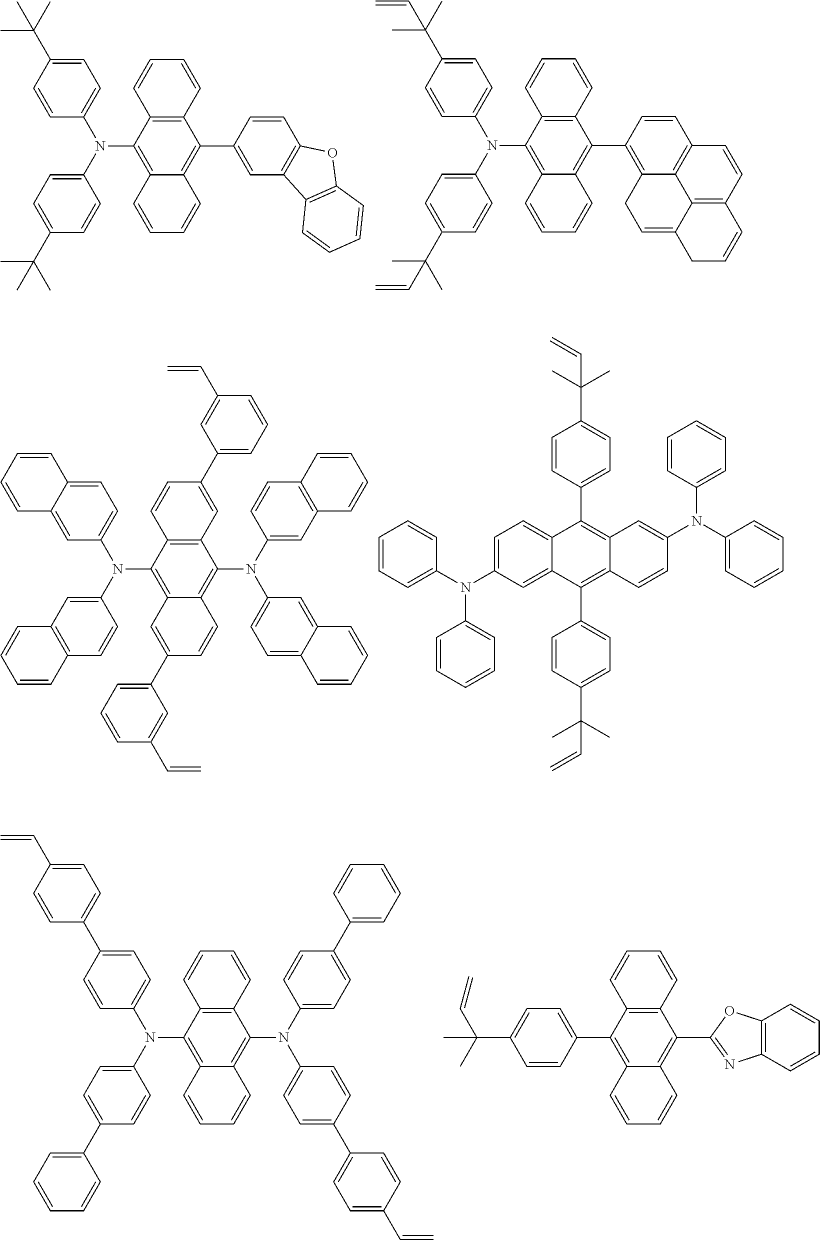

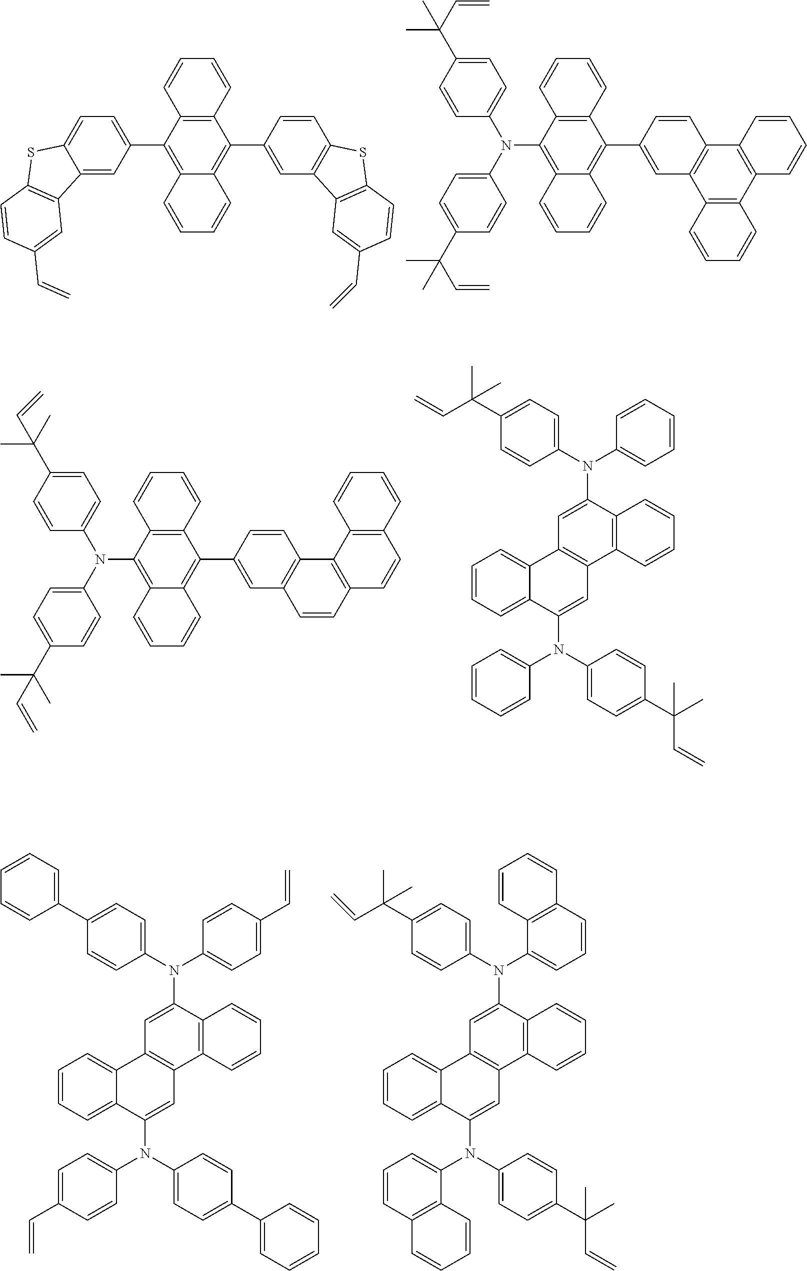

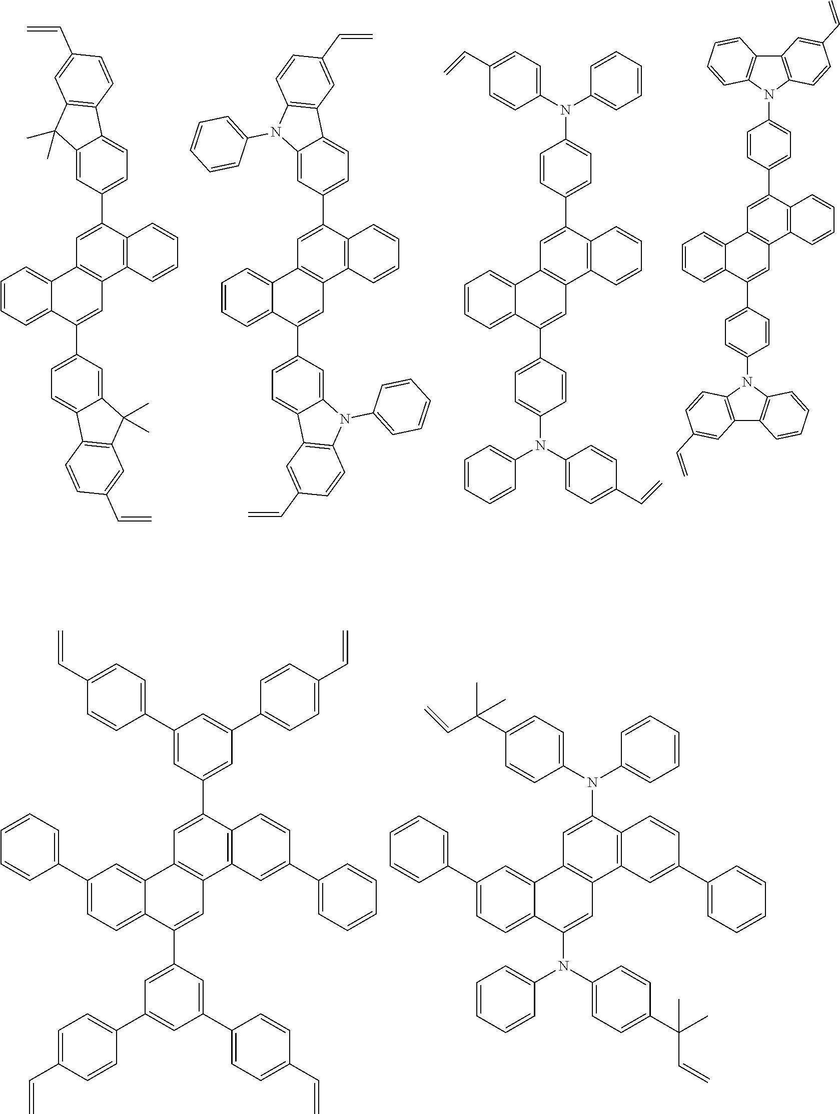

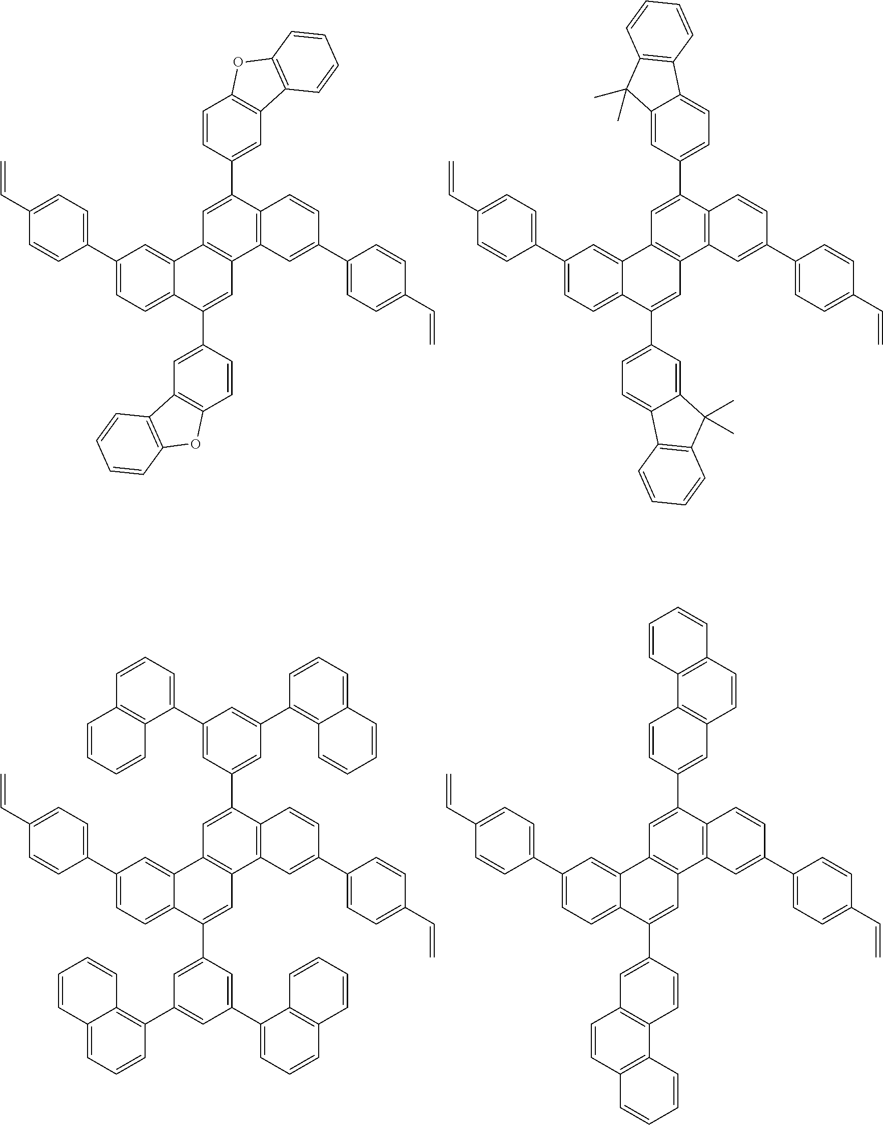

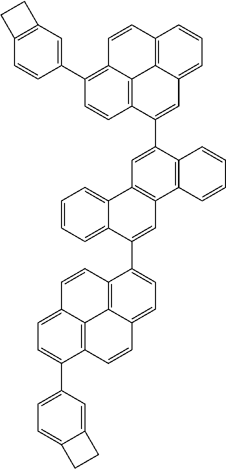 [SMILES: c1cc2ccc3c(-c4ccc5c(c4)CC5)ccc4c(-c5cc6c7ccccc7c(-c7ccc8ccc9c(-c%10ccc%11c(c%10)CC%11)ccc%10ccc7c8c%109)cc6c6ccccc56)cc(c1)c2c34]

In some embodiments, the FWHM of the emission spectrum of the organic compound H≤70 nm, preferably ≤60 nm, more preferably ≤50 nm, further preferably ≤40 nm, and most preferably ≤35 nm.

In some embodiments, the organic compound H is a compound (i.e., Bodipy derivative) having the following structural formula:

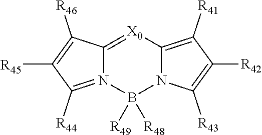

Where X₀ is CR₄₇ or N; R₄₁ to R₄₉ are independently selected from a hydrogen, an alkyl group, a cycloalkyl group, a heterocyclic group, an alkenyl group, a cycloalkenyl group, an alkynyl group, a hydroxy group, a mercapto group, an alkoxy group, an alkylthio group, an aryl ether group, an aryl thioether group, an aryl group, a heteroaryl group, a halogen, a cyano group, an aldehyde group, a carbonyl group, a carboxy group, an oxycarboxyl group, a carbamoyl group, an amino group, a nitro group, a silyl group, a siloxanyl group, a boronalkyl group, or a phosphorus oxide group; R₄₁-R₄₉ may form a fused ring and an aliphatic ring with the adjacent substituents therebetween.

In some embodiments, each of R₄₈ and R₄₉ is electron-withdrawing group. The suitable electron-withdrawing groups include, but not limited to, F, Cl, a cyano group, a partial/perfluorinated alkyl chain, or one of the following groups:

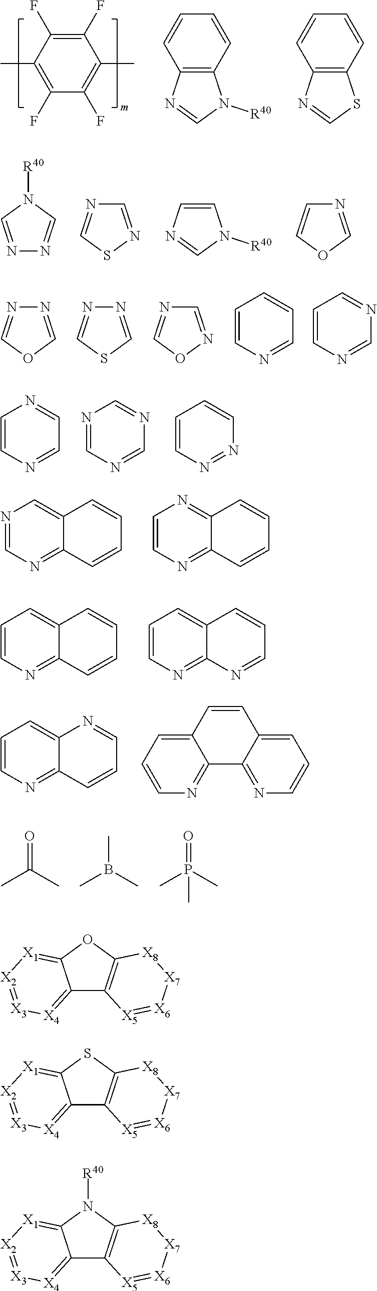

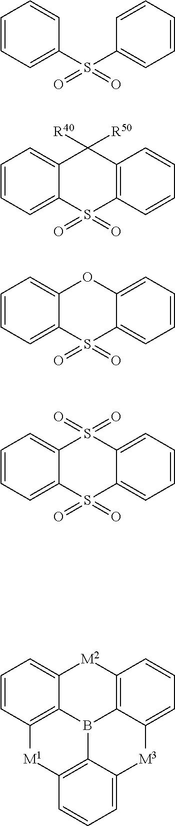

[symbol]

Where m is 1, or 2, or 3; each of X₁ to X₈ is CR⁴⁰ or N, and at least one of them is N; M¹, M², and M³ independently represent N(R⁴⁰), C(R⁴⁰R⁵⁰), Si(R⁴⁰R⁵⁰), O, C═N(R⁴⁰), C═C(R⁴⁰R⁵⁰), P(R⁴⁰), P(═O)R⁴⁰, S, S═O, SO₂, or null; R⁴⁰ and R⁵⁰ are identically defined as the above-mentioned R¹.

Examples of suitable Bodipy derivatives include, but not limited to,

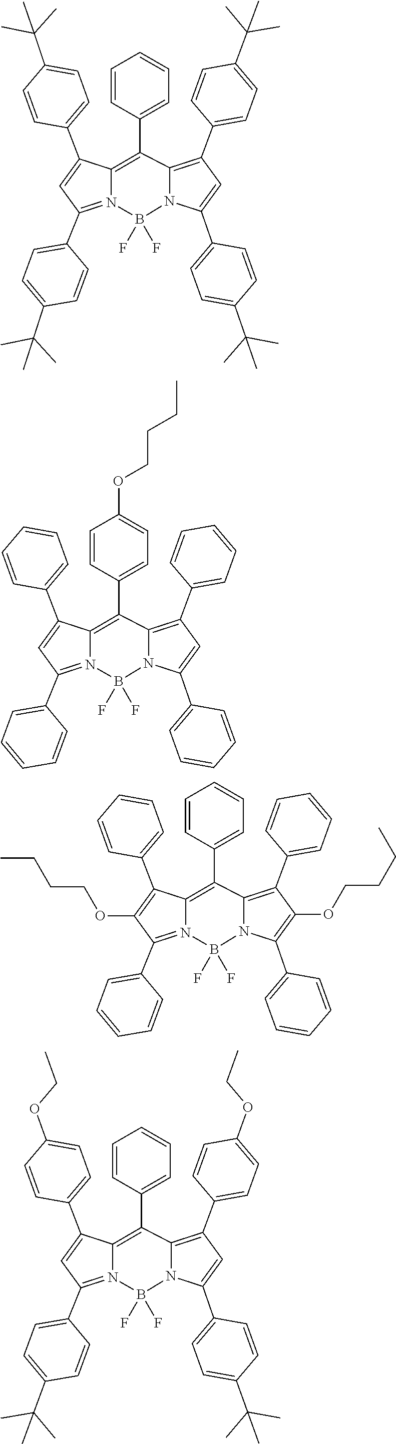

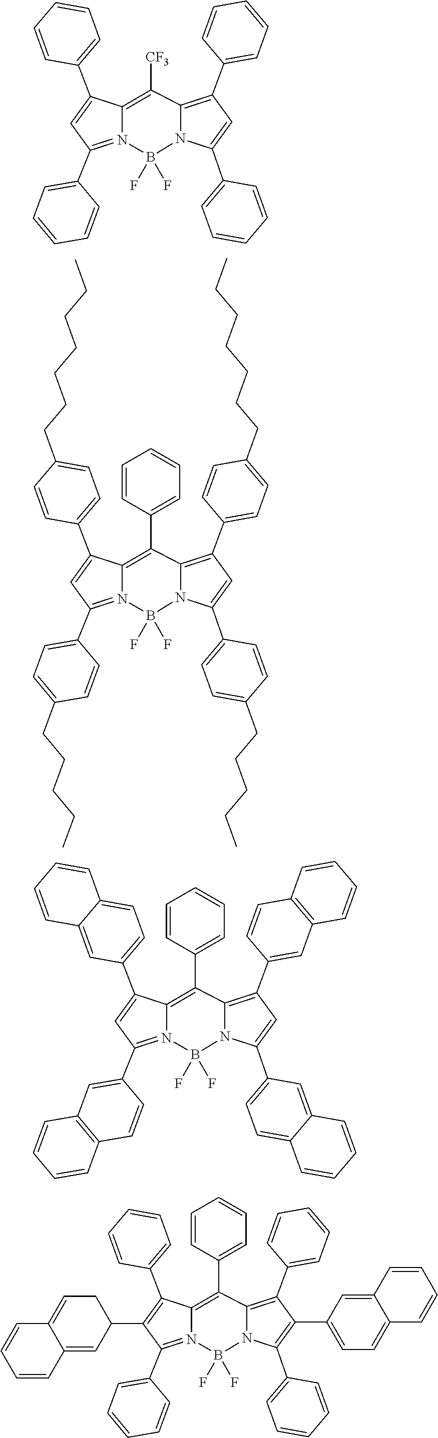

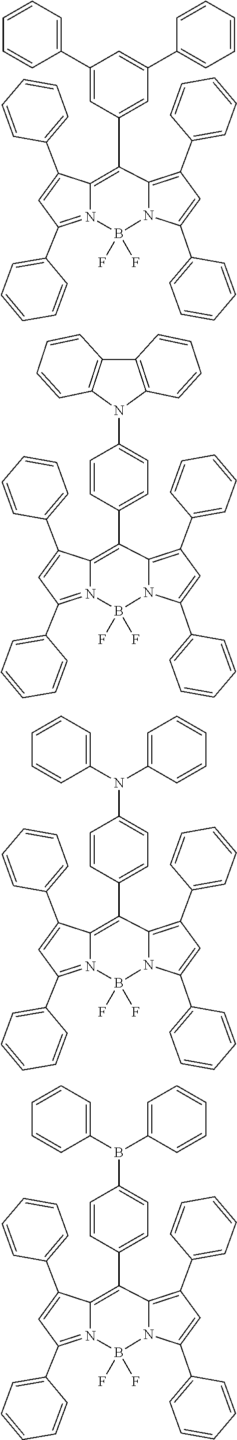

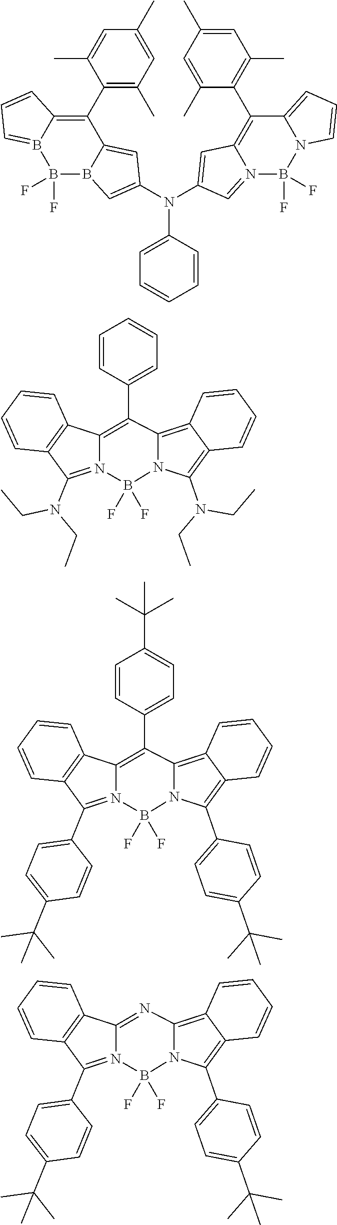

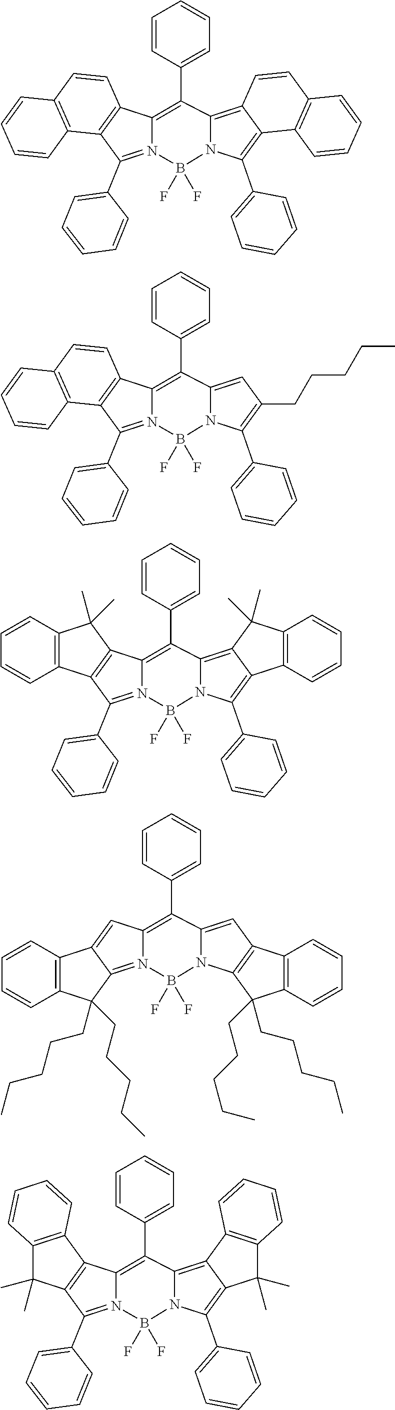

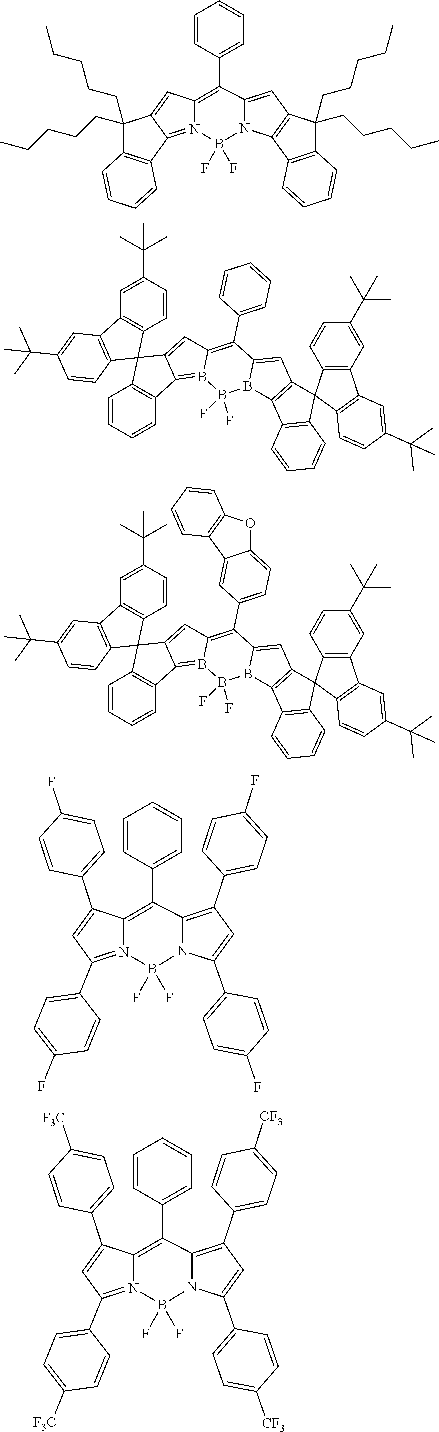

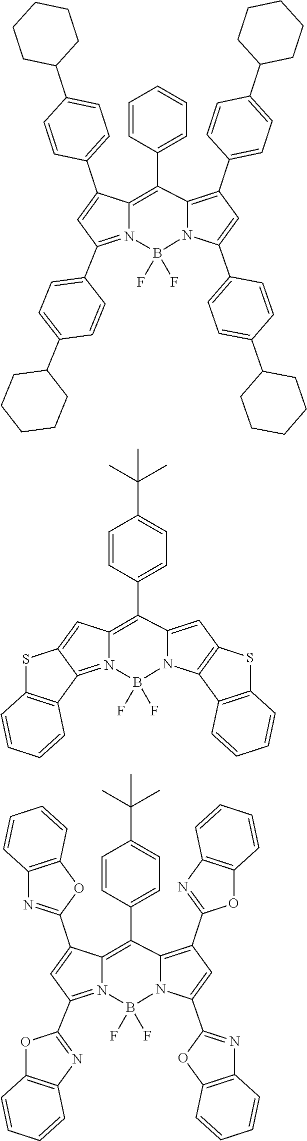

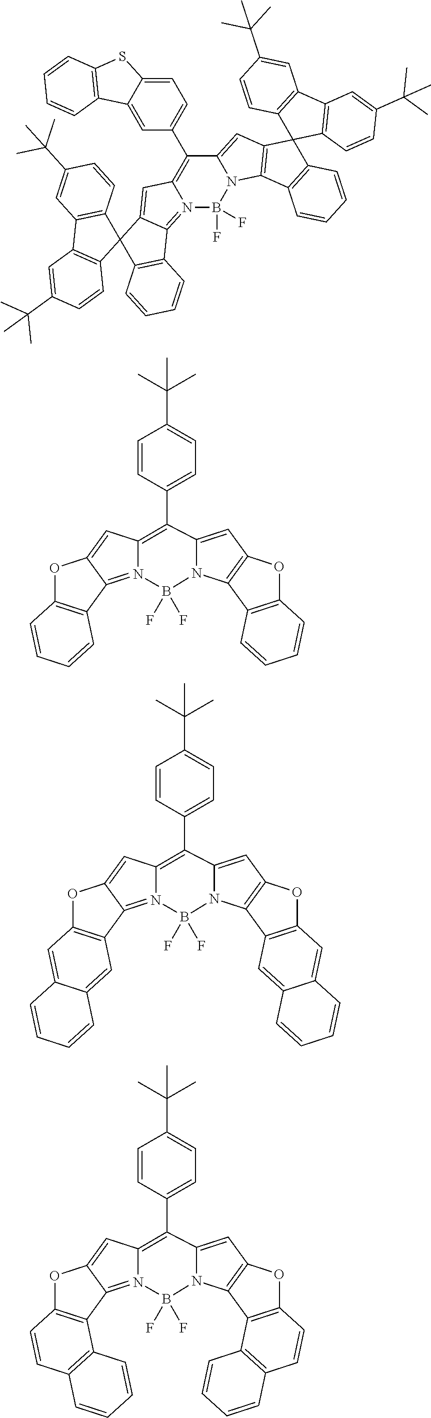

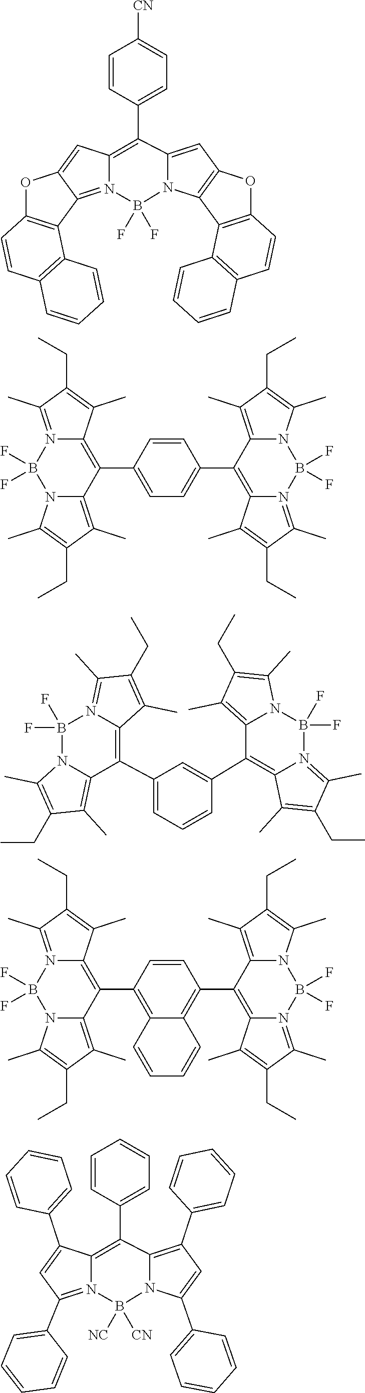

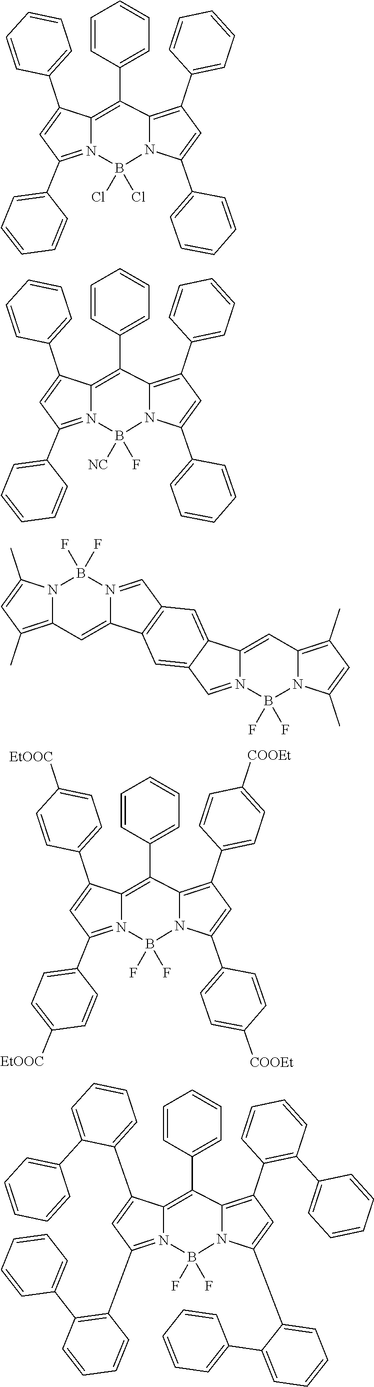

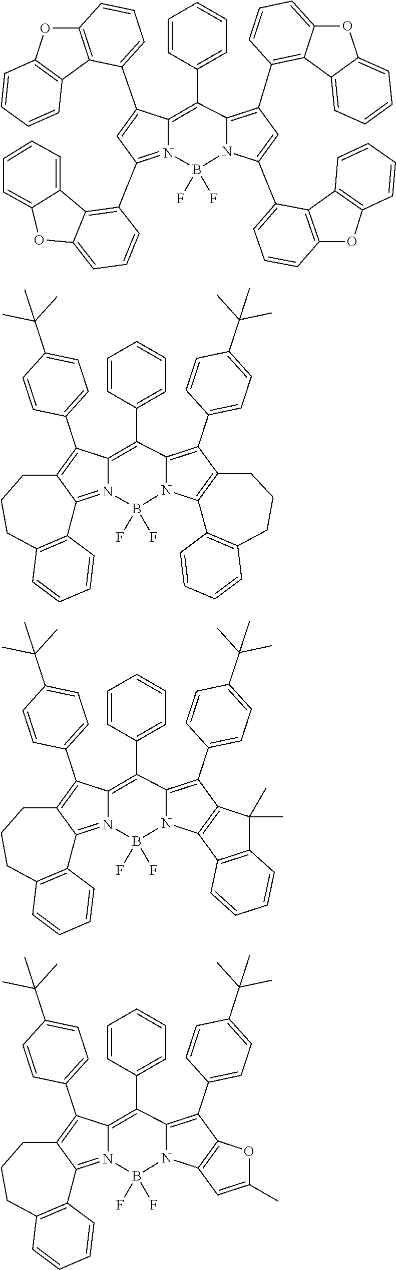

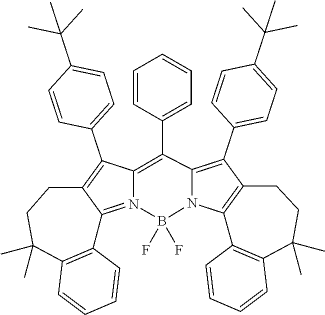

In some embodiments, the organic compound H comprises a structural unit of formula (IV) or (V).

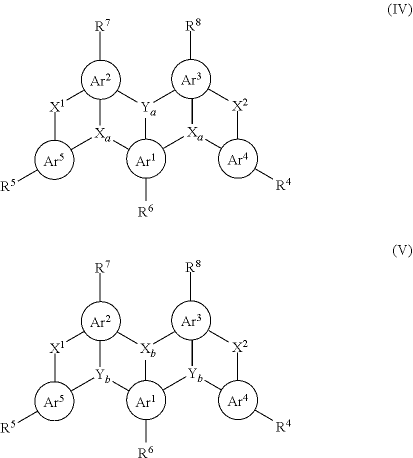

Where each of Ar¹ to Ar³ is independently selected from an aromatic group or a heteroaromatic group containing 5 to 24 ring atoms; each of Ar⁴ and Ar⁵ is independently selected from null, an aromatic group or a heteroaromatic group containing 5 to 24 ring atoms; when neither Ar⁴ nor Ar⁵ is null, each of Xₐ and X_{b} is independently selected from N, C(R⁹), or Si(R⁹); each of Yₐ and Y_{b} is independently selected from B, P═O, C(R⁹), or Si(R⁹); when Ar⁴ and/or Ar⁵ is null, each Yₐ is selected from B, P═O, C(R⁹), or Si(R⁹); each X_{b} is selected from N, C(R⁹), or Si(R⁹); each of Xₐ and Y_{b} is independently selected from N(R⁹), C(R⁹R¹⁰), Si(R⁹R¹⁰), C═O, O, C═N(R⁹), C═C(R⁹R¹⁰), P(R⁹), P(═O)R⁹, S, S═O, or SO₂; each of X¹ and X² is independently null or a bridging group; R⁴ to R¹⁰ are identically defined as the above-mentioned R¹.

In some embodiments, R⁴ to R¹⁰ are independently selected from the group consisting of —H, -D, a C₁-C₁₀ linear alkyl group, a C₁-C₁₀ linear alkoxy group, a C₁-C₁₀ linear thioalkoxy group, a C₃-C₁₀ branched/cyclic alkyl group, a C₃-C₁₀ branched/cyclic alkoxy group, a C₃-C₁₀ branched/cyclic thioalkoxy group, a C₃-C₁₀ branched/cyclic silyl group, a C₁-C₁₀ substituted ketone group, a C₂-C₁₀ alkoxycarbonyl group, a C₇-C₁₀ aryloxycarbonyl group, a cyano group (—CN), a carbamoyl group (—C(═O)NH₂), a haloformyl group (—C(═O)—X where X represents a halogen atom), a formyl group (—C(═O)—H), an isocyano group, an isocyanate group, a thiocyanate group, an isothiocyanate group, a hydroxyl group, a nitro group, —CF₃, —Cl, —Br, —F, a cross-linkable group, a substituted/unsubstituted aromatic or heteroaromatic group containing 5 to 20 ring atoms, an aryloxy or heteroaryloxy group containing 5 to 20 ring atoms, and any combination thereof, where one or more R⁴-R¹⁰ may form a monocyclic or polycyclic aliphatic or aromatic ring system with each other and/or with the rings bonded thereto.

The preferred embodiment of the organic compound H of formula (IV) or (V) can be referred to three Chinese patent applications declared in the same period, with application numbers CN202110370910.9, CN202110370866.1, CN202110370884.X. The patent document above are specially incorporated herein by reference in their entirety.

In the mixture as described herein, both the absorption spectrum of the perovskite emitter E and the emission spectrum of the organic compound H have a large overlap, so that the efficient energy transfer (i.e., Förster resonance energy transfer (FRET)) can be realized therebetween.

In some embodiments, the emission spectrum of the mixture is derived exclusively from the perovskite emitter E, i.e., a complete energy transfer is realized between the perovskite emitter E and the organic compound H.

In some embodiments, the mixture comprises more than two organic compounds H.

In some embodiments, in the mixture as described herein, the weight ratio of the organic compound H to the perovskite emitter E ranges from 50:50 to 99:1, preferably from 60:40 to 98:2, more preferably from 70:30 to 97:3, and most preferably from 80:20 to 95:5.

In some embodiments, the mixture further comprises an organic resin. For the purposes of the present disclosure, the organic resin refers to a resin prepolymer or a resin formed after the resin prepolymer is crosslinked or cured.

In some embodiments, the mixture comprises two or more organic resins.

The organic resins suitable for the present disclosure include, but not limited to: polystyrene, polyacrylate, polymethacrylate, polycarbonate, polyurethane, polyvinylpyrrolidone, polyvinyl acetate, polyvinyl chloride, polybutylene, polyethylene glycol, polysiloxane, polyacrylate, epoxy resin, polyvinyl alcohol, polyacrylonitrile, polyvinylidene chloride (PVDC), polystyrene-acrylonitrile (SAN), polybutylene terephthalate (PBT), polyethylene terephthalate (PET), polyvinyl butyrate (PVB), polyvinyl chloride (PVC), polyamide, polyoxymethylene, polyimide, polyetherimide, and mixtures thereof.

Further, the organic resins suitable for the present disclosure include, but not limited to, those prepared by the homopolymerization or copolymerization from the following monomers (resin prepolymers): styrene derivatives, acrylate derivatives, acrylonitrile derivatives, acrylamide derivatives, vinyl ester derivatives, vinyl ether derivatives, maleimide derivatives, conjugated diene derivatives.

Examples of styrene derivatives include, but not limited to alkylstyrenes, such as α-methylstyrene, o-, m-, p-methylstyrene, p-butylstyrene; especially 4-tert-butylstyrene, alkoxystyrene, such as p-methoxystyrene, p-butoxystyrene, p-tert-butoxystyrene.

Examples of acrylate derivatives include, but not limited to methyl acrylate, methyl methacrylate, ethyl acrylate, ethyl methacrylate, n-propyl acrylate, n-propyl methacrylate, isopropyl acrylate, isopropyl methacrylate, n-butyl acrylate, n-butyl methacrylate, isobutyl acrylate, isobutyl methacrylate, sec-butyl acrylate, sec-butyl methacrylate, tert-butyl acrylate, tert-butyl methacrylate, 2-hydroxyethyl acrylate, 2-hydroxyethyl methacrylate, 2-hydroxypropyl acrylate, 2-hydroxypropyl methacrylate, 3-hydroxypropyl acrylate, 3-hydroxypropyl methacrylate, 2-hydroxybutyl acrylate, 2-hydroxybutyl methacrylate, 3-hydroxybutyl acrylate, 3-hydroxybutyl methacrylate, 4-hydroxybutyl acrylate, 4-hydroxybutyl methacrylate, allyl acrylate, allyl methacrylate, benzyl acrylate, benzyl methacrylate, cyclohexyl acrylate, cyclohexyl methacrylate, phenyl acrylate, phenyl methacrylate, 2-methoxyethyl acrylate, 2-methoxyethyl methacrylate, 2-phenoxyethyl acrylate, 2-phenoxyethyl methacrylate, methoxydiethylene glycol acrylate, methoxydiethylene glycol methacrylate, methoxytriethylene glycol acrylate, methoxytriethylene glycol methacrylate, methoxypropylene glycol acrylate, methoxypropylene glycol methacrylate, methoxy dipropylene glycol acrylate, methoxydipropylene glycol methacrylate, isobornyl acrylate, isobornyl methacrylate, dicyclopentadiene acrylate, dicyclopentadiene methacrylate, adamantane (meth)acrylate, norbornene (meth)acrylate, 2-hydroxy-3-phenoxypropyl acrylate, 2-hydroxy-3-phenoxypropyl methacrylate, glyceryl mono acrylate, and glyceryl monostearate; 2-aminoethyl acrylate, 2-aminoethyl methacrylate, 2-dimethylaminoethyl acrylate, 2-dimethylaminoethyl methacrylate, N,N-dimethylaminoethyl (meth)acrylic acid, N,N-diethylaminoethyl (meth)acrylate, 2-dimethylaminopropyl methacrylate, 3-aminopropyl acrylate, 3-aminopropyl methacrylate, N,N-dimethyl-1,3-propane diamine (meth) acrylate, 3-dimethylaminopropyl acrylate, 3-dimethylaminopropyl methacrylate, glycidyl acrylate, and glycidyl methacrylate.

Examples of the acrylonitrile derivatives include, but not limited to acrylonitrile, methacrylonitrile, α-chloroacrylonitrile, and vinylidene cyanide.

Examples of acrylamide derivatives include, but are not limited to acrylamide, methacrylamide, α-chloroacrylamide, N-2-hydroxyethyl acrylamide, and N-2-hydroxyethyl methacrylamide.

Examples of vinyl ester derivatives include, but not limited to vinyl acetate, vinyl propionate, vinyl butyrate, and vinyl benzoate.

Examples of vinyl ether derivatives include, but not limited to vinyl methyl ether, vinyl ethyl ether, and allyl glycidyl ether.

Examples of maleimide derivatives include, but not limited to maleimide, benzylmaleimide, N-phenylmaleimide, and N-cyclohexylmaleimide.

Examples of conjugated diene derivatives include, but not limited to 1,3-butadiene, isoprene, and chloroprene.

The homopolymers or copolymers can be prepared by free-radical polymerization, cationic polymerization, anionic polymerization, or organometallic catalysis polymerization (for example Ziegler-Natta catalysis). The polymerization process may be suspension polymerization, emulsion polymerization, solution polymerization, or bulk polymerization.

The number average molecualr weight Mn (as determined by GPC) of the organic resins is generally in the range of 10 000 g/mol to 1 000 000 g/mol, preferably in the range of 20 000 g/mol to 750 000 g/mol, more preferably in the range of 30 000 g/mol to 500 000 g/mol.

In some embodiments, the at least one of the organic resin is a thermosetting resin or an UV curable resin. In some embodiments, the organic resin is cured by a method that will enable roll-to-roll processing.

Thermosetting resins require curing in which they undergo an irreversible process of molecular cross-linking, which makes the resin non-fusible. In some embodiments, the thermosetting resin is an epoxy resin, a phenolic resin, a vinyl resin, a melamine resin, a urea-formaldehyde resin, an unsaturated polyester resin, a polyurethane resin, an allyl resin, an acrylic resin, a polyamide resin, a polyamide-imide resin, a phenol-amide polycondensation resin, an urea-melamine polycondensation resin, or combinations thereof.

In some embodiments, the thermosetting resin is an epoxy resin. The epoxy resins are easy to cure and do not give off volatiles or generate by-products from a wide range of chemicals. The epoxy resins can also be compatible with most substrates and tend to readily wet surfaces. See also Boyle, M. A. et al., “Epoxy Resins”, Composites, Vol. 21, ASM Handbook, pages 78-89 (2001).

In some embodiments, the organic resin is a silicone thermosetting resin. In some embodiments, the silicone thermosetting resin is OE6630A or OE6630B (Dow Corning Corporation (Auburn, Michigan.)).

In some embodiments, a thermal initiator is used. In some embodiments, the thermal initiator is AIBN[2,2′-azobis(2-methylpropionitrile)] or benzoyl peroxide.

The UV curable resin is a polymer that will cure and rapidly harden upon exposure to light of a specific wavelength. In some embodiments, the UV curable resin is a resin having a free radical polymerization group, and a cationic polymerizable group as functional groups; the radical polymerizable group is such as (meth)acryloyloxy group, vinyloxy group, styryl group, or vinyl group. The cationically polymerizable group is such as epoxy group, thioepoxy group, vinyloxy group, or oxetanyl group. In some embodiments, the UV curable resin is a polyester resin, a polyether resin, a (meth)acrylic resin, an epoxy resin, a polyurethane resin, an alkyd resin, a spiroacetal resin, a polybutadiene resin, or a thiolene resin.

In some embodiments, the UV curable resin is selected from polyurethane acrylate, allyloxy diacrylate, bis (acryloyloxyethyl) hydroxyisocyanurate, bis (acryloyloxyneopentyl glycol) adipate, bisphenol A diacrylate, bisphenol A dimethacrylate, 1,4-butanediol diacrylate, 1,4-butanediol dimethacrylate, 1,3-butanediol diacrylate, 1,3-butanediol dimethacrylate, dicyclopentyl diacrylate, diethylene glycol diacrylate, diethylene glycol dimethacrylate, dipentaerythritol hexaacrylate, dipentaerythritol monohydroxy pentacrylate, bis (trimethylolpropane) tetraacrylate, triethylene glycol dimethacrylate, glyceryl methacrylate, 1,6-hexanediol diacrylate, neopentyl glycol dimethacrylate, neopentyl glycol hydroxypivalonate, pentaerythritol triacrylate, pentaerythritol tetraacrylate, dimethacrylate, polyethylene glycol diacrylate, polypropylene glycol diacrylate, tetraethylene glycol diacrylate, tetrabromobisphenol A diacrylate, triethylene glycol divinyl ether, glycerol diacrylate, trimethylolpropane triacrylate, tripropylene glycol diacrylate, tris (acryloyloxyethyl) isocyanurate, triacrylate, diacrylate, propyl acrylate, vinyl-terminated polydimethylsiloxane, vinyl-terminated diphenyl siloxane-dimethyl siloxane copolymer, vinyl-terminated polyphenyl methyl siloxane, vinyl-terminated difluoromethyl siloxane-dimethyl siloxane copolymer, vinyl-terminated diethyl siloxane-dimethyl siloxane copolymer, vinyl methyl siloxane, monomethacryloxypropyl-terminated polydimethylsiloxane, monovinyl-terminated polydimethylsiloxane, monoallyl-mono-trimethylsilyloxy-terminated polyethylene oxide, or any combination thereof.

In some embodiments, the UV curable resin is a mercapto functional compound that can be cross-linked under UV curing conditions with an isocyanate, an epoxy resin, or an unsaturated compound. In some embodiments, the mercapto functional compound is a polythiol. In some embodiments, the polythiol is selected from: pentaerythritol tetrakis(3-mercaptopropionate) (PETMP), trimethylolpropane tris(3-mercaptopropionate) (TMPMP), ethylene glycol bis(3-mercaptopropionate) (GDMP); tris [25-(3-mercapto-propionyloxy)ethyl]isocyanurate (TEMPIC), dipentaerythritol hexa(3-mercaptopropionate) (Di-PETMP), ethoxylated trimethylolpropane tri(3-mercaptopropionate) (ETMP1300 and ETTMP700), polycaprolactone tetra(3-mercaptopropionate) (PCL4MP1350), pentaerythritol tetramercaptoacetate (PETMA), trimethylolpropane trimercaptoacetate (TMPMA), or ethylene glycol dimercaptoacetate (GDMA). These compounds are sold under the trade name THIOCURE® by Bruno Bock (Malsacht, Germany).

In some embodiments, the UV curable resin further comprises photoinitiator. The photoinitiator will initiate crosslinking and/or curing reactions of the photosensitive material during exposure to light. In some embodiments, the photoinitiator is a compound such as acetophenone-based, benzoin-based, or thidrone-based that initiate the polymerization, crosslinking and curing of monomers.

In some embodiments, the UV curable resin comprises mercapto-functional compounds, methacrylates, acrylates, isocyanates, or any combination thereof. In some embodiments, the UV curable resin comprises polythiols, methacrylates, acrylates, isocyanates, or any combination thereof.

In some embodiments, the photoinitiator is MINS-311RM (Minuta Technology Co., Ltd (Korea)).

In some embodiments, the photoinitiator is Irgacure® 127, Irgacure® 184, Irgacure® 184D, Irgacure® 2022, Irgacure® 2100, Irgacure® 250, Irgacure® 270, Irgacure® 2959, Irgacure® 369, Irgacure® 369EG, Irgacure® 379, Irgacure® 500, Irgacure® 651, Irgacure® 754, Irgacure® 784, Irgacure® 819, Irgacure® 819DW, Irgacure® 907, Irgacure® 907FF, Irgacure® OxeOI, Irgacure® TPO-L, Irgacure® 1173, Irgacure® 1173D, Irgacure® 4265, Irgacure® BP, or Irgacure® MBF (BASF Corporation (Wyandotte, Michigan)).

In some embodiments, the photoinitiator is TPO (2,4,6-trimethylbenzoyl-diphenyl-oxide) or MBF (methyl benzoyl formate).

In some embodiments, the weight percentage of organic resin in the formulation is about 20% to about 99%, about 20% to about 95%, about 20% to about 90%, about 20% to about 85%, about 20% to about 80%, about 20% to about 70%, about 20% to about 60%, about 40% to about 99%, about 40% to about 95%, about 40% to about 90%, about 40% to about 85%, about 40% to about 80%, about 40% to about 70%, about 70% to about 99%, about 70% to about 95%, about 70% to about 90%, about 70% to about 85%, about 70% to about 80%, about 80% to about 99%, about 80% to about 95%, about 80% to about 90%, about 80% to about 85%, about 85% to about 99%, about 85% to about 95%, about 85% to about 90%, about 90% to about 99%, about 90% to about 95%, or about 95% to about 99%.

In another aspect, the present disclosure also provides a formulation comprising a mixture as described herein, and at least one solvent.

In some embodiments, the formulation as described herein is a solution.

In some embodiments, the formulation as described herein is a dispersion.

The formulations as described herein in the embodiments may comprise the perovskite emitter E of 0.01 wt % to 20 wt %, preferably 0.1 wt % to 20 wt %, more preferably 0.2 wt % to 20 wt %, and most preferably 2 wt % to 15 wt %.

Using the formulation as described herein, the color conversion layer may be fabricated by ink-jet printing, transfer printing, photolithography, etc. In this case, the compound (i.e., the color conversion material) needs to be dissolved alone or together with other materials in a resin (prepolymer) and/or an organic solvent, to form the ink. The mass concentration of the compound (i.e. the color conversion material) in the ink is not less than 0.1 wt %. The color conversion ability of the color conversion layer can be tuned by adjusting the concentration of the color conversion material in the ink and the thickness of the color conversion layer. In general, the higher the concentration of the color conversion material or the thickness of the layer, the higher the color conversion efficiency of the color conversion layer would be.

In some embodiments, the at least one solvent is selected from water, alcohols, esters, aromatic ketones, aromatic ethers, aliphatic ketones, aliphatic ethers, borates, phosphorates, or mixtures of two or more of them.

In some embodiments, the suitable and preferred solvents include aliphatics, alicyclics, aromatics, amines, thiols, amides, nitriles, esters, ethers, polyethers, alcohols, diols, or polyols.

In some embodiments, the alcohol represents a solvent of the suitable class. The preferred alcohols include alkylcyclohexanol, especially methylated aliphatic alcohol, naphthol, etc.

Other examples of the suitable alcohol solvents include dodecanol, phenyltridecanol, benzyl alcohol, ethylene glycol, ethylene glycol methyl ether, glycerol, propylene glycol, propylene glycol 1-ethoxy-2-propanol, etc.

The solvent may be used alone or as a mixture of two or more organic solvents.

Further, examples of organic solvents, include(but are not limited to): methanol, ethanol, 2-methoxyethanol, dichloromethane, trichloromethane, chlorobenzene, o-dichlorobenzene, tetrahydrofuran, anisole, morpholine, toluene, o-xylene, m-xylene, p-xylene, 1,4-dioxane, acetone, methylethylketone, 1,2-dichloroethane, 3-phenoxytoluene, 1,1,1-trichloroethane, 1,1,2,2-tetrachloroethane, ethyl acetate, butyl acetate, dimethylformamide, dimethylacetamide, dimethylsulfoxide, tetrahydronaphthalene, naphthane, indene, and/or any mixture thereof.

In some embodiments, the organic solvent of the formulation is selected from aromatic, heteroaromatic, ester, aromatic ketone, aromatic ether, aliphatic ketone, aliphatic ether, cycloaliphatic, alicyclic or olefin compounds, borate, phosphorate, or a mixture of two or more of them.

Examples of aromatic or heteroaromatic solvents as described herein include, but not limited to: 1-tetralone, 3-phenoxytoluene, acetophenone, 1-methoxynaphthalene, p-diisopropylbenzene, amylbenzene, tetrahydronaphthalene, cyclohexylbenzene, chloronaphthalene, 1,4-dimethylnaphthalene, 3-isopropylbiphenyl, p-methylcumene, dipentylbenzene, o-diethylbenzene, m-diethylbenzene, p-diethylbenzene, 1,2,3,4-tetramethyl benzene, 1,2,3,5-tetramethyl benzene, 1,2,4,5-tetramethyl benzene, butylbenzene, dodecyl benzene, 1-methylnaphthalene, 1,2,4-trichlorobenzene, 1,3-dipropoxybenzene, 4,4-difluorodiphenylmethane, diphenyl ether, 1,2-dimethoxy-4-(1-propenyl) benzene, diphenylmethane, 2-phenylpyridine, 3-phenylpyridine, 2-phenoxymethyl ether, 2-phenoxytetrahydrofuran, ethyl-2-naphthyl ether, N-methyldiphenylamine, 4-isopropylbiphenyl, α,α-dichlorodiphenylmethane, 4-(3-phenylpropyl) pyridine, benzyl benzoate, 1,1-bis (3,4-dimethylphenyl) ethane, 2-isopropylnaphthalene, dibenzyl ether, etc

In some embodiments, the suitable and preferred solvents are aliphatics, alicyclics, aromatics, amines, thiols, amides, nitriles, esters, ethers, or polyethers.

The solvent may be a cycloalkane, such as decahydronaphthalene.

In some embodiments, the formulation as described herein comprises at least 50 wt % of an alcoholic solvent; preferably at least 80 wt %; particularly preferably at least 90 wt %.

In some embodiments, the organic solvent particularly suitable for the present disclosure is a solvent having Hansen solubility parameters in the following ranges:
δ_{d} (dispersion force) is in the range of 17.0 MPa^{1/2} to 23.2 MPa^{1/2}, especially in the range of 18.5 MPa^{1/2} to 21.0 MPa^{1/2};
δₚ (polarity force) is in the range of 0.2 MPa^{1/2} to 12.5 MPa^{1/2}, especially in the range of 2.0 MPa^{1/2} to 6.0 MPa^{1/2};
δₕ (hydrogen bonding force) is in the range of 0.9 MPa^{1/2} to 14.2 MPa^{1/2}, especially in the range of 2.0 MPa^{1/2} to 6.0 MPa^{1/2}

In the formulation as described herein, the boiling point parameter of the organic solvents should be taken into account when selecting the organic solvents. In the present disclosure, the boiling points of the organic solvents ≥150° C.; preferably ≥180° C.; more preferably ≥200° C.; further preferably ≥250° C.; and most preferably ≥275 C or ≥300° C. The boiling points in these ranges are beneficial in terms for preventing nozzle clogging of the inkjet printhead. The organic solvent can be evaporated from solution system to form a functional film.

In some embodiments, in the formulation as described herein,
1) the viscosity is in the range of 1 cps to 100 cps at 25° C.; and/or
2) the surface tension is in the range of 19 dyne/cm to 50 dyne/cm at 25° C.

In the formulation as described herein, the surface tension parameter should be taken into account when selecting the resins (prepolymers) or the organic solvents. The suitable surface tension parameters of the inks are suitable for the particular substrate and particular printing method. For example, for the ink-jet printing, in some embodiments, the surface tension of the resin (prepolymer) or the organic solvent at 25° C. is in the range of 19 dyne/cm to 50 dyne/cm, more preferably in the range of 22 dyne/cm to 35 dyne/cm, and most preferably in the range of 25 dyne/cm to 33 dyne/cm.

In some embodiments, the surface tension of the formulation at 25° C. is in the range of 19 dyne/cm to 50 dyne/cm; more preferably in the range of 22 dyne/cm to 35 dyne/cm; and most preferably in the range of 25 dyne/cm to 33 dyne/cm.

In the formulation as described herein, the viscosity parameters of the ink should be taken into account when selecting the resins (prepolymers) or the organic solvents. The viscosity can be adjusted by election different methods, such as by the suitable resin (prepolymer) or organic solvent and the concentration of functional materials in the ink. In some embodiments, the viscosity of the resin (prepolymer) or the organic solvent is less than 100 cps, more preferably less than 50 cps, and most preferably from 1.5 cps to 20 cps. The viscosity herein refers to the viscosity during printing at the ambient temperature that is generally at 15-30° C., preferably at 18-28° C., more preferably at 20-25° C., and most preferably at 23-25° C. The resulting formulation will be particularly suitable for ink-jet printing.

In some embodiments, the viscosity of the formulation at 25° C. is in the range of about 1 cps to 100 cps; more preferably in the range of 1 cps to 50 cps; and most preferably in the range of 1.5 cps to 20 cps.

The ink obtained from the resin (prepolymer) or the organic solvent satisfying the above-mentioned boiling point parameter, surface tension parameter and viscosity parameter can form a functional film with uniform thickness and formulation property.

In yet another aspect, the present disclosure further provides an organic functional film comprising a mixture or a formulation as described herein.

In yet another aspect, the present disclosure further provides a method for preparing the organic functional film, as shown in the following steps:
1) Prepare a mixture or a formulation as described herein.
2) The mixture or the formulation is coated on a substrate by printing or coating to form a film, where the method of printing or coating is selected from the group consisting of ink-jet printing, nozzle printing, typographic printing, screen printing, dip coating, spin coating, blade coating, roller printing, torsional roll printing, planographic printing, flexographic printing, rotary printing, spray coating, brush or pad printing, and slot die coating.
3) The obtained film is heated at 50° C. and above, optionally in combination with ultraviolet irradiation, to allow the film to undergo a crosslinking reaction and be cured.

The thickness of the organic functional film is generally from 50 nm to 200 μm, preferably from 100 nm to 150 μm, more preferably from 500 nm to 100 μm, further preferably from 1 μm to 50 μm, and most preferably from 1 μm to 20 μm.

In yet another aspect, the present disclosure further provides the use of the mixture and the organic functional film in optoelectronic devices.

In some embodiments, the optoelectronic device may be selected from an organic light emitting diode (OLED), an organic photovoltaic cell (OPV), an organic light emitting electrochemical cell (OLEEC), an organic light emitting field effect transistor, or an organic laser.

In yet another aspect, the present disclosure further provides an optoelectronic device comprising a mixture or an organic functional film as described herein.

Preferably, the optoelectronic device is an electroluminescent device, such as an organic light emitting diode (OLED), an organic light emitting electrochemical cell (OLEEC), an organic light emitting field effect transistor, a perovskite light emitting diode (PeLED), or a quantum dot light emitting diode (QD-LED), where one of the functional layers comprises an organic functional film as described herein. The functional layer may be selected from a hole-injection layer, a hole-transport layer, an electron-injection layer, an electron-transport layer, a light-emitting layer, or a cathodic passivation layer (CPL).

In some embodiments, the optoelectronic device is an electroluminescent device comprising two electrodes, where the functional layer is located on the same side of the two electrodes.

In some embodiments, the optoelectronic device comprises a light emitting unit and a color conversion layer (functional layer), where the color conversion layer comprises a mixture or an organic functional film as described herein.

In some embodiments, the color conversion layer absorbs 95% or more of the light from the light emitting unit, preferably 97% or more, more preferably 99% or more, and most preferably 99.9% or more.

In some embodiments, the light emitting unit is selected from a solid-state light emitting device. The solid-state light emitting device is preferably selected from a LED, an organic light emitting diode (OLED), an organic light emitting electrochemical cell (OLEEC), an organic light emitting field effect transistor, a perovskite light emitting diode (PeLED), a quantum dot light emitting diode (QD-LED), or a nanorod LED (see DOI: 10.1038/srep 28312).

In some embodiments, the light emitting unit emits blue light, which is converted into green light or red light by the color conversion layer.

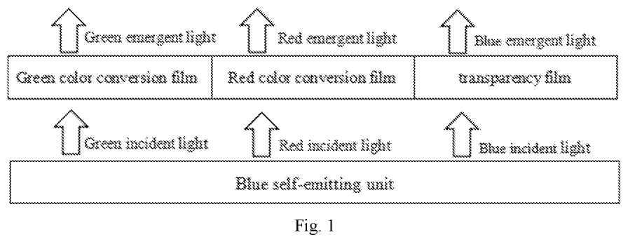

In yet another aspect, the present disclosure further provides a display, comprising at least three pixels of red, green and blue. As shown in the attached FIG. 1, the blue pixel comprises a blue emitting unit, and the pixel of red or green comprises a blue emitting unit and a corresponding red or green color conversion layer.

In yet another aspect, the present disclosure further provides an organic light-emitting device comprising a substrate, a first electrode, an organic light-emitting layer, a second electrode, a color conversion layer, and an encapsulation layer in sequence from bottom to top, the second electrode is at least partially transparent, where 1) the color conversion layer comprises the mixture as described herein; 2) the color conversion layer absorbs 50% or more of the light emitted by the organic light-emitting layer through the second electrode; 3) the emission spectrum of the organic compound H is on the short wavelength side of the absorption spectrum of the perovskite emitter E, and at least partially overlaps with the absorption spectrum of the perovskite emitter E. Preferably, the FWHM of the emission spectrum of the perovskite emitter E≤45 nm

The organic compound H, the perovskite emitter E, and the preferred embodiment thereof are as described above.

In some embodiments, the color conversion layer further comprises a resin or a resin prepolymer. The suitable and preferred resins or resin prepolymers are as described above.

In some embodiments, the object is to obtain a multi-color light, the color conversion layer can absorb 30% or more of the light emitted by the organic light-emitting layer through the second electrode, preferably 40% or more, and most preferably 50% or more.

In some embodiments, the object is to obtain a monochromatic light with high color purity, the color conversion layer can absorb 95% or more of the light emitted by the organic light-emitting layer through the second electrode, preferably 97% or more, more preferably 99% or more, and most preferably 99.9% or more.

In some embodiments, the thickness of the color conversion layer is between 100 nm and 5 μm, preferably between 150 nm and 4 μm, more preferably between 200 nm and 3 μm, and most preferably between 200 nm and 2 μm.

In some embodiments, the organic light-emitting device is an organic electroluminescent device. In some embodiments, the organic light-emitting device is an OLED. More preferably, the first electrode is an anode, the second electrode is a cathode. Particularly preferably, the organic light-emitting device is a top emission OLED.

The substrate should be opaque or transparent. A transparent substrate could be used to produce a transparent light-emitting device (for example: Bulovic et al., Nature 1996, 380, p 29, and Gu et al., Appl. Phys. Lett. 1996, 68, p 2606). The substrate can be rigid/flexible, e.g. it can be plastic, metal, semiconductor wafer, or glass. Preferably, the substrate has a smooth surface. Particularly desirable are substrates without surface defects. In some embodiments, the substrate is flexible and can be selected from a polymer film or plastic with a glass transition temperature (Tg)>150° C., preferably >200° C., more preferably >250° C., and most preferably >300° C. Examples of the suitable flexible substrate includes poly (ethylene terephthalate) (PET) and polyethylene glycol (2,6-naphthalene) (PEN).

The choice of anodes may include a conductive metal, or a metal oxide, or a conductive polymer. The anode should be able to easily inject holes into a hole-injection layer (HIL), a hole-transport layer (HTL), or a light-emitting layer. In some embodiments, the absolute value of the difference between the work function of the anode and the HOMO energy level of the emitter of the light-emitting layer, or the HOMO energy level/valence band energy level of the p-type semiconductor materials of the hole-injection layer (HIL)/hole-transport layer (HTL)/electron-blocking layer (EBL) <0.5 eV, preferably <0.3 eV, more preferably <0.2 eV. Examples of anode materials may include, but not limited to: Al, Cu, Au, Ag, Mg, Fe, Co, Ni, Mn, Pd, Pt, ITO, aluminum-doped zinc oxide (AZO), etc. Other suitable anode materials are known and can be readily selected for use by the general technicians in this field. The anode material can be deposited using any suitable technique, such as a suitable physical vapor deposition method, including RF magnetron sputtering, vacuum thermal evaporation, e-beam, etc. In some embodiments, the anode is patterned. Patterned conductive ITO substrates are commercially available and can be used to produce the devices as described herein.

The choice of cathode may include a conductive metal or a metal oxide. The cathode should be able to easily inject electrons into the EIL, the ETL, or the directly into the light-emitting layer. In some embodiments, the absolute value of the difference between the work function of the cathode and the LUMO energy level of the emitter of the light-emitting layer, or the LUMO energy level/conduction band energy level of the n-type semiconductor materials of the electron-injection layer (EIL)/electron-transport layer (ETL)/hole-blocking layer (HBL) <0.5 eV, preferably <0.3 eV, and most preferably <0.2 eV. In principle, all materials that can be used as cathodes for OLEDs may be applied as cathode materials for the devices as described herein. Examples of cathode materials include, but not limited to: Al, Au, Ag, Ca, Ba, Mg, LiF/Al, MgAg alloys, BaF2/Al, Cu, Fe, Co, Ni, Mn, Pd, Pt, ITO, etc. The cathode materials can be deposited using any suitable technique, such as the suitable physical vapor deposition method, including RF magnetron sputtering, vacuum thermal evaporation, e-beam, etc. In some embodiments, the transmittance of the cathode in the range of 400-680 nm≥40%, preferably ≥45%, more preferably ≥50%, and most preferably ≥60%. Typically, 10-20 nm of Mg:Ag alloys can be used as transparent cathodes, and the ratio of the Mg:Ag can range from 2:8 to 0.5:9.5.

The light-emitting layer of the organic electroluminescent device preferably comprises a blue fluorescent host and a blue fluorescent dopant; in some embodiments, the light-emitting layer comprises a blue phosphorescent host and a blue phosphorescent dopant. The OLED may also comprise other functional layers, such as a hole-injection layer (HIL), a hole-transport layer (HTL), an electron-blocking layer (EBL), an electron-injection layer (EIL), an electron-transport layer (ETL), and a hole-blocking layer (HBL). Materials suitable for use in these functional layers are described in details above and in WO2010135519A1, US20090134784A1 and WO2011110277A1, the entire contents of these three documents are hereby incorporated herein for reference.

Further, the organic electroluminescent device further comprises a cathode capping layer (CPL).

In some embodiments, the CPL is disposed between the second electrode and the color conversion layer.

In some embodiments, the CPL is disposed on the top of the color conversion layer.

The CPL material generally requires high refractive index (n), such as n≥1.95@460 nm, n≥1.90@520 nm, n≥1.85@620 nm. Examples of the CPL materials include:

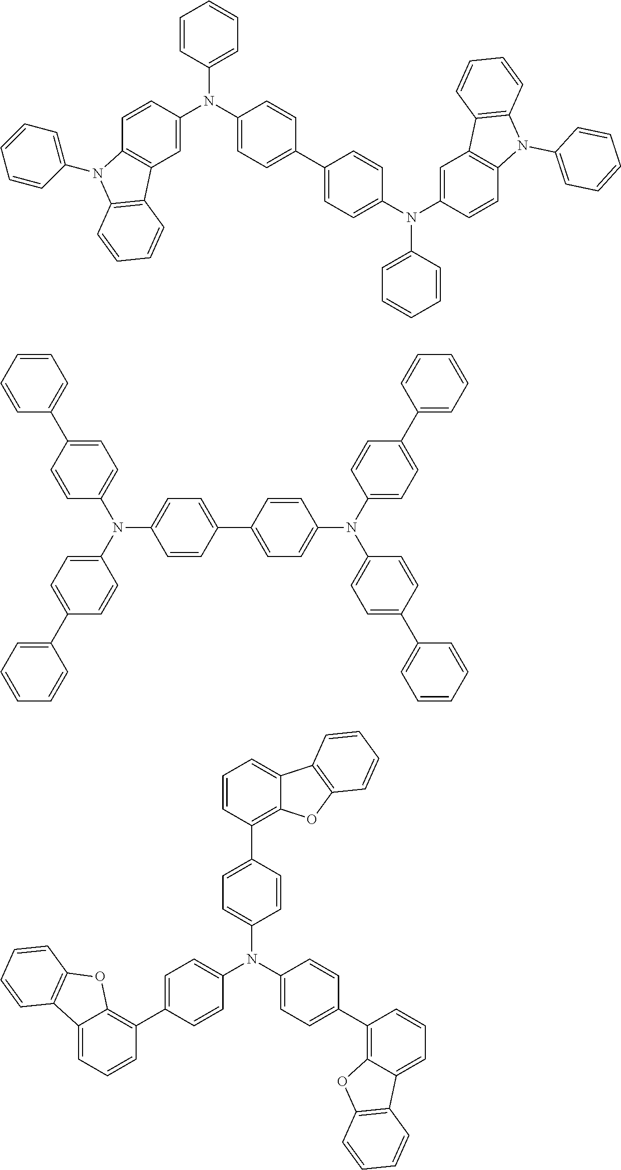

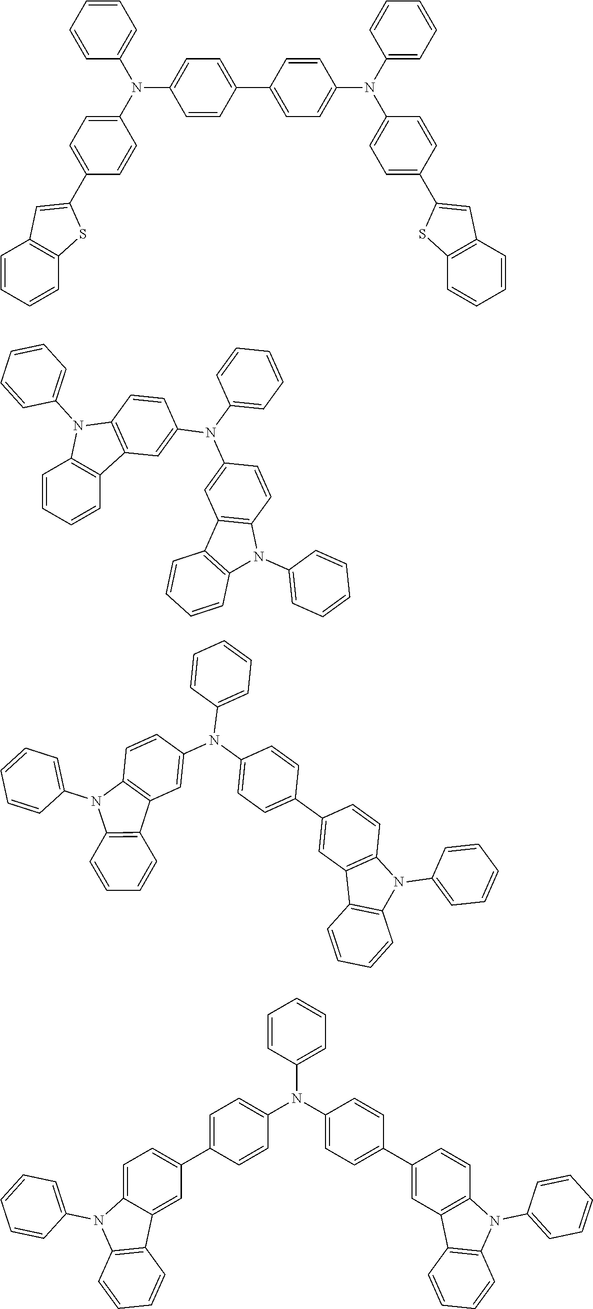

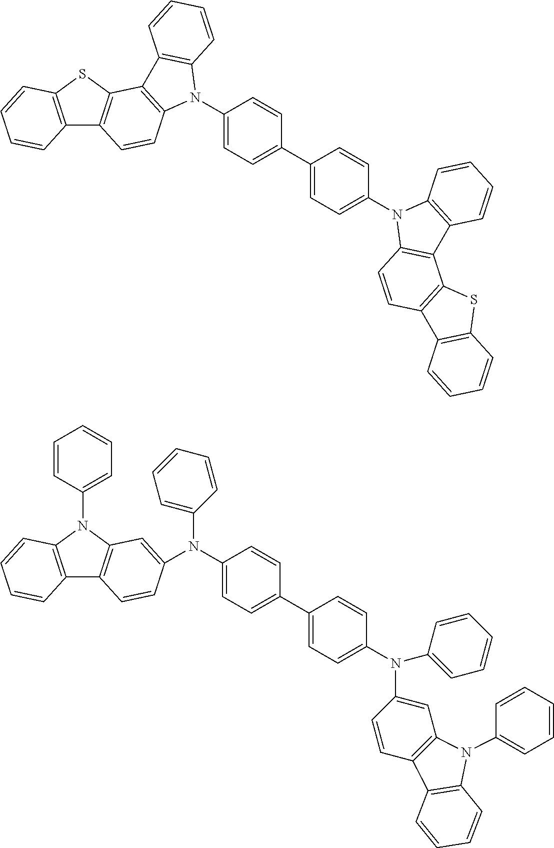 [SMILES: c1ccc2c(c1)sc1c2ccc2c1c1ccccc1n2-c1ccc(-c2ccc(-n3c4ccccc4c4c5sc6ccccc6c5ccc43)cc2)cc1 ; c1ccc(N(c2ccc(-c3ccc(N(c4ccccc4)c4ccc5c6ccccc6n(-c6ccccc6)c5c4)cc3)cc2)c2ccc3c4ccccc4n(-c4ccccc4)c3c2)cc1]

More further examples of the CPL materials can be found in the following patent literature: KR20140128653A, KR20140137231A, KR20140142021A, KR20140142923A, KR20140143618A, KR20140145370A, KR20150004099A, KR20150012835A, U.S. Pat. No. 9,496,520B2, US2015069350A1, CN103828485B, CN104380842B, CN105576143A, TW201506128A, CN103996794A, CN103996795A, CN104744450A, CN104752619A, CN101944570A, US2016308162A1, U.S. Pat. No. 9,095,033B2, US2014034942A1, WO2017014357A₁. The above patent documents are incorporated herein by reference in their entirety.

In some embodiments, the color conversion layer comprises a CPL material as described herein.

Preferably, the encapsulation layer of the organic electroluminescent device is thin-film encapsulated (TFE).

The present disclosure also provides a display panel, where at least one pixel comprises an organic electroluminescent device described herein.

The present disclosure will be described below in conjunction with the preferred embodiments, but the present disclosure is not limited to the following embodiments. It should be understood that the scope of the present disclosure is covered by the scope of the claims of the present disclosure, and those skilled in the art should understand that certain changes may be made to the embodiments of the present disclosure.

### Specific Embodiment

The organic compound H as the host material comprises a structure shown in H1-H10:

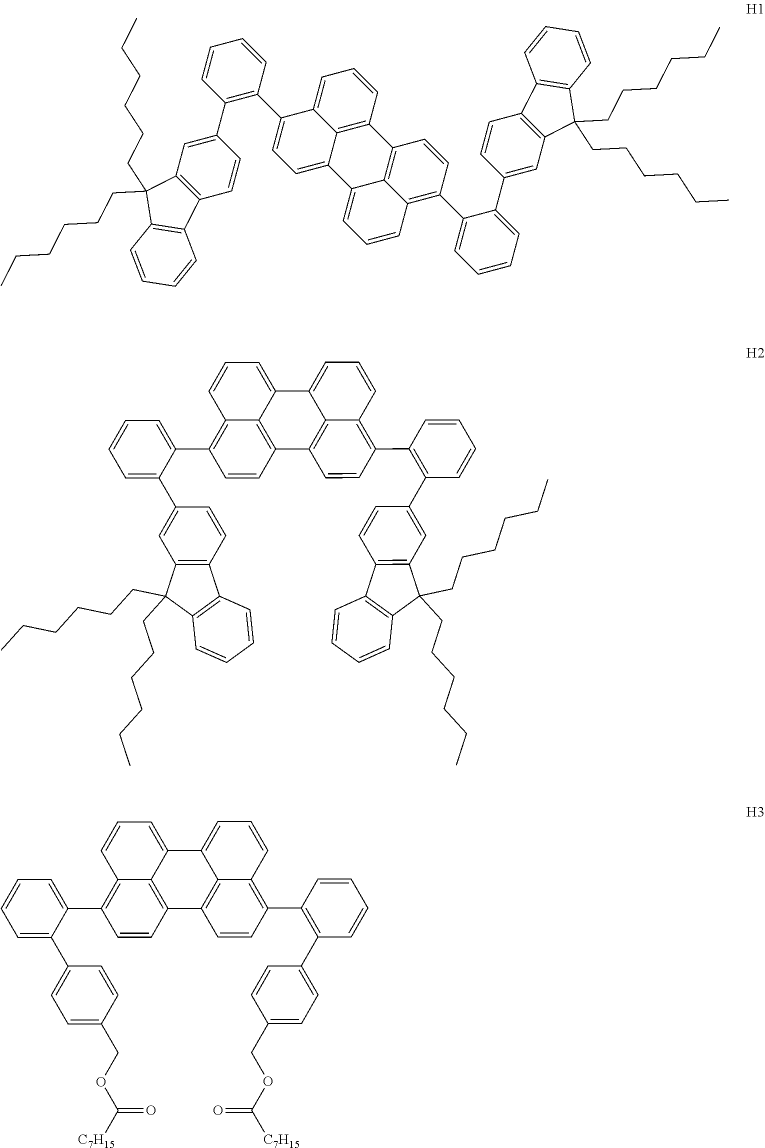

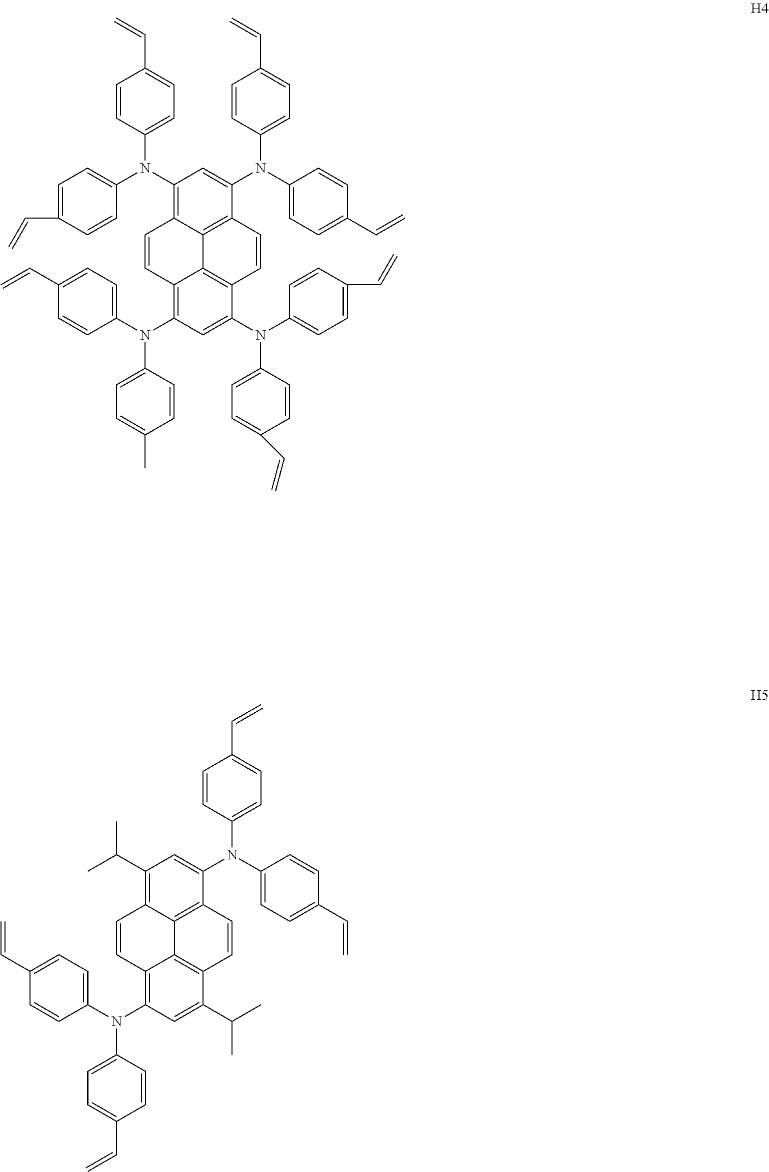 [SMILES: C=Cc1ccc(N(c2ccc(C)cc2)c2cc(N(c3ccc(C=C)cc3)c3ccc(C=C)cc3)c3ccc4c(N(c5ccc(C=C)cc5)c5ccc(C=C)cc5)cc(N(c5ccc(C=C)cc5)c5ccc(C=C)cc5)c5ccc2c3c54)cc1 ; C=Cc1ccc(N(c2ccc(C=C)cc2)c2cc(C(C)C)c3ccc4c(N(c5ccc(C=C)cc5)c5ccc(C=C)cc5)cc(C(C)C)c5ccc2c3c54)cc1]

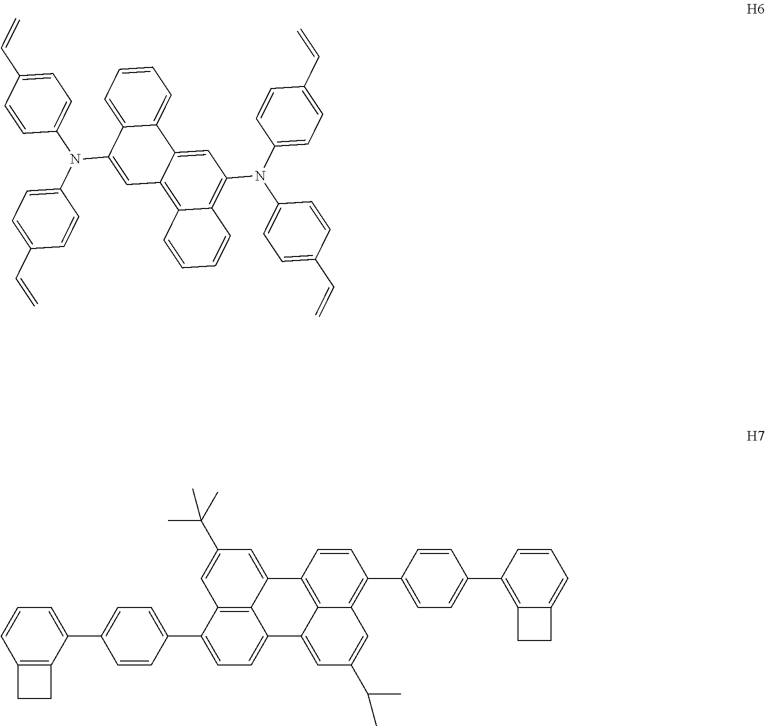

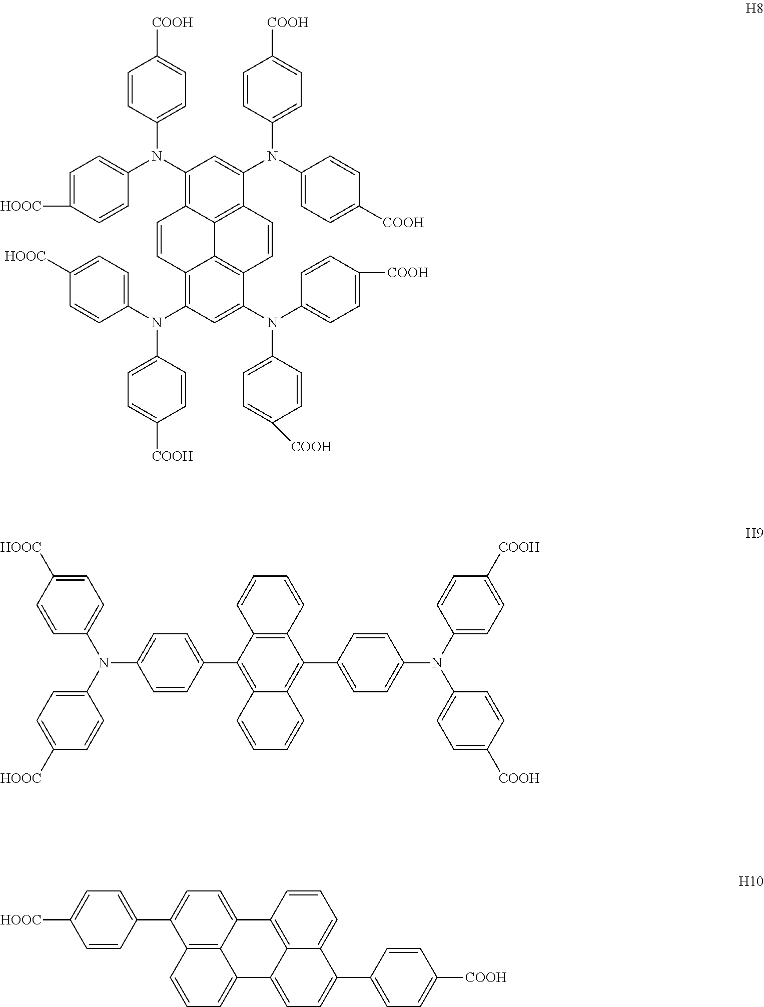 [SMILES: O=C(O)c1ccc(N(c2ccc(C(=O)O)cc2)c2cc(N(c3ccc(C(=O)O)cc3)c3ccc(C(=O)O)cc3)c3ccc4c(N(c5ccc(C(=O)O)cc5)c5ccc(C(=O)O)cc5)cc(N(c5ccc(C(=O)O)cc5)c5ccc(C(=O)O)cc5)c5ccc2c3c54)cc1 ; O=C(O)c1ccc(N(c2ccc(C(=O)O)cc2)c2ccc(-c3c4ccccc4c(-c4ccc(N(c5ccc(C(=O)O)cc5)c5ccc(C(=O)O)cc5)cc4)c4ccccc34)cc2)cc1 ; O=C(O)c1ccc(-c2ccc3c4cccc5c(-c6ccc(C(=O)O)cc6)ccc(c6cccc2c63)c54)cc1]

The host materials H1-H3 are synthesized as disclosed in the patent application with application number CN202110370887.3; H4-H7 are synthesized as disclosed in the contemporaneous patent application with application number CN2022085362; and H8-H10 are synthesized as disclosed in the contemporaneous patent application with application number CN2022085363.

For the perovskite emitters E1-E4, the E1 is a green three-dimensional perovskite emitter, the E2 is a red three-dimensional perovskite emitter, the E3 is a green quasi-two-dimensional perovskite emitter, and the E4 is a red quasi-two-dimensional perovskite emitter. These perovskite emitters were commercially available, e.g., purchased from Zhijing Technology (Beijing) Co., Ltd. The FWHMs of the perovskite emitters E1-E4<40 nm.

### Example 1: Preparation of Polymers-Containing Formulations and Organic Functional Films

100 mg of polymethyl methacrylate (PMMA), 50 mg of the host material Hx (i.e., H1-H10) for color conversion, and 5 mg of the perovskite emitter Ex (i.e., E1-E4) were dissolved in 1 mL of n-butyl acetate to obtain a clear solution (i.e., a formulation or a printing ink). Using a KW-4a spin coater, the above clear solution was spun-coated on the surface of the quartz glass to form an uniform thin film, which is an organic functional film (i.e., a color conversion film). When the thickness is thinner than 6 μm, most of the obtained color conversion films have an optical density(OD) reach 3 or more.

### Example 2: Preparation of Resin Prepolymers-Containing Formulations and Organic Functional Films

The resin prepolymers-containing formulations and organic functional films could be obtained that the above-mentioned host material Hx (i.e., H1-H10) and the perovskite emitters Ex (i.e., E1-E4) for color conversion were premixed with resin prepolymer (such as methyl methacrylate, styrene, or methylstyrene). Initiated by 1-5 wt % of a photoinitiator (such as TPO (diphenyl (2,4,6-trimethylbenzoyl) phosphine oxide, 97%, CAS: 75980-60-8), the obtained formulation could form a thin film by spin coating, coating method, etc., and the obtained film was further cured by irradiation with a 365 nm or 390 nm UV LED lamp to form a color conversion film.

The green color conversion film can be disposed in a blue self-emitting unit that exhibits blue emission in the range of 400 nm to 490 nm. Through the green color converter, the blue light could change to a green light ranging from 490 nm to 550 nm. Through the red color converter, the blue light could change to a red light ranging from 600 nm to 680 nm.

### Example 3: Preparation of Top-Emission OLED Devices

Materials to be used in the preparation of top-emission OLED devices:

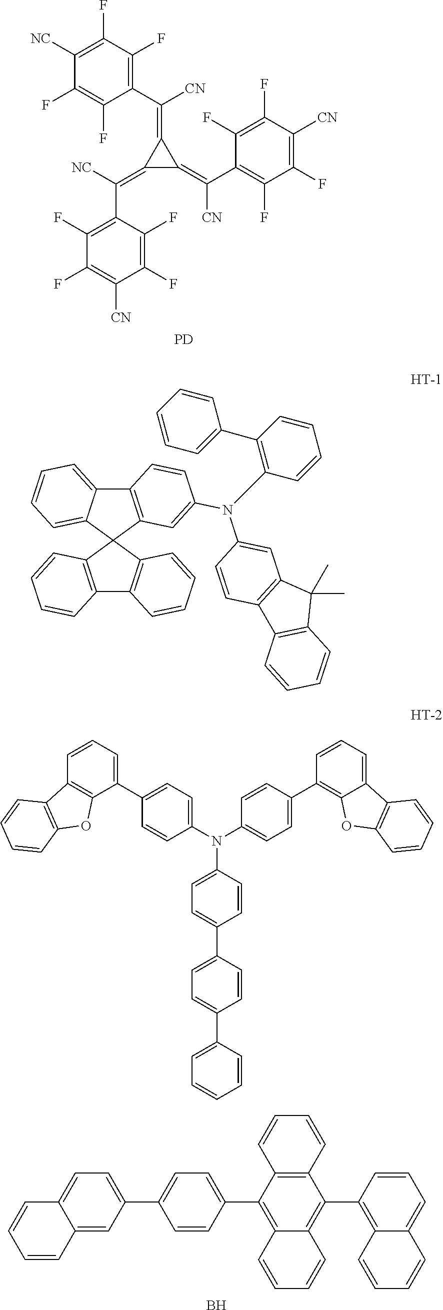

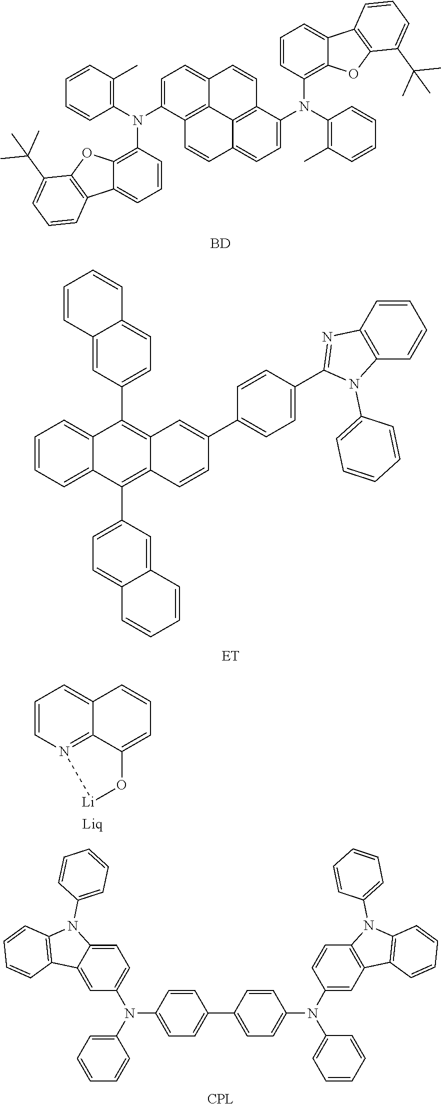

Preparation of Ink1:

Preparation of prepolymers: n-butyl acetate (42 wt %), methyl methacrylate (MMA) (50 wt %), hydroxypropyl acrylate (HPA) (3 wt %), and benzoyl peroxide (BPO) (5 wt %) were respectively weighed, mixed and stirred for 50 minutes at 125° C. to obtain a prepolymer. The prepolymer (67 wt %), n-butyl acetate (30 wt %), color conversion host material (H8) (2.5 wt %), and green perovskite emitter E1 (0.5 wt %) were mixed and stirred to obtain a clear solution (Ink1).

Preparation of Ink2: 50 mg of the host material (H8) for color conversion and 10 mg of the green perovskite emitter E1 for color conversion were dissolved in 1 mL of n-butyl acetate to obtain a clear solution (Ink2).
1. Green Light-Emitting Device 1
a. Cleaning of Ag-containing ITO (indium tin oxide) top substrate: the substrate was ultrasonically cleaned with strip liquid, pure water, and isopropyl alcohol in sequence, then treated with ozone in argon after drying.
b. Evaporation: the resultant substrate was mounted on a vacuum deposition apparatus in high vacuum (1×10⁻⁶ mbar), the weight ratio of PD and HT-1 was controlled to be 3:100 to form a hole-injection layer (HIL) having a thickness of 10 nm, followed by evaporation of compound HT-1 on the hole-injection layer to form a hole-transport layer (HTL) having a thickness of 120 nm, and then immediately followed by evaporation of compound HT-2 on the hole-transport layer to form a hole-buffer layer having a thickness of 10 nm. Then BH and BD at a weight ratio of 100:3 to form a light-emitting layer film having a thickness of 25 nm. Subsequently, ET:Liq were respectively placed in two different evaporation sources, and co-deposited on the light-emitting layer at a weight ratio of 50:50 to form an electron-transport layer having a thickness of 35 nm. Yb was then deposited on the electron-transport layer to form an electron-injection layer having a thickness of 1.5 nm, and Mg:Ag (1:9) alloy was deposited on the electron-injection layer to form a cathode having a thickness of 16 nm.
c. On the cathode, ink1 was printed with Haisi electronic IJDAS310 (nozzle FUJIFILM Dimatix DMC-11610), then cured by irradiating with a 390 nm UV LED lamp to obtain a color conversion layer with a thickness of 2 μm to 3 μm.
d. Encapsulation: encapsulating the device in a nitrogen-regulated glove box with UV curable resin.
2. Green light-emitting device 2: steps a, b, d are the same as described in the procedure for preparing the above-mentioned green light-emitting device 1, the step c is as follows.
c. On the cathode, Ink2 was printed with Haisi electronic IJDAS310 (nozzle FUJIFILM Dimatix DMC-11610) to obtain a color conversion layer with a thickness of 1 μm to 2 μm.
3. Green light-emitting device 3: steps a, b, c are the same as described in the procedure for preparing the above-mentioned green light-emitting device 1, the step d, e are as follows:
d. CPL with a thickness of 70 nm was evaporated on the color conversion layer and used as an optical capping layer.
e. Encapsulation: encapsulating the device in a nitrogen-regulated glove box with UV curable resin.
4. Green light-emitting device 4: steps a, b, and c are the same as described in the procedure for preparing the above-mentioned green light-emitting device 2, the steps d, e are as follows:
d. CPL with a thickness of 70 nm was evaporated on the color conversion layer and used as an optical capping layer.
e. Encapsulation: encapsulating the device in a nitrogen-regulated glove box with UV curable resin.

All of the above green light-emitting devices 1-4 have high color purity, and the FWHMs of their emission spectrums are below 35 nm. Green and red light-emitting devices preparing from other host materials and perovskite emitters can also be produced by the similar way.

The technical features of the above-described embodiments can be combined in any ways. For the sake of brevity, not all possible combinations of the technical features of the above-described embodiments have been described. However, as long as there are no contradictions in the combination of these technical features, they should be considered to be within the scope of this specification.

What described above are several embodiments of the present disclosure, and they are specific and in detail, but not intended to limit the scope of the present disclosure. It will be understood that improvements can be made without departing from the concept of the present disclosure, and all these modifications and improvements are within the scope of the present disclosure. The scope of the present disclosure shall be subject to the appended claims.

What is claimed is:

1. A mixture, comprising an organic compound H and a perovskite emitter E, wherein, an emission spectrum of the organic compound H is on a short wavelength side of an absorption spectrum of the perovskite emitter E, and at least partially overlaps with the absorption spectrum of the perovskite emitter E; the perovskite emitter E comprises constituent components A, B, and X, wherein the constituent component A indicates a component positioned at each vertex of a hexahedron having the constituent component B at a center in a perovskite type crystal structure and is a monovalent cation; the constituent component X indicates a component positioned at each vertex of an octahedron having the constituent component B at the center in the perovskite type crystal structure and is an anion; the constituent component B indicates a component positioned at the centers of the hexahedron where the constituent component A is disposed at each vertex and the octahedron where the constituent component X is disposed at each vertex in the perovskite type crystal structure and is a metal cation; and a full width at half maximum (FWHM) of an emission spectrum of the perovskite emitter E≤45 nm.

2. The mixture according to claim 1, wherein the perovskite emitter E is selected from a compound having any of a three-dimensional structure, a two-dimensional structure, a quasi-two-dimensional structure, or any combination thereof, and the compositional formula of the perovskite emitter E having a three-dimensional structure is represented by ABX_{(3+δ)}, the compositional formula of the perovskite emitter E having a two-dimensional or quasi-two-dimensional structure is represented by A₂BX_{(4+δ)}, wherein δ is a number which can be changed according to the charge balance of B and is in a range of −0.7 to 0.7.

3. The mixture according to claim 1, wherein,
the constituent component A in multiple occurrences, is independently selected from cesium ions, or cations of formula (I) or (II), 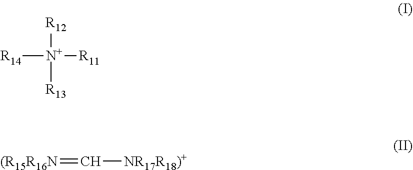
wherein, R₁₁ to R₁₈ are independently selected from the group consisting of —H, -D, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, and R₁₁ to R₁₄ are not all H or D;
and/or the constituent component B in multiple occurrences, is independently selected from Cu²⁺, Ni²⁺, Mn²⁺, Fe²⁺, Co²⁺, Pd²⁺, Ge²⁺, Sn²⁺, Pb²⁺, or Eu²⁺, preferably from Sn²⁺ or Pb²⁺, more preferably from Pb²⁺;
and/or the constituent component X in multiple occurrences, is independently selected from a halide ion or a thiocyanate ion.

4. The mixture according to claim 2, wherein,
the constituent component A in multiple occurrences, is independently selected from cesium ions, or cations of formula (I) or (II), 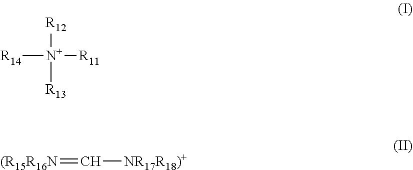
wherein, R₁₁ to R₁₈ are independently selected from the group consisting of —H, -D, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, and R₁₁ to R₁₄ are not all H or D;
and/or the constituent component B in multiple occurrences, is independently selected from Cu²⁺, Ni²⁺, Mn²⁺, Fe²⁺, Co²⁺, Pd²⁺, Ge²⁺, Sn²⁺, Pb²⁺, or Eu²⁺, preferably from Sn²⁺ or Pb²⁺, more preferably from Pb²⁺;
and/or the constituent component X in multiple occurrences, is independently selected from a halide ion or a thiocyanate ion.

5. The mixture according to claim 1, wherein the organic compound H is selected from the compounds comprising at least one of the following groups: 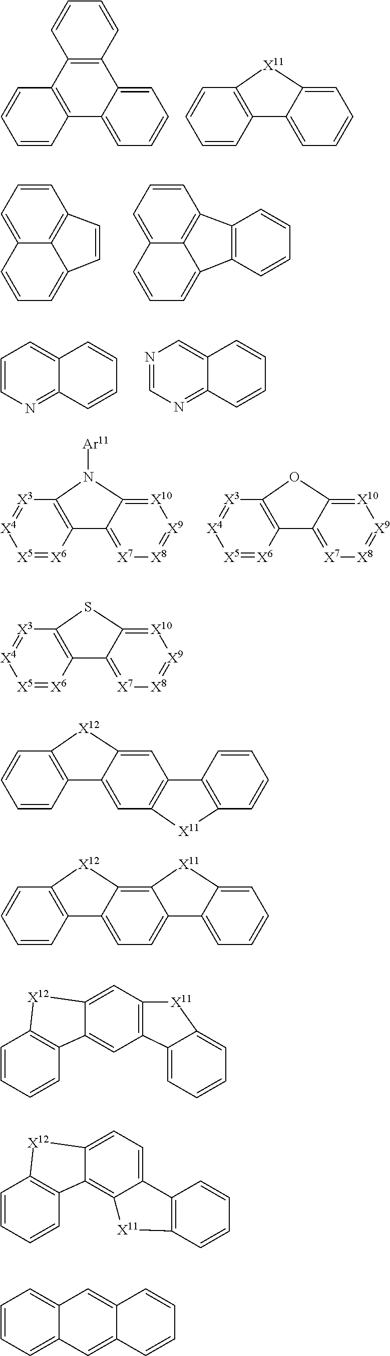 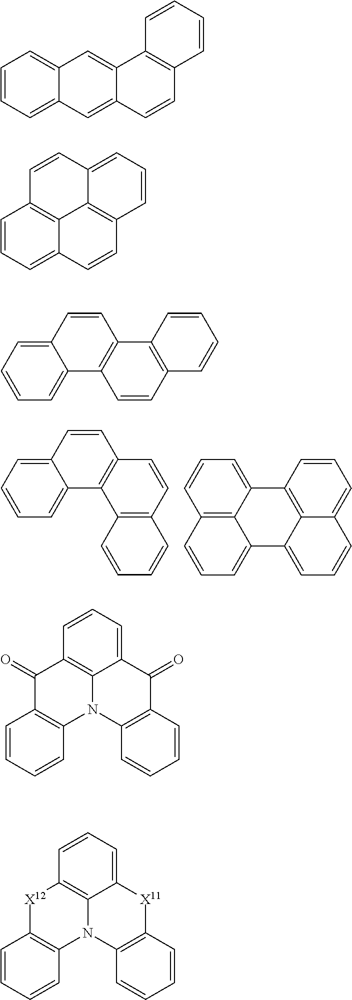
wherein:
Ar¹¹ is aryl or heteroaryl;
each of X³ to X¹⁰ is CR¹ or N;
X¹¹ and X¹² are independently selected from CR¹R², NR¹, or O;
R¹ and R² are independently selected from the group consisting of H, D, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ substituted ketone group, a C₂-C₂₀ alkoxycarbonyl group, a C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —NO₂, —CF₃, —Cl, —Br, —F, —I, a cross-linkable group, a substituted/unsubstituted aromatic or heteroaromatic group containing 5 to 40 ring atoms, an aryloxy/heteroaryloxy group containing 5 to 40 ring atoms, an arylamine or heteroarylamine group containing 5 to 40 ring atoms, and a disubstituted unit in any position of the above substituents or a combination thereof, wherein one or more R¹-R² may form a monocyclic or polycyclic aliphatic or aromatic ring system with each other and/or with the rings bonded thereto.

6. The mixture according to claim 2, wherein the organic compound H is selected from the compounds comprising at least one of the following groups: 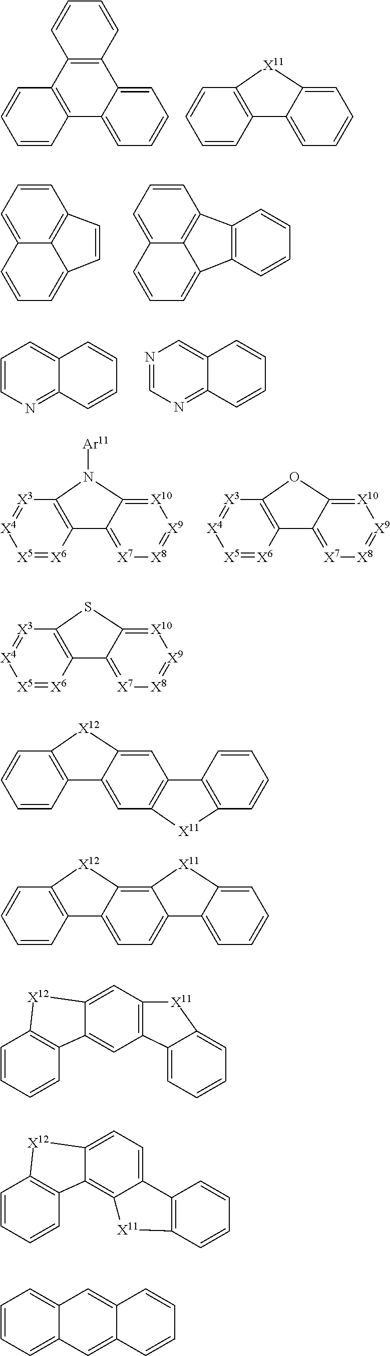 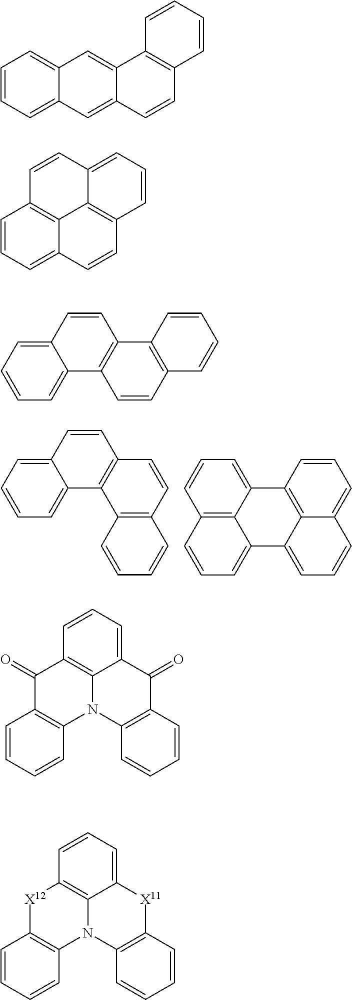
wherein:
Ar¹¹ is aryl or heteroaryl;
each of X³ to X¹⁰ is CR¹ or N;
X¹¹ and X¹² are independently selected from CR¹R², NR¹, or O;
R¹ and R² are independently selected from the group consisting of H, D, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ substituted ketone group, a C₂-C₂₀ alkoxycarbonyl group, a C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —NO₂, —CF₃, —Cl, —Br, —F, —I, a cross-linkable group, a substituted/unsubstituted aromatic or heteroaromatic group containing 5 to 40 ring atoms, an aryloxy/heteroaryloxy group containing 5 to 40 ring atoms, an arylamine or heteroarylamine group containing 5 to 40 ring atoms, and a disubstituted unit in any position of the above substituents or a combination thereof, wherein one or more R¹-R² may form a monocyclic or polycyclic aliphatic or aromatic ring system with each other and/or with the rings bonded thereto.

7. The mixture according to claim 3, wherein the organic compound H is selected from the compounds comprising at least one of the following groups: 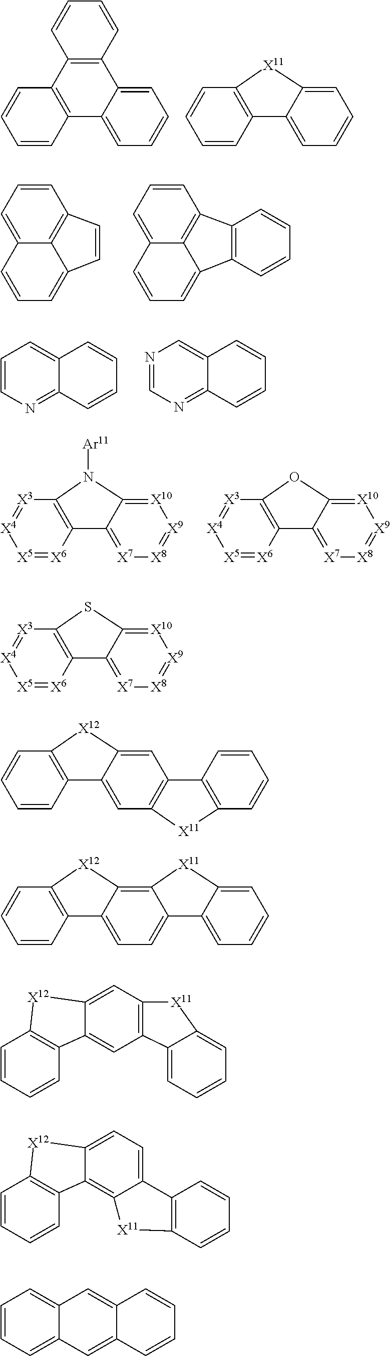 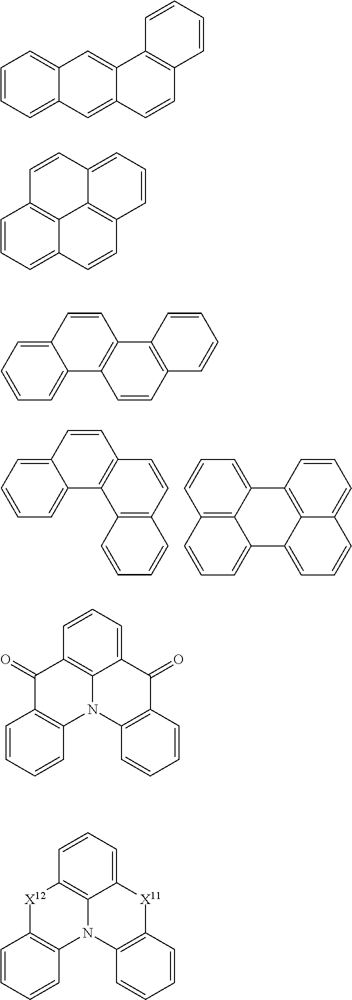
wherein:
Ar¹¹ is aryl or heteroaryl;
each of X³ to X¹⁰ is CR¹ or N;
X¹¹ and X¹² are independently selected from CR¹R², NR¹, or O;
R¹ and R² are independently selected from the group consisting of H, D, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ substituted ketone group, a C₂-C₂₀ alkoxycarbonyl group, a C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —NO₂, —CF₃, —Cl, —Br, —F, —I, a cross-linkable group, a substituted/unsubstituted aromatic or heteroaromatic group containing 5 to 40 ring atoms, an aryloxy/heteroaryloxy group containing 5 to 40 ring atoms, an arylamine or heteroarylamine group containing 5 to 40 ring atoms, and a disubstituted unit in any position of the above substituents or a combination thereof, wherein one or more R¹-R² may form a monocyclic or polycyclic aliphatic or aromatic ring system with each other and/or with the rings bonded thereto.

8. The mixture according to claim 4, wherein the organic compound H is selected from the compounds comprising at least one of the following groups: 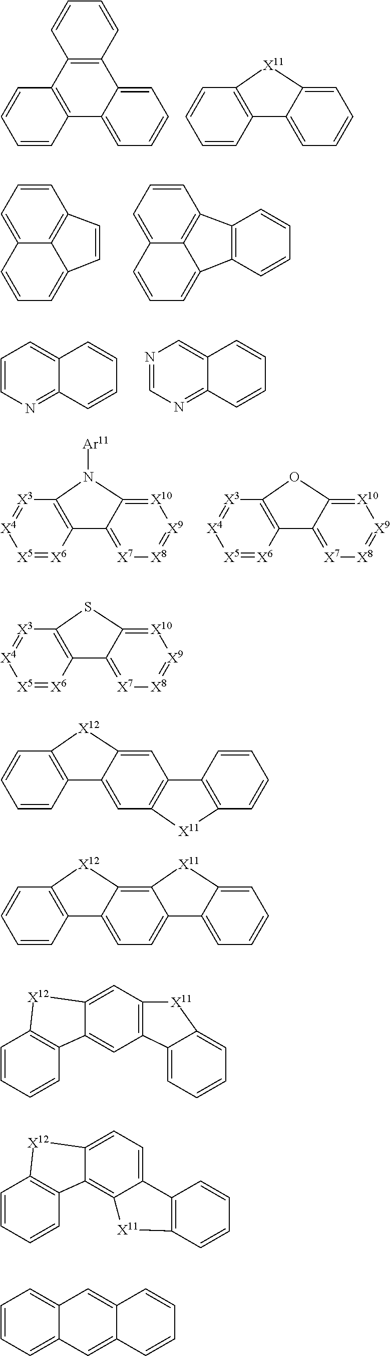 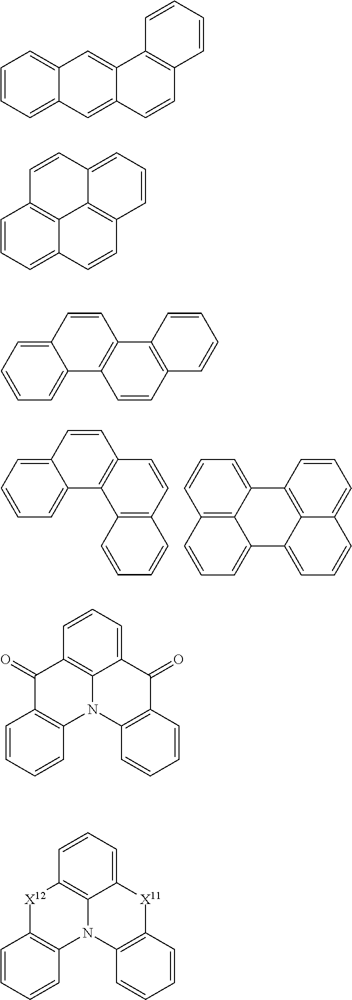
wherein:
Ar¹¹ is aryl or heteroaryl;
each of X³ to X¹⁰ is CR¹ or N;
X¹¹ and X¹² are independently selected from CR¹R², NR¹, or O;
R¹ and R² are independently selected from the group consisting of H, D, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ substituted ketone group, a C₂-C₂₀ alkoxycarbonyl group, a C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —NO₂, —CF₃, —Cl, —Br, —F, —I, a cross-linkable group, a substituted/unsubstituted aromatic or heteroaromatic group containing 5 to 40 ring atoms, an aryloxy/heteroaryloxy group containing 5 to 40 ring atoms, an arylamine or heteroarylamine group containing 5 to 40 ring atoms, and a disubstituted unit in any position of the above substituents or a combination thereof, wherein one or more R¹-R² may form a monocyclic or polycyclic aliphatic or aromatic ring system with each other and/or with the rings bonded thereto.

9. The mixture according to claim 1, wherein the organic compound H comprises a structure of one of formulas (III-I)-(III-V): 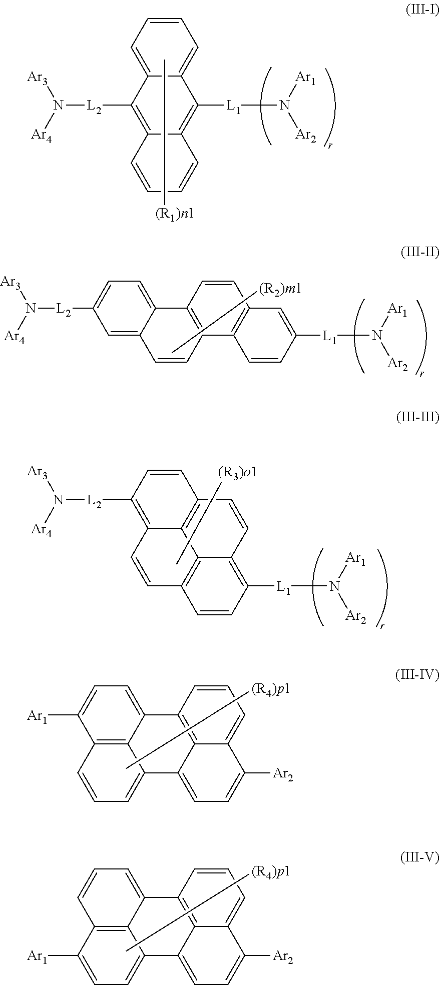
wherein:
n1, o1 are integers from 1 to 8; m1, p1 are integers from 1 to 10; r is 0 or 1;
R₁ to R₄ are substituent and are independently selected from the group consisting of a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/cyclic alkyl group, a C₃-C₂₀ branched/cyclic haloalkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ substituted ketone group, a C₂-C₂₀ alkoxycarbonyl group, a C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —NO₂, —CF₃, —Cl, —Br, —F, —I, a cross-linkable group, a substituted/unsubstituted aromatic or heteroaromatic group containing 5 to 40 ring atoms, an aryloxy or heteroaryloxy group containing 5 to 40 ring atoms, an arylamine or heteroarylamine group containing 5 to 40 ring atoms, and a disubstituted unit in any position of the above substituents or a combination thereof;
each of Ar₁ to Ar₄ at each occurrence is independently selected from the group consisting of a substituted/unsubstituted aromatic or heteroaromatic group containing 5 to 40 ring atoms, an aryloxy or heteroaryloxy group containing 5 to 40 ring atoms, and any combination thereof;
each of L₁ and L₂ at each occurrence is independently selected from the group consisting of a single bond, a substituted/unsubstituted aromatic or heteroaromatic group containing 6 to 30 ring atoms.

10. The mixture according to claim 1, wherein the mixture further comprises at least one organic resin.

11. The mixture according to claim 10, wherein at least one of the organic resin is a thermosetting resin or a UV curable resin.

12. A formulation, comprising the mixture according to claim 1, and at least one solvent.

13. The formulation according to claim 12, wherein the at least one solvent is selected from water, alcohols, esters, aromatic ketones, aromatic ethers, aliphatic ketones, aliphatic ethers, borates, phosphorates, or mixtures of two or more of them.

14. An organic light-emitting device, comprising a substrate, a first electrode, an organic light-emitting layer, a second electrode, a color conversion layer, and an encapsulation layer in sequence from bottom to top, wherein the second electrode is at least partially transparent, the color conversion layer comprises the mixture according to claim 1; the color conversion layer absorbs 50% or more of the light emitted by the organic light-emitting layer through the second electrode; and the emission spectrum of the organic compound H is on the short wavelength side of the absorption spectrum of the perovskite emitter E, and at least partially overlaps with the absorption spectrum of the perovskite emitter E.
